(19) United States
(12) Patent Application Publication
(10) Pub. No.: US 2026/0031057 A1
(43) Pub. Date: Jan. 29, 2026

(54) DISPLAY APPARATUS, CONTROL METHOD, AND ADJUSTMENT METHOD FOR POWER SUPPLY VOLTAGE

(71) Applicant: HISENSE VISUAL TECHNOLOGY CO., LTD., Shandong (CN)

(72) Inventors: Zhenhua PANG, Shandong (CN); Zhitao YU, Shandong (CN); Minhua LI, Shandong (CN); Yedong WANG, Shandong (CN); Jianwei CAO, Shandong (CN); Chunyang ZHANG, Shandong (CN); Mingyu LI, Shandong (CN); Guangxue LIU, Shandong (CN); Zhiqiang XU, Shandong (CN); Bin LI, Shandong (CN); Laiyuan ZHANG, Shandong (CN)

(21) Appl. No.: 19/345,418

(22) Filed: Sep. 30, 2025

Related U.S. Application Data
(63) Continuation of application No. 19/329,208, filed on Sep. 15, 2025.
Application No. 19/329,208 is a continuation of application No. PCT/CN2024/083141, filed on Mar. 21, 2024.

(30) Foreign Application Priority Data
Mar. 21, 2023 (CN) 202310280055.1
Feb. 8, 2024 (CN) 202410178142.0
Feb. 8, 2024 (CN) 202410178148.8
Feb. 8, 2024 (CN) 202410178444.8
Feb. 8, 2024 (CN) 202410178446.7
Feb. 8, 2024 (CN) 202410178447.1
Feb. 8, 2024 (CN) 202410178449.0
Feb. 8, 2024 (CN) 202420290590.5
Feb. 8, 2024 (CN) 202420290603.9

(51) Int. Cl. G09G 3/34; G09G 3/36

(52) U.S. Cl. CPC G09G 3/3426; G09G 3/3648; G09G 2310/0245; G09G 2320/0233; G09G 2320/0247; G09G 2320/064; G09G 2330/023

(57) ABSTRACT

A display apparatus comprises a backlight assembly, comprising: at least one drive group, wherein one drive group comprises at least one first drive chip and at least one second drive chip, a quantity of channels of a first drive chip differs from a quantity of channels of a second drive chip, and the at least one first drive chip and the at least one second drive chip are connected in series; and at least one light-emitting unit group, wherein one light-emitting unit group comprises a plurality of light sources, each of the plurality of light sources is connected to the first drive chip or the second drive chip via a channel of the first drive chip or the second drive chip.

The present application is a continuation application of U.S. patent application Ser. No. 19/329,208, which is a continuation application of PCT/CN2024/083141 filed on Mar. 21, 2024, which claims the priority of Chinese patent applications No. 202310280055.1 filed on Mar. 21, 2023, No. 202410178449.0 filed on Feb. 8, 2024, No. 202410178446.7 filed on Feb. 8, 2024, No. 202410178447.1 filed on Feb. 8, 2024, No. 202410178142.0 filed on Feb. 8, 2024, No. 202410178148.8 filed on Feb. 8, 2024, No. 202420290603.9 filed on Feb. 8, 2024, No. 202420290590.5 filed on Feb. 8, 2024, No. 202410178444.8, filed on Feb. 8, 2024, the entire contents of which are incorporated by reference herein.

### TECHNICAL FIELD

The present application relates to a display apparatus, a control method and a method for adjusting a power supply voltage.

### BACKGROUND

A display apparatus is an apparatus that displays images and/or user interfaces. The display apparatus includes at least one processor, a display panel, and a backlight assembly. The backlight assembly includes a drive circuit and a light board. The light board includes array-distributed light beads. At least one light bead is electrically connected to form a light-emitting unit group (partition). The drive circuit drives each partition to emit light.

As the display quality of the display apparatus improves, the increasing of the quantity of partitions on the light board increases and the improving of the driving capability of the drive circuit becomes a research topic.

The display apparatus may also include a power supply circuit and a mainboard. The power supply circuit provides power source signals to the mainboard and the backlight assembly at the same time through stepped power supply. When the display apparatus is in standby mode, the backlight assembly generates leakage current based on the power source signal, resulting in power loss. Therefore, how to reduce the power loss generated by the backlight assembly during the standby mode of the display apparatus has become a research topic.

During the power supply process of the power supply circuit, at least one processor generates drive data based on the acquired data to adjust the current value provided by each drive chip to the corresponding light string, and also controls the power supply circuit to provide the power supply voltage to multiple light strings based on the electrical signal fed back by the drive chip, so that the multiple light strings emit light. How to ensure the accuracy of power supply voltage regulation while reducing the quantity of signals transmitted inside the display apparatus has become a research topic.

In order to improve the smoothness and clarity of the image of the display apparatus, some liquid crystal display apparatuses use variable refresh rate (VRR) technology to dynamically adjust the display cycle of the display panel and backlight assembly in the display apparatus according to the current frame quantity effect to improve the display quality. Black frame insertion (BFI) technology based on variable refresh rate can solve the ghosting phenomenon caused by the slow response of liquid crystal molecules in the display panel.

Since the black insertion time length in the display period corresponding to different refresh rates is fixed, the black insertion ratios corresponding to different refresh rates are different, causing flickering in the image display. Therefore, solving the flickering problem of image storage has become a research topic.

As the integration of the backlight assembly increases, the temperature of the internal components in each region increases with the same current. Excessively high temperature will affect the life of the components.

In the related art, a temperature threshold of a component is set. When the temperature reaches the temperature threshold, the output current is controlled to be reduced to a lower value, which may cause the image displayed by the display apparatus to flicker and the accuracy and reliability of the backlight control to be low.

### SUMMARY

An embodiment of the present application provides a display apparatus, including: a backlight assembly, comprising: at least one drive group, wherein one drive group comprises at least one first drive chip and at least one second drive chip, a quantity of channels of a first drive chip differs from a quantity of channels of a second drive chip, and the at least one first drive chip and the at least one second drive chip are connected in series; and at least one light-emitting unit group, wherein one light-emitting unit group comprises a plurality of light sources, each of the plurality of light sources is connected to the first drive chip or the second drive chip via a channel of the first drive chip or the second drive chip; and a controller, connected to the at least one drive group and configured to: control the at least one drive group to drive the at least one light-emitting unit group to emit light based on drive data and a quantity of channels of the at least one drive group.

### BRIEF DESCRIPTION OF FIGURES

FIG. 1 is a schematic diagram of an operation scenario between a display apparatus and a control apparatus according to some embodiments.

FIG. 2 is a schematic structural diagram of a display apparatus according to some embodiments.

FIG. 3 is a schematic structural diagram of a display apparatus according to some other embodiments.

FIG. 4 is a schematic structural diagram of a circuit of a backlight assembly according to some embodiments.

FIG. 5A is a schematic structural diagram of a backlight assembly according to some other embodiments.

FIG. 5B is a schematic structural diagram of a backlight assembly according to some other embodiments.

FIG. 6 is a schematic flow chart of a method for controlling a display apparatus according to some embodiments.

FIG. 7 is a schematic diagram of hybrid dimming according to an embodiment.

FIG. 8 is a schematic flow chart of a method for controlling a display apparatus according to some other embodiments.

FIG. 9 is a schematic structural diagram of a drive chip according to some embodiments.

FIG. 10 is a schematic structural diagram of a drive chip according to some embodiments.

FIG. 11A is a schematic structural diagram of a connection relationship between a drive chip and its corresponding light beads according to some embodiments.

FIG. 11B is a schematic structural diagram of a connection relationship between a drive chip and its corresponding light beads according to some other embodiments.

FIG. 11C is a schematic structural diagram of a connection relationship between a drive chip and its corresponding light beads according to some other embodiments.

FIG. 12 is a schematic diagram of coating positions of an insulating layer and a conductive layer for a jumper wire in an exemplary embodiment.

FIG. 13 is a schematic diagram of coating positions of an insulating layer and a conductive layer for a jumper wire in another exemplary embodiment.

FIG. 14 is a schematic diagram of coating positions of an insulating layer and a conductive layer for a jumper wire in another exemplary embodiment.

FIG. 15 is a schematic diagram of coating positions of an insulating layer and a conductive layer for a jumper wire in another exemplary embodiment.

FIG. 16 is a schematic diagram of coating positions of an insulating layer and a conductive layer for a jumper wire in another exemplary embodiment.

FIG. 17 is a schematic diagram of coating positions of an insulating layer and a conductive layer for a jumper wire in another exemplary embodiment.

FIG. 18 is a waveform diagram of drive data in an exemplary embodiment.

FIG. 19 is a waveform diagram of drive data in another exemplary embodiment.

FIG. 20 is a waveform diagram of drive data in another exemplary embodiment.

FIG. 21 is a waveform diagram of drive data in another exemplary embodiment.

FIG. 22 is a waveform diagram of drive data in another exemplary embodiment.

FIG. 23 is a schematic structural diagram of a backlight assembly according to some other embodiments.

FIG. 24 is a schematic diagram of a circuit structure of a power supply source according to some embodiments.

FIG. 25 is a schematic structural diagram of a backlight assembly according to some embodiments.

FIG. 26A is a schematic structural diagram of a backlight assembly according to some embodiments.

FIG. 26B is a schematic structural diagram of a backlight assembly according to some other embodiments.

FIG. 26C is a schematic structural diagram of a backlight assembly according to some other embodiments.

FIG. 26D is a schematic structural diagram of a backlight assembly according to some other embodiments.

FIG. 27 is a display control method according to some embodiments.

FIG. 28 is a schematic structural diagram of a power supply control circuit according to some embodiments.

FIG. 29A is a schematic structural diagram of a power supply control circuit according to some other embodiments.

FIG. 29B is a schematic structural diagram of a power supply control circuit according to some other embodiments.

FIG. 30 is a schematic structural diagram of a backlight assembly according to some other embodiments.

FIG. 31 is a schematic structural diagram of a power supply control circuit according to some other embodiments.

FIG. 32 is a schematic structural diagram of an address unit according to some embodiments.

FIG. 33 is a schematic structural diagram of a drive circuit according to some embodiments.

FIG. 34 is a schematic structural diagram of a backlight assembly according to some other embodiments.

FIG. 35 is a schematic structural diagram of a backlight assembly according to some other embodiments.

FIG. 36 is a schematic structural diagram of a backlight assembly according to some other embodiments.

FIG. 37 is a schematic structural diagram of a power supply control circuit according to some other embodiments.

FIG. 38 is a waveform diagram of drive data according to some embodiments.

FIG. 39 is a waveform diagram of drive data according to some embodiments.

FIG. 40 is a waveform diagram of drive data according to some embodiments.

FIG. 41 is a schematic structural diagram of a display apparatus according to some other embodiments.

FIG. 42 is a schematic structural diagram of a backlight assembly according to some other embodiments.

FIG. 43 is a schematic structural diagram of a backlight assembly according to some other embodiments.

FIG. 44 is a schematic structural diagram of a demodulation circuit according to some embodiments.

FIG. 45 is a schematic diagram of a positional relationship between light beads and liquid crystal molecules according to some embodiments.

FIG. 46 is a schematic diagram of a response of liquid crystal molecules according to some embodiments.

FIG. 47 is a waveform diagram of a variable refresh rate according to some embodiments.

FIG. 48 is a schematic flow chart of a backlight control method for a display apparatus according to some embodiments.

FIG. 49 is a schematic diagram of a coupling of a plurality of drive chips with at least one controller in an exemplary embodiment.

FIG. 50A is a first schematic structural diagram of a drive circuit according to some embodiments of the present application.

FIG. 50B is a schematic structural diagram of a drive circuit in the related art.

FIG. 51 is a second schematic structural diagram of a drive circuit according to some embodiments of the present application.

FIG. 52A is a first structural diagram of a drive chip according to some embodiments of the present application.

FIG. 52B is a second structural diagram of a drive chip according to some embodiments of the present application.

FIG. 53A is a third schematic structural diagram of a drive circuit according to some embodiments of the present application.

FIG. 53B is a fourth schematic structural diagram of a drive circuit according to some embodiments of the present application.

FIG. 53C is a fifth schematic structural diagram of a drive circuit according to some embodiments of the present application.

FIG. 54A is a schematic structural diagram of a drive chip having a physical address in an exemplary embodiment.

FIG. 54B is a schematic structural diagram of a drive chip with a physical address in another exemplary embodiment.

FIG. 55 is a schematic structural diagram of a drive chip in another exemplary embodiment e.

FIG. 56 is a schematic structural diagram of a drive chip provided with an address calibration circuit in an exemplary embodiment.

FIG. 57 is a schematic structural diagram of a drive group according to some embodiments of the present disclosure.

FIG. 58 is a schematic structural diagram of a drive group according to some embodiments of the present disclosure.

FIG. 59 is a schematic structural diagram of a drive group according to some embodiments of the present disclosure.

FIG. 60A is a schematic structural diagram of a light board according to some embodiments of the present disclosure.

FIG. 60B is a schematic structural diagram of a light board according to some embodiments of the present disclosure.

FIG. 61 is a schematic structural diagram of a drive circuit according to some embodiments of the present disclosure.

FIG. 62 is a schematic structural diagram of a drive circuit according to some embodiments of the present disclosure.

FIG. 63 is a schematic structural diagram of a display apparatus according to some embodiments of the present application.

FIG. 64 is a schematic flow chart of a data communication method provided by the present application.

FIG. 65 is a schematic structural diagram of a drive circuit according to an embodiment.

FIG. 66 is a first schematic structural diagram of drive data of the drive group.

FIG. 67 is a second schematic structural diagram of drive data of the drive group.

FIG. 68 is a third schematic structural diagram of drive data of the drive group.

FIG. 69 is a fourth schematic structural diagram of drive data of the drive group.

FIG. 70 is a fifth schematic structural diagram of drive data of the drive group.

### DETAILED DESCRIPTION

Exemplary embodiments will be described in detail herein, examples of which are shown in the accompanying drawings. When the following description refers to the drawings, unless otherwise indicated, the same quantities in different drawings represent the same or similar elements. The implementations described in the following exemplary embodiments do not represent all implementations consistent with the present application. Instead, they are merely examples of devices and methods consistent with some aspects of the present application as detailed in the appended claims.

It should be noted that the brief description of terms in the present application is only for the convenience of understanding the embodiments described below, and is not intended to limit the embodiments of the present application. Unless otherwise specified, these terms should be understood according to their ordinary and common meanings.

The terms “first”, “second”, etc., in the specification and claims of the present application and the above drawings are used to distinguish similar or similar objects or entities, and do not necessarily mean to limit a specific order or sequence, unless otherwise indicated. It should be understood that the terms used in this way can be interchangeable under appropriate circumstances, for example, they can be implemented in an order other than those given in the diagrams or descriptions of the embodiments of the present application.

In addition, the terms “include” and “have” and any variations thereof are intended to cover but not exclude inclusion, for example, a product or device including a list of components is not necessarily limited to those components explicitly listed, but may include other components not explicitly listed or inherent to such products or devices. The term “circuit” as used in the present application refers to any known or later developed hardware, software, firmware, artificial intelligence, fuzzy logic or combination of hardware and/or software code that is capable of performing the functions associated with the element.

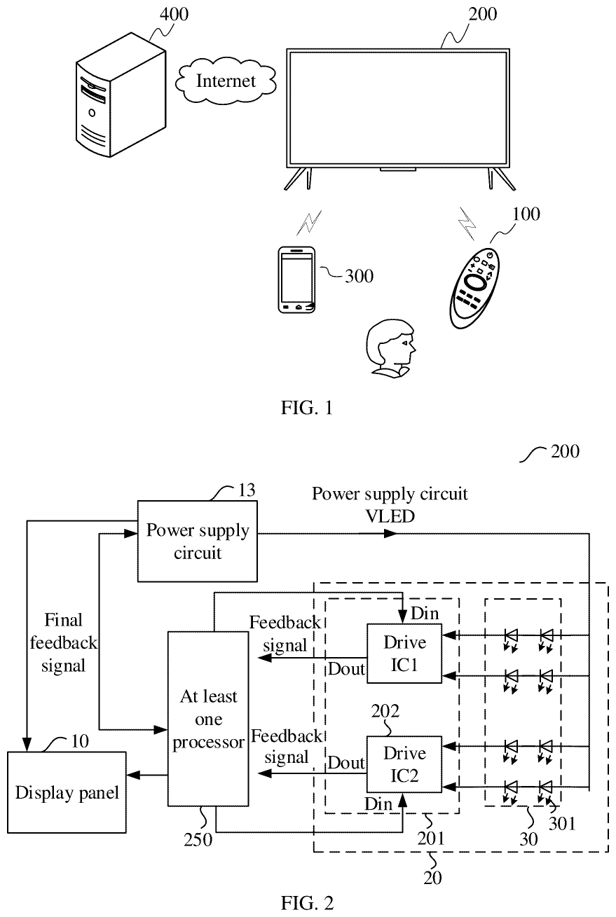

FIG. 1 is a schematic diagram of an operation scenario between a display apparatus and a control device according to some embodiments. As shown in FIG. 1, a user can operate a display apparatus 200 through a smart device 300 or a control device 100.

In some embodiments, the control device 100 may be a remote controller, and the communication between the remote controller and the display apparatus includes infrared protocol communication or Bluetooth protocol communication, and other short-range communication methods, and the display apparatus 200 is controlled wirelessly or wired. The user can input user commands through buttons on the remote controller, voice input, control panel input, etc., to control the display apparatus 200.

In some embodiments, a smart device 300 (such as a mobile terminal, a tablet computer, a computer, a laptop computer, etc.) may also be used to control the display apparatus 200. For example, the display apparatus 200 is controlled using an application running on the smart device.

In some embodiments, the display apparatus may not use the above smart device or control device to receive commands, but may receive user control through touch or gestures.

In some embodiments, the display apparatus 200 can also be controlled in a manner other than the control device 100 and the smart device 300. For example, the user's voice command control can be directly received through a module for obtaining voice commands configured inside the display apparatus 200, or the user's voice command control can be received through a voice control device set outside the display apparatus 200.

In some embodiments, the display apparatus 200 also communicates data with the server 400. The display apparatus 200 may be allowed to communicate and couple via a local area network (LAN), a wireless local area network (WLAN), and other networks. The server 400 may provide various content and interactions to the display apparatus 200. The server 400 may be one cluster or multiple clusters, and may include one or more types of servers.

FIG. 2 is a schematic structural diagram of a display apparatus 200 according to some embodiments.

In some embodiments, the display apparatus 200 includes at least one processor 250, and the at least one processor 250 can be configured to receive a video input signal or an image input signal, obtain backlight data and display data from the video input signal or the image input signal, and perform format conversion, timing control and other processing on the backlight data and the display data and then output them.

In some embodiments, at least one processor 250 may include multiple processors, for example, may include a System On Chip (SOC), which may be configured to obtain a video input signal or an image input signal (hereinafter referred to as input signal) from an external input port or a network port, and perform format conversion, data processing, image rendering and other operations on the input signal.

In some embodiments, at least one processor may include a timing controller (Tcon), which may be configured to perform timing control on the data obtained by it and output.

In some embodiments, the timing controller may be further configured to perform data format conversion.

In some embodiments, at least one processor 250 may include a backlight controller (Bcon) or at least one dimming controller (Dcon), which may be configured to obtain processed data associated with backlight data, generate and output drive data using the processed data.

In some embodiments, the display apparatus 200 may include a display panel 10 coupled to at least one processor, and the display panel 10 may include liquid crystal molecules that may be configured to deflect based on received processed display data.

In some embodiments, the display apparatus 200 may include a backlight assembly 20 coupled to at least one processor 250, and the backlight assembly 20 may be configured to emit light based on drive data. The display panel 10 may display an image based on the backlight provided by the backlight assembly 20.

In some embodiments, the backlight assembly 20 may include a drive circuit 201 coupled to at least one processor 250. The drive circuit 201 includes a plurality of drive chips 202. The drive chips 202 may be configured to generate drive signals based on drive data.

In some embodiments, the backlight assembly 20 may further include a light board 30, which includes light beads 301 distributed in an array, at least one light bead is electrically connected to form a light-emitting unit group, and the light-emitting unit group is electrically connected to a drive terminal of the drive chip 202, and can be configured to emit light based on a drive signal.

In some embodiments, the backlight assembly 20 may further include a plurality of light bars, and the light bar includes a plurality of light beads 301.

In some embodiments, the plurality of light beads 301 on the light bar are a string of light beads driven by the same one drive signal.

In some embodiments, a string of light beads on the light bar are connected in series.

In some other embodiments, a string of light beads on the light bar are connected in parallel.

In some embodiments, in the light-emitting unit group, at least one light bead is connected in series to form a light string.

In some other embodiments, in the light-emitting unit group, at least one light bead is connected in parallel.

In some other embodiments, in the light-emitting unit group, after at least one light bead is connected in series to form a light string, at least one light string is electrically connected in parallel.

Among them, the light string is a light string composed of light beads connected in series from left to right or from right to left, or a light string composed from top to bottom or from bottom to top, or a light string composed of light beads connected in series in a preset order (e.g., rotating, bending, etc.).

Among them, the light beads can be composed of Mini-LED, Micro-LED, WLED, RGB-LED, GB-rLED or QLED (quantum dots).

In one embodiment, the display apparatus 200 may include a power supply circuit 13, which is coupled to at least one processor 250, the backlight assembly, and the display panel 10. The power supply circuit 13 may be configured to provide corresponding power source signals to at least one processor 250, the display panel 10, and/or the backlight assembly 20.

In some embodiments, the power supply circuit 13 is coupled to the power supply terminal of each light-emitting unit group in the backlight assembly 20 and can be configured to provide a backlight power supply signal VLED so that the light-emitting unit group emits light when obtaining the backlight power supply signal VLED and the drive signal provided by the drive chip 202.

In some embodiments, the drive chip 202 samples the power supply voltage of the light-emitting unit group to determine the power supply state of the light-emitting unit group, where the power supply state includes an undervoltage state or an overvoltage state. The power supply state is fed back to at least one processor 250, so that at least one processor provides a final feedback signal to the power supply circuit 13 based on the feedback signal. The power supply circuit 13 adjusts the power supply voltage based on the final feedback signal.

In some embodiments, the drive chip 202 may transmit the feedback signal via a wire between its data output terminal Dout and the at least one processor 250.

In some other embodiments, the drive chip 202 may utilize its drive data transmission wires to transmit the feedback signal in reverse to at least one processor.

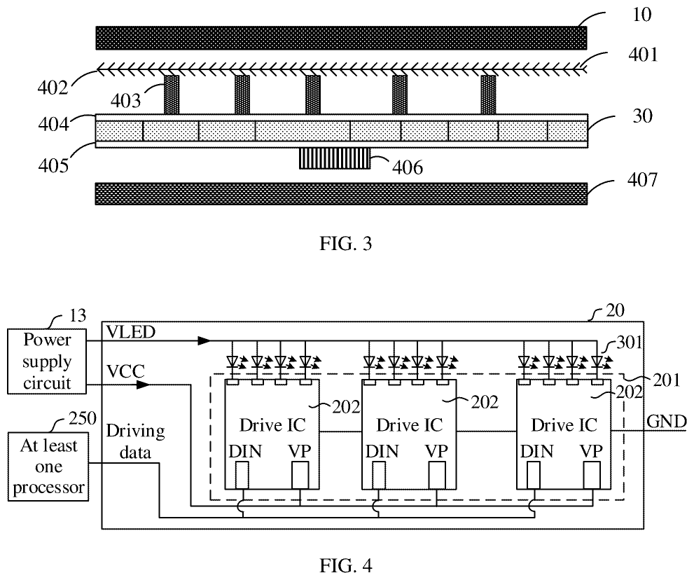

A physical structural schematic diagram of the backlight assembly 20 and the display panel 10 is shown in FIG. 3. The display panel 10 is disposed on an upper side of the backlight assembly, and the display panel 10 can display images on its upper side.

In some embodiments, the backlight assembly 20 can include a back panel 407, which can be configured as a substrate that provides support.

In some embodiments, the backlight assembly 20 may include a light board 30 on which light beads are disposed, and may be configured to provide backlight.

In some embodiments, the backlight assembly 20 may include: a reflective sheet 404, which may be configured to reflect the backlight of the light board toward the diffuser plate.

In some embodiments, the backlight assembly 20 may include: a bracket 403, which may be configured to support the diffuser plate 402, the film 401, etc., to maintain an optical spacing between the light board and the diffuser plate.

In some embodiments, the backlight assembly 20 may include: a film 401.

In some embodiments, the backlight assembly 20 may include: a diffuser plate 402.

The film 401 and the diffuser plate 402 may be configured to improve the reflective efficiency of the backlight generated by the backlight assembly, uniformly guide light, increase brightness and color saturation, and adjust the light so that the brightness distribution of the entire display panel is more uniform.

In some embodiments, the arrangement order of the components in the backlight assembly 20 from top to bottom is: the film 401, the diffuser plate 402, the bracket 403, the reflective sheet 404, the light board 30, and the back panel 407.

In some other embodiments, the backlight assembly 20 may further include a honeycomb panel 405 and a vibrator 406, which are placed between the light board 30 and the back panel 407 and may be configured to drive the backlight assembly 20 and the display panel 10 to vibrate and produce sound based on a sound signal.

In some embodiments, taking a micro LED display apparatus as an example, a plurality of light boards 30 are provided in the backlight assembly 20. After being spliced, the plurality of light boards 30 jointly emit light to provide backlight to the display panel 10. Each light board 30 may include a plurality of light-emitting regions, and each light-emitting region (also referred to as partition) may include a plurality of micro light beads, and the micro light beads are micron-level light beads such as mini-LED and micro-LED.

The light board 30 is electrically connected to the drive circuit, which may include one or more drive chips. The drive chip of each partition receives the processed backlight data sent by Bcon or Dcon, and drives the corresponding light beads to emit light based on the processed backlight data, thereby realizing local backlight control for the backlight assembly, that is, realizing local dimming, thereby achieving more accurate regional light control and making the screen brightness more uniform and harmonious.

FIG. 4 is a schematic structural diagram of a backlight assembly 20 according to some embodiments.

In some embodiments, the backlight assembly 20 may include a plurality of light beads 301 distributed in an array. At least one electrically connected light bead forms a light-emitting unit group. In some embodiments, the light-emitting unit group is called a partition.

In some embodiments, the backlight assembly 20 may include a drive circuit 201, the drive circuit 201 may include a plurality of drive chips 202, the drive chip 202 is provided with a data input terminal Din, and the data input terminal Din is coupled to at least one processor, and may be configured to receive drive data.

The drive chip 202 is further provided with a power source terminal VP connected to the power supply circuit 13, and the power source terminal VP can be configured to receive a power source signal VCC.

The drive chip 202 is further provided with at least one drive terminal, at least one drive terminal is electrically connected to the negative electrode of the corresponding light-emitting unit group, the positive electrode of the light-emitting unit group is connected to the power supply circuit 13, and the light-emitting unit group can be configured to obtain a power source signal VLED from the power supply circuit 13, obtain a drive signal from the drive chip 202, and emit light based on the drive signal and the power source signal.

In order to improve the display effect of the display apparatus, the quantity of partitions of the backlight assembly can generally be increased so that the quantity of adjustable light-emitting unit groups in a unit area on the backlight assembly increases. When the same brightness is provided in the unit area provides, at least one processor can adjust more light-emitting unit groups to achieve the target brightness. The adjustment of the quantity of light-emitting unit groups improves the adjustment accuracy of at least one processor, thereby improving the quality of the display image.

When the quantity of partitions increases, the size of a single light bead 301 can be reduced, and the bare light beads 301 can be attached and mounted on the light board to increase the quantity of light beads 301 per unit area on the backlight assembly 20, thereby increasing the quantity of partitions to reduce the production cost of the backlight assembly 20. The light board with the light beads 301 is adaptable to the increase in the quantity of partitions and improves the wiring accuracy, and the production cost is not much different.

As the quantity of partitions increases, the quantity of drive terminals of each drive chip 202 or the quantity of drive chips 202 provided in the backlight assembly 20 increases accordingly, so that each drive chip 202 in the drive circuit 201 meets the driving requirements of each partition. However, the increase in the quantity of drive terminals of the drive chip 202 or the increase in the quantity of drive chips 202 will greatly increase the production cost of the backlight assembly. Therefore, how to improve the driving capability of the drive circuit in the backlight assembly at a low cost when the quantity of partitions in the backlight assembly increases has become a research focus.

To this end, in a control method for a display apparatus and a display apparatus provided by some embodiments of the present application, the display apparatus may include a display panel, a power supply circuit, at least one processor, a light board and a drive circuit, the drive circuit is provided with at least one drive terminal and plurality of power supply terminals, drive terminals corresponds to multiple light-emitting unit groups, and the multiple light-emitting unit groups correspond to the plurality of power supply terminals respectively. When the drive circuit obtains drive data provided by at least one processor, power source signals are sequentially output from the plurality of power supply terminals to supply power to the multiple light-emitting unit groups connected to the power supply terminals in turn. and then corresponding drive signals are output through the drive terminals to drive different light-emitting unit groups to generate corresponding light intensities. Based on the above connection relationship and control logic, the quantity of light-emitting unit groups driven by the drive terminals of the drive circuit is increased exponentially, and when the quantity of partitions on the light board of the display apparatus is increased, the driving requirements of the partitions can be met without adding a large quantity of drive terminals and corresponding drive circuit structures, thereby achieving an improvement in the driving capability of the drive circuit in the backlight assembly at a low-cost.

The following specific embodiments are used to describe the implementation of the present application in detail. The following specific embodiments can be combined with each other, and the same or similar concepts or processes may not be described in detail in some embodiments.

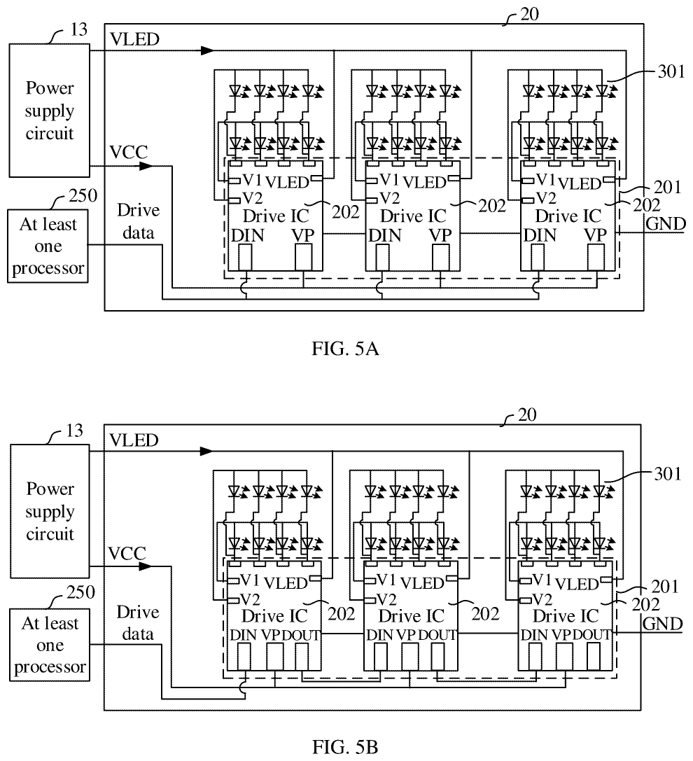

FIG. 5A is a schematic structural diagram of a display apparatus in a display apparatus provided in some embodiments of the present application. As shown in FIG. 5A, in some embodiments, the display apparatus may include a power supply circuit 13, which may be configured to provide a power source signal.

In some embodiments, the display apparatus may include at least one processor, which may be configured to obtain display data and backlight data, where the display data is data for controlling the rotation angle of liquid crystal molecules in the display panel, and the backlight data is data for controlling the backlight assembly to provide backlight.

In some embodiments, at least one processor is configured to provide processed backlight data.

In some embodiments, at least one processor is configured to further output drive data corresponding to each light-emitting unit group based on backlight data, the drive data including current value and duty ratio; and the current values corresponding to the light-emitting unit groups are the same.

At least one processor adjusts the brightness of the corresponding light-emitting unit group in the backlight assembly by adjusting the duty ratio, where the larger the duty ratio, the brighter the brightness; and the smaller the duty ratio, the lower the brightness.

FIG. 7 is a schematic diagram of dimming provided by the present application, including drive data corresponding to the four-row and five-column light-emitting unit group. The current values of the backlight sub-units are the same, which are 70 mA. The duty ratios of the backlight sub-unit are different. The brighter the brightness, the greater the duty ratio, and the darker the brightness, the smaller the duty ratio.

During the display of different frames of images, at least one processor adjusts the current value accordingly based on different backlight data.

In some embodiments, the display apparatus may include a backlight assembly 20 that may be configured to emit light based on the processed backlight data.

In some embodiments, the display apparatus may include a backlight assembly 20 configured to emit light based on the processed backlight data.

In some embodiments, the backlight assembly 20 may further include a plurality of light bars, and the light bar includes a plurality of light beads 301.

In some embodiments, the plurality of light beads 301 on the light bar are a string of light beads driven by the same one drive signal.

In some embodiments, a string of light beads on the light bar are connected in series.

In some other embodiments, a string of light beads on the light bar are connected in parallel.

In some embodiments, the backlight assembly 20 includes a light board, and the light board includes a plurality of light beads 301 distributed in an array.

In some embodiments, at least one light bead 301 is electrically connected to form a light-emitting unit group.

In some embodiments, a single light bead 301 forms a light-emitting unit group.

In some embodiments, at least two light beads 301 are electrically connected in series to form a light-emitting unit group.

In some embodiments, at least two light beads 301 are electrically connected in series to form at least one light string, and at least one light string is electrically connected in parallel to form a light-emitting unit group.

In the above embodiment, at least two light beads electrically connected in series or in parallel may be light beads arranged in rows, or may also be light beads arranged column by column, or may also be light beads arranged in a preset order, and the light beads may form regular or irregular patterns.

In some embodiments, the backlight assembly 20 may include a drive circuit 201.

In some embodiments, the drive circuit 201 is provided with a plurality of power supply terminals.

In some embodiments, the drive circuit 201 is provided with a power source terminal VP.

In some embodiments, the drive circuit 201 is provided with at least one drive terminal.

In some embodiments, the drive circuit 201 is provided with a data input terminal Din.

In some embodiments, the power source terminal VP is coupled to the power supply circuit 13 and may be configured to obtain a power source signal obtained by the power supply circuit 13.

In the circuit structure of the example of FIG. 5A, each data input terminal Din is coupled to at least one processor, each data input terminal Din corresponds to a piece of address information, and at least one processor can be configured to transmit corresponding drive data to each data input terminal Din based on the address information.

In some embodiments, output terminals of the drive circuits 202 correspond to a plurality of light-emitting unit groups and are electrically connected to the plurality of light-emitting unit groups. The plurality of light-emitting unit groups respectively correspond to a plurality of power supply terminals, where the quantity of power supply terminals is determined by the quantity of light-emitting unit groups corresponding to each drive terminal.

In some embodiments, the quantity of power supply terminals is greater than or equal to the quantity of light-emitting unit groups electrically connected to the drive terminals, and the power supply terminal can provide a power source signal to each light-emitting unit group accordingly.

In some other embodiments, each power supply terminal is electrically connected to the input terminal of the gating device, and the output terminal of the gating device is electrically connected to the light-emitting unit group electrically connected to each drive terminal, where the total quantity of output terminals of the gating device electrically connected to each power supply terminal is greater than or equal to the quantity of light-emitting unit groups electrically connected to each drive terminal.

The drive circuit 201 can be configured to obtain power source signals and drive data, and based on the drive data, sequentially output the power source signals from the power supply terminal, and output corresponding drive signals from the drive terminal to drive the light strings corresponding to the power supply terminal and the drive terminal to emit light.

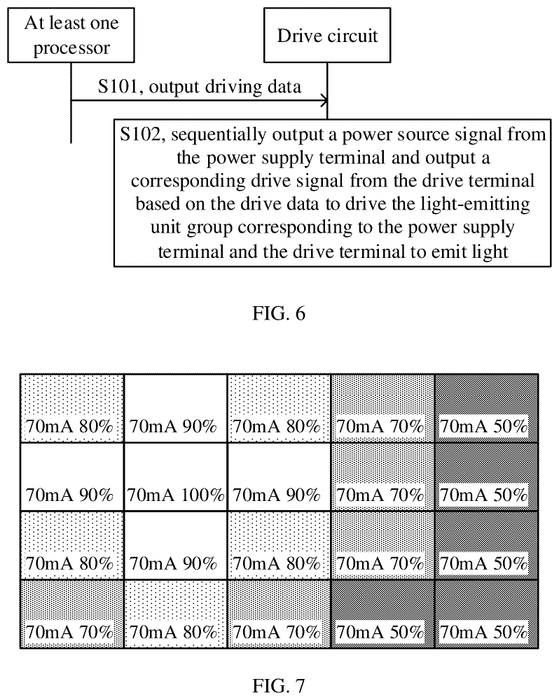

FIG. 6 is a schematic flow chart of a method for controlling a display apparatus provided by the present application. As shown in FIG. 6, the method may include the following.

S101, at least one processor outputs drive data.

S102, the drive circuit sequentially outputs power source signals from the power supply terminal and outputs a corresponding drive signal from the drive terminal based on the drive data to drive the light-emitting unit group corresponding to the power supply terminal and the drive terminal to emit light.

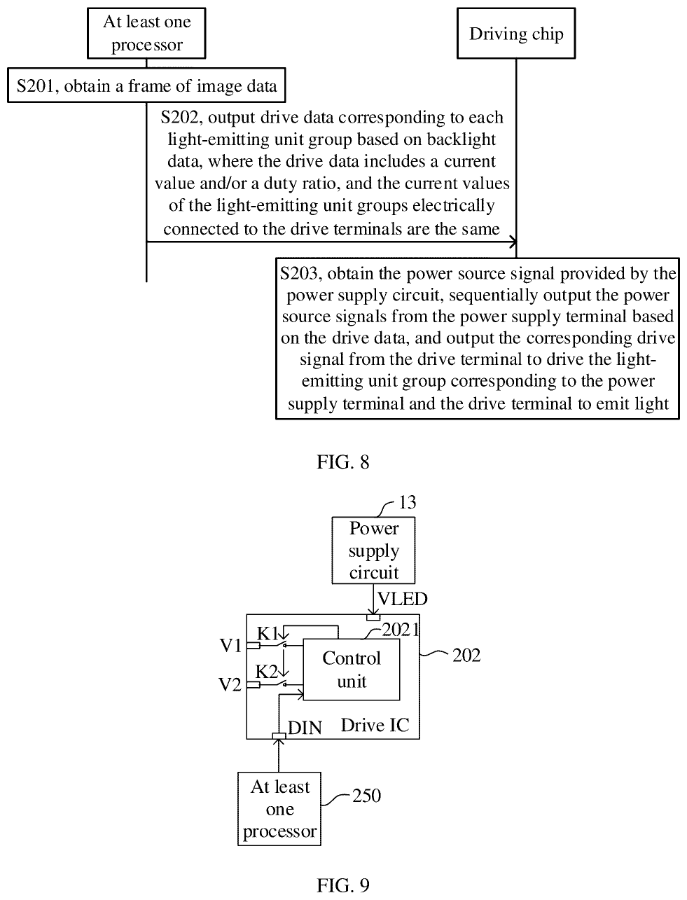

FIG. 8 is a schematic flow chart of a method for controlling a display apparatus provided by the present application. As shown in FIG. 8, the method includes the following.

S201, at least one processor obtains backlight data.

S202, at least one processor outputs drive data corresponding to each light-emitting unit group to the drive chip based on backlight data, where the drive data includes a current value and/or a duty ratio, and the current values of the light-emitting unit groups electrically connected to the drive terminals are the same.

S203, the drive chip obtains the power source signal provided by the power supply circuit, sequentially outputs the power source signals from the power supply terminal based on the drive data, and outputs the corresponding drive signal from the drive terminal to drive the light-emitting unit group corresponding to the power supply terminal and the drive terminal to emit light.

Taking FIG. 5A as an example, the method for controlling the display apparatus provided in the present application is further explained.

In some embodiments, the drive circuit 201 may include a plurality of drive chips 202, each of which is provided with at least one drive terminal.

In some embodiments, each drive chip 202 is provided with a plurality of power source terminals, and the quantity of the light-emitting unit groups connected to the drive terminals is less than or equal to the quantity of the power source terminals.

In some embodiments, when the quantity of the plurality of light-emitting unit groups connected to the drive terminal is the same as the quantity of the power source terminals, the plurality of light-emitting unit groups and the plurality of power source terminals are electrically connected correspondingly.

In some embodiments, when the quantity of at least one light-emitting unit group connected to the drive terminal is less than the quantity of the power source terminals, at least one light-emitting unit group can be electrically connected to a corresponding quantity of the power source terminals based on a preset light-emitting logic.

The preset light-emitting logic is the light-emitting sequence of multiple light-emitting unit groups corresponding to the drive chip, and the light-emitting unit groups are connected to the corresponding drive terminals and power source terminals based on their positions in the light-emitting sequence.

In some embodiments, the drive terminal may be suspended and not connected to the light-emitting unit group.

In some embodiments, the light-emitting unit group can be electrically connected to multiple power source terminals at the same time. When multiple power source terminals supply power, the light-emitting unit group can emit light through the corresponding drive signal obtained during the power supply period of one power source terminal.

In some embodiments, the drive terminal is electrically connected to at least two light-emitting unit groups. In the example shown in FIG. 5A, the drive circuit 201 includes three drive chips 202, and each drive terminal of each drive chip 202 is electrically connected to two light-emitting unit groups: a first light-emitting unit group and a second light-emitting unit group, where the first and second are only used to distinguish different light-emitting unit groups and have no order meaning.

In some embodiments, the drive chip 202 is provided with a power supply terminal V1 and a power supply terminal V2, the power supply terminal V1 is electrically connected to the first light-emitting unit group, and the power supply terminal V2 is electrically connected to the second light-emitting unit group.

In some other embodiments, each drive chip 202 is provided with a power supply terminal V1, and the power supply terminal V1 is electrically connected to an input terminal of a two-select-one gating device, where the two-select-one gating device is provided with an input terminal and two output terminals, and the two output terminals are electrically connected to the first light-emitting unit group and the second light-emitting unit group respectively. At any moment, only one output terminal of the two-select-one gating device is connected to the input terminal thereof.

In some embodiments, the drive chip is provided with 4 drive terminals, and the drive chip can drive up to 8 light-emitting unit groups, each drive terminal is electrically connected to the drive terminals of two light-emitting unit groups, and the power source terminals of the two light-emitting unit groups are electrically connected to the corresponding power supply terminals.

In some embodiments, the light-emitting unit group may include a light string composed of multiple light beads electrically connected in series, the drive terminal is electrically connected to the negative electrodes of the two light strings, and the positive electrodes of the two light strings are electrically connected to the corresponding two power supply terminals or the two output terminals of the two-select-one gating device.

In this embodiment, when the drive chip drives 8 light-emitting unit groups, the drive chip selects a row of light-emitting unit groups that need to emit light based on the power supply terminal for the corresponding two rows and four columns of light-emitting unit groups, and based on the drive signals provided by different drive terminals, drives this row of light strings to generate brightness corresponding to the drive signals based on the corresponding relationship with the drive terminals, thereby realizing the control of each light string by the drive chip.

In some embodiments, the plurality of drive chips 202 in the drive circuit 201 are arranged in an array. When the display panel is scanned row by row, multiple drive chips 202 driving the plurality of light-emitting unit groups in the same row form a drive group.

In some embodiments, data input terminals of the multiple drive chips 202 in each drive group are respectively electrically connected to the output terminal of at least one processor, as shown in FIG. 5A. Each drive chip 202 is provided with address information, and the address information may include a physical address or a memory address. At least one processor is electrically connected to the data input terminals of the drive chips 202 through a data line, and at least one processor broadcasts the data including the address information to the data line. The drive chip 202 corresponding to the address information obtains the drive data from the data line to drive its corresponding light-emitting unit group to emit light.

In one embodiment, the drive chips 202 in the drive group are electrically connected in series based on the data line, and the drive chips 202 are also provided with data output terminals Dout. As shown in FIG. 5B, the data input terminal Din of the drive chip 202 located first is electrically connected to the output terminal of at least one processor, and the data input terminal Din of other drive chips 202 is electrically connected to the data output terminal Dout of the previous drive chip 202.

In some embodiments, the drive data may further include the memory address of each drive chip, and the drive chip obtains the data terminal corresponding to its memory address from the drive data based on its memory address.

In some other embodiments, the sizes of the data terminals obtained by the drive chips are the same, so the drive chips read data segments of the same data length from the drive data one by one. After the reading of their data segments is completed, the remaining drive data is automatically moved forward to the reading position, so that the subsequent drive chips read the remaining data segments of the drive data from the reading position.

When there are at least two drive groups, the drive chip 202 located first in each drive group is provided with a physical address as the physical address of the drive group in which it is located. When at least one processor transmits drive data, the physical address of each drive group is provided in the drive data. Each drive group can simultaneously obtain the drive data transmitted by at least one processor. When the physical address of the drive data is consistent with the physical address of the drive group, the drive data is transmitted one by one along the arrangement order of the drive chips 202 in the drive group to ensure the accuracy of data transmission.

In some embodiments, when the drive chip 202 has plurality of power supply terminals, a power source switch is provided between the power source terminal and each power supply terminal, and the drive chip controls each power supply terminal to output a power source signal by controlling the conduction state of the power source switch.

In some embodiments, the drive chip 202 may include a control unit 2021 and multiple power source switches, and the multiple power source switches correspond to plurality of power supply terminals. The first terminals of the multiple power source switches are electrically connected to the power source terminal VP of the drive chip, and the second terminals of the multiple power source switches are respectively coupled to the corresponding power supply terminals.

FIG. 9 is a schematic structural diagram of the drive chip 202 according to some embodiments. As shown in FIG. 9, the drive chip 202 may include a first power source switch K1 and a second power source switch K2. The second terminal of the first power source switch K1 is electrically connected to the power supply terminal V1, and the second terminal of the second power source switch K2 is electrically connected to the power supply terminal V2. The first terminals of the first power source switch K1 and the second power source switch K2 are coupled to the power source terminal VP of the drive chip 202.

In some other embodiments, the first terminals of the plurality of power source switches are electrically connected to the power source terminal VP, and the second terminals of the plurality of power source switches are correspondingly coupled to the plurality of power supply terminals.

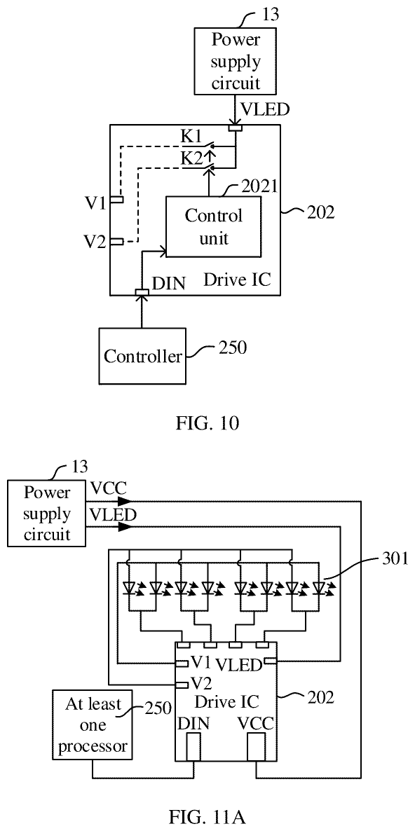

FIG. 10 is a schematic structural diagram of the drive chip 202 according to some embodiments. As shown in FIG. 10, the drive chip 202 may include a first power source switch K1 and a second power source switch K2. The second terminal of the first power source switch K1 is coupled to the power supply terminal V1, and the second terminal of the second power source switch K2 is coupled to the power supply terminal V2. The first terminals of the first power source switch K1 and the second power source switch K2 are electrically connected to the power source terminal VP of the drive chip 202.

In some embodiments, the power source switch may include a high-side transfer switch, a first terminal of which serves as an input terminal of the power source switch, a second terminal of which serves as an output terminal of the power source switch, and a control terminal of which serves as a control terminal of the power source switch.

In some embodiments, the high-side transfer switch may be a transistor or a field effect transistor.

The control unit 2021 is connected to control terminals of the plurality of power source switches respectively.

In some embodiments, when the drive chip 202 may also include a multiple-select-one gating device, the power source terminal VP of the drive chip 202 is electrically connected to the input terminal of the multiple-select-one gating device, the multiple output terminals of the multiple-select-one gating device are electrically connected to the first terminals of the multiple power source switches accordingly, and the control terminal of the multiple-select-one gating device is electrically connected to the control unit 2021.

The control unit 2021 may also be configured to drive the output terminals of the multiple-select-one gating device to be connected to the input terminal in a preset gating sequence based on the drive data.

In some embodiments, the multiple-select-one gating device can be equivalent to multiple power source switches, and the input terminal of the multiple-select-one gating device is electrically connected to the power source terminal VP of the drive chip 202, and each output terminal is electrically connected to the corresponding power supply terminal.

The drive chip 202 can be configured to receive the power source signal VLED provided by the power supply circuit 13 from the power source terminal, and sequentially control multiple power source switches to be turned on, so that plurality of power supply terminals sequentially output power source signals. It is worth noting that plurality of power supply terminals cannot output power source signals at the same time.

In some embodiments, the drive chip 202 may be configured to obtain drive data from at least one processor 250, and determine to output control signals to the power source switches based on the drive data.

In some embodiments, the drive data obtained by the drive circuit 201 may include multiple pulse signal segments, and the multiple pulse signal segments correspond to plurality of power supply terminals. The drive circuit 201 may be configured to output a power source signal from a corresponding power supply terminal within a power supply period corresponding to the pulse signal segment based on the multiple pulse signal segments. The display cycle may include multiple power supply periods, and the multiple power supply periods do not overlap with each other. The multiple pulse signal segments correspond to multiple power supply periods, and multiple power supply periods correspond to plurality of power supply terminals.

In each power supply period, a drive signal is output based on the pulse signal segment to drive the light-emitting unit group electrically connected to the drive terminal to emit light.

The drive chip adjusts the conduction state of each power source switch according to the acquired state of the pulse signal segment, thereby adjusting the power supply state of each power supply terminal.

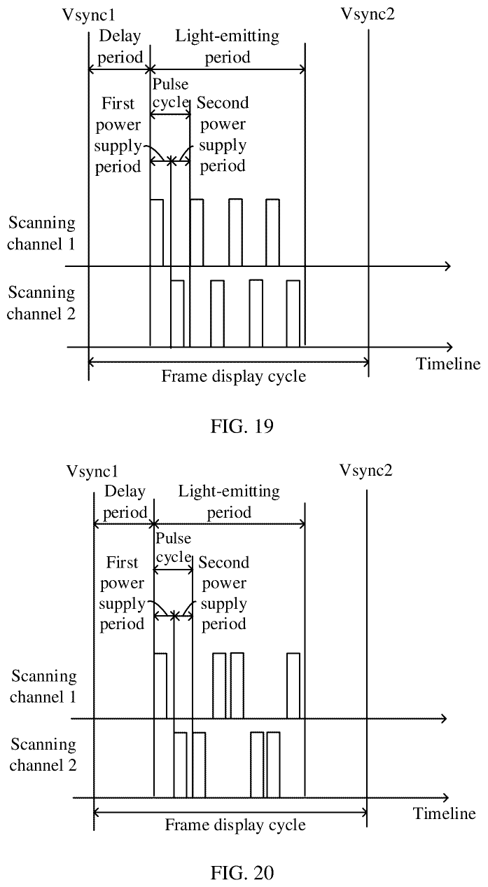

Taking the example of a drive chip 202 having two power supply terminals, the drive data obtained by the drive chip is a waveform diagram shown in FIG. 19. The control unit 2021 adjusts a control signal output based on the rising edge state of the pulse signal obtained by it, that is, when obtaining the rising edge of the first pulse signal, the control unit outputs a conduction control signal of the power source switch connected to the power supply terminal V2 to turn on the power source switch, and outputs the power source signal VLED obtained by the power source terminal of the drive chip from the power supply terminal V2 until the control unit obtains the rising edge of the second pulse signal, then stops outputting the conduction control signal to the power source switch connected to the power supply terminal V2, and outputs the conduction control signal to the power source switch connected to the power supply terminal V1, so that the power source signal VLED obtained by the power source terminal of the drive chip is output from the power supply terminal V1.

In some embodiments, a display cycle of one frame may include multiple pulse cycles, and the pulse cycle may include power supply periods corresponding to multiple light-emitting unit groups.

In some embodiments, the pulse cycles are different so as to make corresponding electrical signal adjustments to the driving process in cycles of different lengths.

In some embodiments, the pulse cycles are the same to simplify the driving process.

In some embodiments, a delay register is provided in the drive chip 202. After the drive chip obtains a software effectiveness command, the delay register starts timing. When the statistical time reaches the corresponding pulse delay time, the drive chip turns on the corresponding channel; and when the statistical time has not reached the corresponding pulse delay time, the drive chip does not turn on the corresponding channel.

In some embodiments, the delay register starts timing based on a clock signal.

In some other embodiments, the delay register starts timing based on counting the quantity of pulses output by the drive terminal of the drive chip.

In some embodiments, the drive chip 202 may also be configured to obtain multiple pulse delay times of the drive terminal; the pulse delay time is a time difference between a start moment of each pulse signal segment output by the target drive terminal within a pulse cycle and a start moment of the pulse cycle.

Based on the pulse delay time, a plurality of power supply periods are determined.

In some embodiments, the drive chip 202 can also be configured to provide multiple pulse signal segments from the target drive terminal based on the drive data within multiple power supply periods of each pulse cycle to make the corresponding light-emitting unit group emit light. The pulse signal segments correspond to multiple power supply periods, and each pulse signal segment corresponds to multiple light-emitting unit groups connected to each power supply terminal.

In some embodiments, the drive chip 202 may be configured to determine the duty ratio and amplitude of the pulse signal segment output by the target drive terminal in each power supply period based on the drive data; and the drive data may include the current value and the duty ratio.

During the power supply period, a corresponding pulse signal segment is output from the target drive terminal based on the light emission duty ratio and amplitude.

In some embodiments, the drive chip 202 may include a first register, which may be configured to store a current value.

In some embodiments, the drive chip 202 may include a second register, which may be configured to store a duty ratio.

When the drive chip 202 outputs a pulse signal segment, the waveform of the drive signal output by its target drive terminal is shown in FIG. 19. Taking the case where its drive terminal is electrically connected to two light-emitting unit groups as an example, the two pulse signals output by the target drive terminal are two pulse signals output by the drive chip during a scanning process. The first pulse signal is a pulse signal obtained by the light-emitting unit group electrically connected to the first power supply terminal and the target drive terminal when the first power supply terminal is powered, and the second pulse signal is a pulse signal obtained by the light-emitting unit group electrically connected to the second power supply terminal and the target drive terminal when the second power supply terminal is powered.

In some embodiments, the drive chip 202 may include a pulse quantity register, which may be configured to count the quantity of pulses that are output.

When the drive chip 202 determines that the pulse statistics quantity reaches the preset pulse quantity, it turns off the driving channel.

In some embodiments, the drive chip 202 may include a third register, which may be configured to adjust the output current value of the drive chip to the current value of the drive signal of the second driving channel when the quantity of pulses output by the first driving channel counted by the pulse quantity register reaches a preset pulse quantity.

The drive chip 202 cyclically provides multiple groups of pulse signals during multiple scanning processes, and the two light-emitting unit groups electrically connected to the target drive terminal emit light cyclically.

The wave generation conditions of other drive terminals of the drive chip 202 are similar to the wave generation conditions of the target drive terminal, and will not be described in detail here.

In some embodiments, the drive signal pulse signals output by the drive chips in the backlight assembly during a frame of image display have the same cycle, the same duty ratio, and the same amplitude. Then, the drive terminal of each drive chip adjusts the quantity of pulses it outputs within a display cycle of one frame based on the drive data to adjust the luminous brightness of the light-emitting unit group it drives.

In some embodiments, the drive chip 202 may also be configured to, when the current value or the voltage value is not within the corresponding preset range, sample the state of the light-emitting unit group driven by it, and feedback the state to the processor; where the state of the light-emitting unit group may include an undervoltage state or an overvoltage state.

In some embodiments, the drive chip 202 may also be configured to sample the state of the light-emitting unit group when the current value is less than a preset current value.

In some embodiments, the drive chip 202 may be further configured to sample the state of the light-emitting unit group when the voltage value is greater than a preset voltage value.

When the drive chip 202 drives the multiple light-emitting unit groups, the multiple light-emitting unit groups electrically connected to the drive chip 202 correspond to the multiple liquid crystal molecule groups in the display panel; each liquid crystal molecule group may include multiple liquid crystal molecules simultaneously used for displaying on the display panel.

The scanning direction for the liquid crystal molecule groups in the display panel may include a first scanning direction and a second scanning direction, and multiple liquid crystal molecule groups arranged along the first scanning direction are used for displaying based on the same phase, and multiple liquid crystal molecule groups arranged along the second scanning direction are used for displaying based on different phases. For example, when the liquid crystal molecule groups are scanned row by row from left to right and from top to bottom, the first scanning direction is from left to right, and the second scanning direction is from top to bottom; and when the liquid crystal molecule groups are scanned column by column from top to bottom and from left to right, the first scanning direction is from top to bottom, and the second scanning direction is from left to right.

The plurality of light-emitting unit groups electrically connected to the drive chips 202 are distributed based on the first scanning direction and the second scanning direction of the plurality of liquid crystal molecule groups. There are many situations in which the drive chips 202 and the light-emitting unit groups are connected and the light-emitting unit groups are arranged in the backlight assembly 20. The various situations are explained respectively through multiple embodiments below.

In some embodiments, the plurality of light-emitting unit groups electrically connected to each drive chip 202 are arranged in a plurality in the first scanning direction and in a single light-emitting unit group in the second scanning direction.

In some embodiments, the display panel is scanned row by row, and all the light-emitting unit groups driven by the drive chip 202 are arranged in a row.

In some embodiments, the display panel is scanned column by column, and all the light-emitting unit groups driven by the drive chip 202 are arranged in one column.

According to the quantity of power supply terminals and the quantity of drive terminals provided in the drive chip 202, all the light-emitting unit groups electrically connected to the drive chip 202 are divided into multiple groups, and the negative electrode of each light-emitting unit group is connected to the same one drive terminal. In each light-emitting unit group, the positive electrode of each light-emitting unit group is connected to each power supply terminal correspondingly.

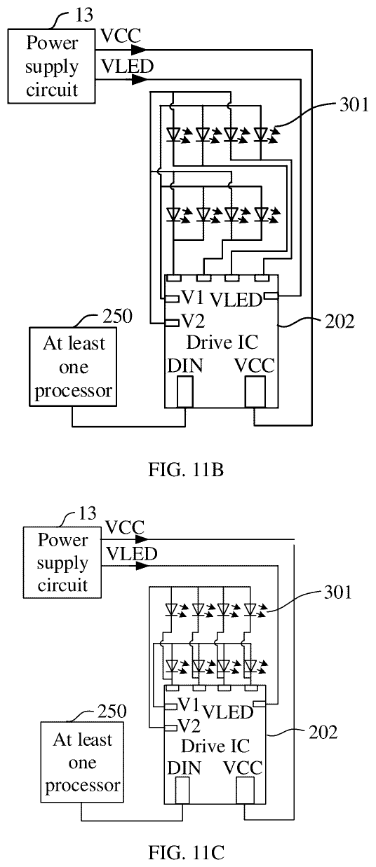

FIG. 11A is a schematic diagram of the connection relationship between a drive chip 202 and light-emitting unit groups. As shown in FIG. 11A, the drive chip 202 is electrically connected to 8 light-emitting unit groups. The drive chip 202 is provided with 4 drive terminals and 2 power supply terminals. The two light-emitting unit groups form a group. The negative electrodes of the two light-emitting unit groups are connected to the same one drive terminal, and the positive electrodes of the two light-emitting unit groups are connected to the two power supply terminals respectively. Among them, different drive terminals correspond to different light-emitting unit groups. For the convenience of description below, the two light-emitting unit groups in the same group are set as the first light-emitting unit group and the second light-emitting unit group, respectively. The first light-emitting unit group is connected to the power supply terminal V1, and the second light-emitting unit group is connected to the power supply terminal V2.

When the drive chip 202 is driving, and the drive chip 202 obtains the drive data of the second light-emitting unit group in each light-emitting unit group, the drive chip 202 outputs a power source signal from the power supply terminal V2 based on the data, and outputs a corresponding drive signal from each drive terminal, so that the second light-emitting unit group in each light-emitting unit group emits light based on the drive signal. When the drive chip 202 obtains the drive data of the first light-emitting unit group in each light-emitting unit group, the drive chip 202 outputs a power source signal from the power supply terminal V1 based on the data, and outputs a corresponding drive signal from each output terminal, so that the first light-emitting unit group in each light-emitting unit group emits light based on the drive signal.

The circuit connection relationship provided in this embodiment can keep the row scanning or column scanning mode of the original backlight assembly unchanged. Only in the process of regulation of each drive chip 202, the luminous effect of the luminous process of a light-emitting unit group electrically connected to a drive terminal in the related art is distributed to two light-emitting unit groups. Compared with the luminous effect in the related art, the luminous regulation process of this embodiment is more precise.

In some other embodiments, the quantity of the plurality of light-emitting unit groups electrically connected to each drive chip in the second scanning direction is at least two, and the quantity of the plurality of light-emitting unit groups electrically connected to each drive chip in the second scanning direction is less than or equal to the quantity of the power supply terminals.

The quantity of the plurality of light-emitting unit groups electrically connected to each drive terminal arranged in the second scanning direction is one.

In some embodiments, the display panel is scanned row by row, all light-emitting unit groups driven by the drive chip 202 are arranged in multiple rows, and multiple light-emitting unit groups electrically connected to each drive terminal are arranged in one row.

In some embodiments, the display panel is scanned column by column, all light-emitting unit groups driven by the drive chip 202 are arranged in multiple columns, and multiple light-emitting unit groups electrically connected to each drive terminal are arranged in one column.

The plurality of light-emitting unit groups connected to the drive chip 202 are divided into a plurality of groups according to the division method of the previous embodiment. The connection method between each light-emitting unit group and the drive chip 202 is the same as that of the previous embodiment and will not be repeated here.

Regarding the arrangement of each group of light-emitting unit groups, in one case, light-emitting unit groups in each group of light-emitting unit groups are arranged in one row, or in another case, light-emitting unit groups in each group of light-emitting unit groups are arranged in at least two rows. Since the negative electrode of one group of light-emitting unit groups is connected to the same drive terminal, each group of light-emitting unit groups can emit light in the same time period. More specifically, in each group of light-emitting unit groups, the light-emitting unit groups cyclically emits light in a preset order within the same time period until the end of the time period.

FIG. 11B is a schematic diagram of an exemplary arrangement of light-emitting unit groups. In FIG. 11B, a group of light-emitting unit groups may include two light-emitting unit groups, and the two light-emitting unit groups are arranged in one row of the backlight assembly. When the drive chip 202 drives the light-emitting unit group to emit light, it can control multiple light-emitting unit groups in the first row to emit light in the same period, and control multiple light-emitting unit groups in the second row to emit light in the same period. When multiple rows of liquid crystal molecules in the display panel are scanned row by row from top to bottom, the start moment of the first row of the light-emitting period is earlier than the start moment of the second row of the light-emitting period, and the delay time length of the start moment of the second row compared to the start moment of the first row is the scanning delay time length of the second row of liquid crystal molecules in the two adjacent rows of liquid crystal molecules compared to the first row of liquid crystal molecules in the two adjacent rows of liquid crystal molecules. When the backlight assembly needs to insert black for the response delay of the liquid crystal molecules, the delay time length is the sum of the scanning delay time length and the black insertion time.

The circuit connection relationship provided in this embodiment can be that a group of drive chips controls multiple rows of light-emitting unit groups to provide backlight to multiple rows of liquid crystal molecules in the display panel row by row, or a group of drive chips controls multiple columns of light-emitting unit groups to provide backlight to multiple columns of liquid crystal molecules in the display panel column by column, which simplifies the processor's calculation and control of the row-by-row delay or column-by-column delay of multiple groups of drive chips.

In some other embodiments, the quantity of the plurality of light-emitting unit groups electrically connected to each drive terminal in the second scanning direction is at least two, and the quantity of the plurality of light-emitting unit groups electrically connected to each drive terminal in the second scanning direction is less than or equal to the quantity of the power supply terminals.

In some embodiments, the display panel is scanned row by row, all light-emitting unit groups driven by the drive chip 202 are arranged in multiple rows, and the light-emitting unit groups electrically connected to each drive terminal are arranged in multiple rows.

In some embodiments, the display panel is scanned column by column, all light-emitting unit groups driven by the drive chip 202 are arranged in multiple columns, and the light-emitting unit groups electrically connected to each drive terminal are arranged in multiple columns.

FIG. 11C is a schematic diagram of another arrangement of light-emitting unit groups. In FIG. 11C, two light-emitting unit groups in one group of light-emitting unit groups are arranged in two rows, and the two rows of light-emitting unit groups connected to the drive chip 202 emit light in the same period. The period during which the two rows of light-emitting unit groups emit light is the scanning period of the two rows of liquid crystal molecules corresponding thereto.

In the circuit connection relationship provided in this embodiment, multiple rows of light-emitting unit groups are utilized to simultaneously provide backlight to multiple rows of liquid crystal molecules in the display panel, or multiple columns of light-emitting unit groups are utilized to simultaneously provide backlight to multiple columns of liquid crystal molecules in the display panel. The control logic is simpler than the aforementioned embodiments and is suitable for display apparatuses that do not have very high requirements on image quality.

In the above three connection relationship diagrams of the drive chip 202 and the light-emitting unit group, there is always a wire jumper situation. In one case, two wires transmitting power source signals are jumper-connected, and in another case, a wire transmitting power source signals and a wire transmitting drive signals are jumper-connected.

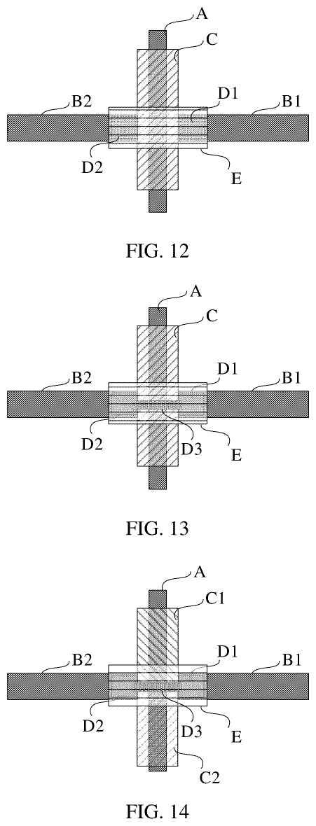

A position relationship of the jumper wire on the light board is shown in FIG. 12. When the horizontal wire needs to jumper the longitudinal wire A, the horizontal wire is divided into two sections B1 and B2 by the wire A. Two pads are set on both sides of the wire A, and the two pads are connected to the wires B1 and B2 respectively. In the related art, in order to solve the problem of wire jumper on the light board, a jumper device is generally set to connect the two pads. Since the quantity of light beads in the light board composed of mini-LEDs or micro-LEDs is large, and the quantity of light-emitting unit groups is also large, the quantity of wires that need to be jumped is also large, resulting in high processing costs of the light board.

In the present application, a wire jumper method is provided. The following is an explanation of the jumper method for two wires that need to be jumped. The wire A is determined as a wire being jumped, and the wire B1 and wire B2 are jumper wires that need to be connected through jumping over the wire A. In one embodiment, the two wires are copper wires, and an insulating layer is coated on the copper wire being jumped, and then a conductive layer is coated on the insulating layer to conduct the jumper wires.

In some embodiments, the conductive layer is a copper paste.

In some other embodiments, the conductive layer is solder paste.

For a printed light board with wire jumper, the side where the device pins are welded is the upper side, and the light board may include copper wires and the insulating layer from bottom to top. The copper wires may include jumper wires and wire being jumped, which are located in the same layer of the printed light board.

The specific arrangement of the insulating layer and the conductive layer in the jumper region is explained below.

In some embodiments, the insulating layer is coated on the outer side of the wire being jumped, and the conductive layer is coated on the side of the insulating layer facing away from the wire being jumped.

In some embodiments, the insulating layer and the conductive layer in the jumper region are arranged as shown in FIG. 12, where the insulating layer C is completely coated on the upper side of the wire A being jumped along the routing direction of the wire A being jumped, and the width of the insulating layer C is greater than the width of the wire A being jumped. A conductive layer E is coated on the insulating layer C, and the conductive layer E connects the pads D1 and D2 correspondingly arranged on the jumper wire B1 and the jumper wire B2.

In some embodiments, solder resist ink is coated on the wires of the printed light board to protect the wires and prevent the solder paste from affecting the wires during the welding process. The printed light board is desoldered at both sides of the wire being jumped and at the end points of the jumper wire, so that the end points of the jumper wire are exposed, and the exposed wires are solder pads.

In some embodiments, solder resist ink is coated on the wire being jumped as an insulating layer.

In some embodiments, the conductive layer covers the two pads and the insulating layer between the pads.

In some embodiments, taking the side where the device pins are welded as the upper side, when producing a printed light board, in the jumper region, a conductive layer, an insulating layer and a wire are stacked from bottom to top, the insulating layer wraps the wire A being jumped, and the conductive layer is connected to the jumper wires placed on both sides of the wire being jumped.

In some embodiments, the configuration of the insulating layer and the conductive layer in the jumper region is shown in FIG. 13, where the insulating layer C is completely coated on the upper side of the wire A being jumped along the routing direction of the wire A being jumped. An adsorption material is coated on the insulating layer C, and the conductive layer E is coated on the adsorption material. The coating region of the adsorption material is D3, and the adsorption material is an insulating material.

In some embodiments, the adsorbent material is applied along at least one predetermined jumper path.

The coating region D3 of the adsorbent material coated along a preset jumper path is shown in FIG. 13.

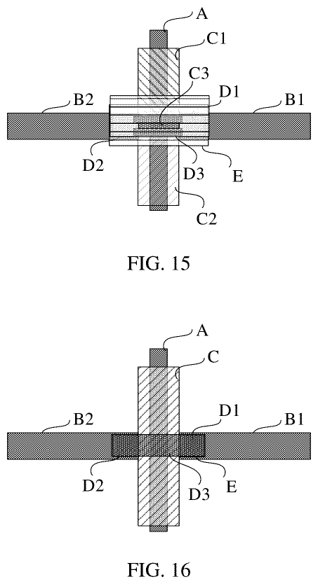

The coating region D3 of the adsorption material along a plurality of preset jumper paths (e.g., two) is shown in FIG. 15.

In some embodiments, the jumper wire B1 is provided with a pad D1 at one end close to the wire A being jumped, and the jumper wire B2 is provided with a pad D2 at one end close to the wire A being jumped. The region where the pad is located may include a first exposed region and a second exposed region, and one terminal of the adsorption material covers the first exposed region of the corresponding pad.

In some embodiments, the conductive layer E is further coated on the second exposed region.

When the material of the conductive layer E is solder paste, the solder paste is heated and soldered on the second exposed regions corresponding to the two pads and on the adsorption material, so that a conduction path is formed between the jumper wires B1 and B2 after the solder paste is melted.

Due to the setting of the adsorption material, not only the amount of solder paste coated in the region D3 is increased, but also the coating area is increased, thereby reducing the impedance in the jumper region. Therefore, the larger the surface area of the adsorption material, the larger the amount of solder paste coated. The coating region D3 of the adsorption material shown in FIG. 15 is larger than the coating region of the adsorption material shown in FIG. 13, the coating area is also larger, and the amount of solder paste coated is large, so the impedance in the jumper region shown in FIG. 15 is smaller than the impedance in the jumper region shown in FIG. 13.

In some embodiments, the conductive layer E is further coated on the insulating layer surrounding the adsorption material, so that the width of the conductive layer E is greater than the width of the pad, which helps to increase the amount of solder paste coated between the two pads.

The conductive layer E has a width direction perpendicular to the connection direction of the two pads, and a width direction of the pad is consistent with the width direction of the conductive layer E.

In some embodiments, solder resist ink is not printed on the lower side of the adsorption region in the coating region D3, so that the adsorption material is in direct contact with the copper foil or the plate body on the printed light board to increase the adhesion of the adsorption material, thereby increasing the adhesion of the conductive layer on the printed light board.

When there is only one coating region D3 in the jumper region, the insulating layer provided on the wire A being jumped can be divided into three insulating coating regions C1, D3 and C2 along the routing direction of the wire, where solder resist ink can be coated in the insulating coating regions C1 and C2. The distribution of the insulating coating regions can be shown in the example of FIG. 14.

When there are multiple coating regions D3 in the jumper region, the regions coated with solder resist ink and the regions coated with adsorption material are placed at intervals.

Taking the case where there are two coating regions D3 in the jumper region as an example, the distribution of the coating regions is explained. As shown in the example of FIG. 15, in the jumper region, along the routing direction of the wire A being jumped from top to bottom, five insulating coating regions C1, D3, C3, D3 and C2 may be included in sequence, where the insulating coating regions C1, C3 and C2 may be coated with solder resist ink, and the insulating coating regions D3 may be coated with adsorption material.

In some embodiments, the configuration of the insulating layer and the conductive layer in the jumper region is shown in FIG. 16, where the insulating layer C is completely coated on the upper side of the wire A being jumped along the routing direction of the wire A being jumped. An adsorption material is coated on the insulating layer C. and the adsorption material is a conductive material, and the adsorption material makes a conduction between the jumper wires B1 and B2.

In some embodiments, the jumper wire B is provided with a pad D1 at one end close to the wire A being jumped, and the jumper wire B2 is provided with a pad D2 at one end close to the wire A being jumped, and both ends of the adsorption material cover the corresponding pads.

In some embodiments, when the first jumper wire B1 and the second jumper wire B2 are not arranged in the same row, the coating direction of the wire layer is the direction of the straight line connecting the first pad D1 and the second pad D2.

In some embodiments, the adsorption material is coated according to a set coating position during the light board printing process, and the adsorption material is solidified through a curing operation.

In some embodiments, during the welding process of the light board, a conductive layer is printed on the adsorption material, and the conductive layer is attached to the adsorption material through the original heating welding process.

The above wire jumper method simplifies the subsequent circuit board processing cost without significantly increasing the cost, so as to realize the circuit connection method of the backlight assembly provided in the present application.

More specifically, in a printed circuit board, the signals transmitted by the wires are different, and the corresponding wire widths are also different. Generally, the width of the wire transmitting the power source signal is greater than the width of the wire transmitting the drive signal.

The following takes an example where a drive chip including four drive terminals and two power supply terminals drives 8 light-emitting unit groups to explain the wire connection relationship between the light-emitting unit groups and the drive chip.

In the wire jumper schematic diagram shown in FIG. 11A, the horizontal wires are wires for transmitting power supply signals of multiple light-emitting unit groups, and the longitudinal wires are wires for transmitting power supply signals of a single light-emitting unit group. On the basis of ensuring stable transmission of electrical signals, the horizontal wires are thicker than the bus wires to save the printing cost of the wires.

In this case, the wire of narrower width (longitudinal wire) can be determined as the wire being jumped, and the wire of wider width (horizontal wire) can be determined as the jumper wire. Since the width of the wire being jumped is narrower and the distance between the pads on both sides of the wire being jumped is smaller, less copper paste is used during printing, which can reduce the printing cost of the copper paste.

Since the impedance of copper paste is relatively large, the influence on the value of the current transmitted on the wire is relatively small when the wire used to transmit power is connected using copper paste. If the copper paste is connected to the wire that transmits the drive signal, the impedance of the copper paste may significantly reduce the current value of the drive signal, resulting in abnormal driving process.

In the wire jumper schematic diagram shown in FIG. 11B, the horizontal wire is a wire for transmitting power supply signals for multiple light-emitting unit groups, the first and second longitudinal wires from the left are wires for transmitting power supply signals for multiple light-emitting unit groups, and the remaining longitudinal wires are wires for transmitting the power supply signal for a single light-emitting unit group. The widths of the first and second wires from the left are equal to the width of the horizontal wire, and the width of the horizontal wire is greater than the widths of the remaining longitudinal wires.

For the jumper connection of two wires of the same width, any one wire can be selected as the wire being jumped, and the other wire can be used as the jumper wire. Regardless of which wire is used as the jumper wire, the corresponding PCB manufacturing cost is the same, and the impedance effect of the coated copper paste on the jumper wire is the same.

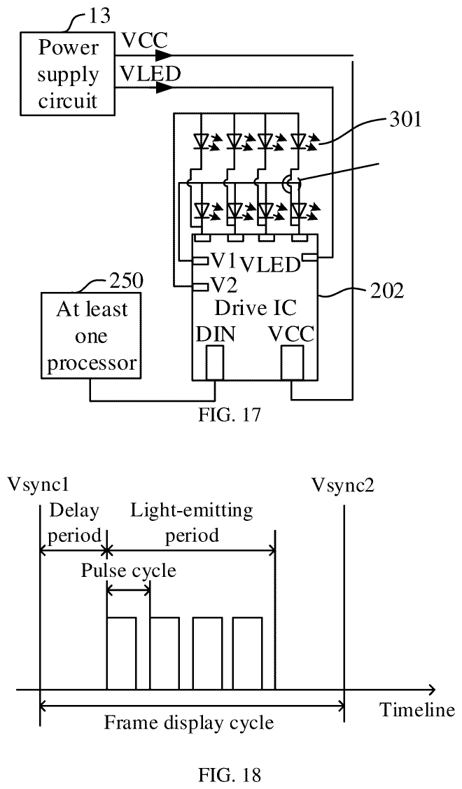

For the jumper connection of two wires of different widths, the jumper connection is performed according to the jumper method shown in FIG. 11A. The jumper method of the jumper connection point wire can refer to that shown in FIG. 17. The longitudinal wire is used as the wire A being jumped, on which an insulating layer is coated. The horizontal wires B2 and B1 are used as jumper wires, and copper paste is coated between the pad D2 connected to the horizontal wire B2 and the pad D1 connected to the horizontal wire B1.

In the wire jumper schematic diagram shown in FIG. 11C, the horizontal wire is a wire for transmitting power supply signals of multiple light-emitting unit groups, and the longitudinal wire is a wire for transmitting the power supply signal of a single light-emitting unit group, and each longitudinal wire jumps over the second horizontal wire. The jumper wire schematic diagram is shown in FIG. 17. The jumper method of the jumper connection point has been explained in the embodiment shown in FIG. 11B, and will not be repeated here.

The method for controlling the backlight assembly in the display apparatus is explained below. FIG. 18 is a waveform diagram of the drive data output by the processor for the backlight assembly shown in FIG. 4 in the related art. As shown in FIG. 18, in response to the frame start signal Vsync1, the processor determines the delay time length of the light-emitting unit group driven by the drive chip, thereby determining the light-emitting period of the light-emitting unit group. During the light-emitting period, the processor obtains the backlight data from the obtained display data, and generates the drive data based on the backlight data.

In some embodiments, the drive data may include a pulse signal segment, and the pulse signal segment may include a plurality of continuous pulse signals, the pulse signals having the same pulse cycle. The processor determines the amplitude and duty ratio of the pulse signal segment based on the backlight data.

Each drive chip in the backlight assembly obtains drive data from the processor, and generates a drive signal based on the drive data to drive the light-emitting unit group to emit light.

In some embodiments, when the drive data may include a pulse signal segment, the drive chip determines the amplitude of the current provided to the light-emitting unit group based on the amplitude of the pulse signal.

In a display cycle of one frame, the brightness of the light-emitting unit group corresponding to the drive terminal is adjusted by adjusting the quantity of pulses output by the drive terminal.

The light-emitting unit group determines the luminous brightness based on the magnitude and time length of the current in the drive chip obtained by it.

When the connection relationship of the backlight assembly of the display apparatus is the connection relationship of the backlight assembly provided in the present application, the processor can no longer drive the light-emitting unit group to emit light correctly based on the waveform diagram shown in FIG. 18, and the processor needs to provide corresponding drive signals for multiple light-emitting unit groups connected to the same output terminal.

The processor 250 can be configured to obtain backlight data from the display data, and based on the backlight data, provide multiple pulse signal segments within the light-emitting period within each frame display cycle. The pulse signal segments correspond to multiple power supply periods, and the pulse signal segments correspond to multiple light-emitting unit groups connected to the power supply terminals.

The drive circuit 201 may be configured to drive the light-emitting unit group corresponding to the pulse signal segment to emit light based on the pulse signal segment transmitted by the processor.

More specifically, the processor 250 obtains the pulse cycle corresponding to each drive terminal; and the pulse cycle is the pulse cycle used to drive the light-emitting unit group when the drive terminal of the drive chip is connected to one light-emitting unit group, that is, the pulse cycle shown in FIG. 18. The processing method corresponding to FIG. 20 is the same. The processor determines the light emission duty ratio and amplitude of the pulse signal in the pulse cycle of the current frame based on the backlight data.

Based on the light emission duty ratio and amplitude determined above, the processor divides each pulse cycle into a preset quantity of pulse sub-cycles (i.e., power supply periods) within the light-emitting period. The power supply periods of the preset quantity correspond to multiple power supply terminals of each drive chip. The power supply periods of the preset quantity are arranged within each pulse cycle of the display period according to a preset power supply sequence of the multiple power supply terminals.

In each power supply period, the drive chip outputs a pulse signal segment, the light emission duty ratio of the pulse signal segment in the pulse sub-cycle in which it is located is the same as the duty ratio of the pulse signal in the pulse cycle, and the amplitude of the pulse sub-signal is the same as the amplitude of the pulse signal. The pulse signal segment can be a single pulse signal or multiple pulse signals, which is not specifically limited here.

The drive chip supplies power to the corresponding multiple light-emitting unit groups through each power supply terminal based on a preset power supply sequence. In each pulse cycle, for each power supply terminal, the drive chip drives the corresponding light-emitting unit group to emit light based on the pulse signal segment in the power supply period corresponding to the power supply terminal.

In one embodiment, the pulse signal segment may include at least one first level signal and/or at least one second level signal.

The drive chip may be configured to, in each power supply period, output current from the drive terminal based on the first level signal in the pulse signal segment, so as to drive the light-emitting unit group electrically connected to the drive terminal to emit light; and/or, in each power supply period, output no current from the drive terminal based on the second level signal in the pulse signal segment, so as to drive the light-emitting unit group electrically connected to the drive terminal not to emit light.

In some embodiments, since the liquid crystal molecules in the display panel are scanned in a preset order, the light-emitting unit group in the backlight assembly also emits light in an order corresponding to the above order. Taking the liquid crystal molecules in the display panel that are scanned row by row in an order from top to bottom as an example, the light-emitting unit group in the backlight assembly also provides backlight row by row, and the processor 250 can be configured to transmit the drive data of the light-emitting unit groups row by row according to the delay time length corresponding to each row of the light-emitting unit groups after obtaining the frame scanning signal.

The processor 250 may also be configured to obtain a frame start signal and a delay time length of a liquid crystal molecule group corresponding to a light-emitting unit group.

The start moment of the display cycle corresponding to the light-emitting unit group is determined based on the frame start signal and the delay time length. The delay time length of the liquid crystal molecule group may include the scanning start moment of the current row of liquid crystal molecules, the delay time length relative to the acquisition moment of the frame start signal, and the sum of the frame start signal and the delay time length is the start moment of the display cycle corresponding to the current light-emitting display group.

The following uses the circuit connection method shown in FIG. 11C as an example to explain the waveform of the drive data output by the processor. Since in FIG. 11C, the negative electrodes of the light-emitting unit groups in the same group are connected to the same one drive terminal, the delay periods of the two rows of light-emitting unit groups compared to the moment at which the frame start signal Vsync is obtained are the same. In FIG. 11C, since the drive chip is provided with two power supply terminals, each pulse cycle can be evenly divided into two pulse sub-cycles. When the drive chip shown in FIG. 11C provides power source signals at the power supply terminals, it always provides the power source signals in the order of the power supply terminal V2 and the power supply terminal V1 sequentially. Then, the waveform diagram of the drive data provided by the processor is shown in FIG. 19.

In each pulse sub-cycle, the duty ratio of the pulse signal in the pulse sub-cycle is the same as the duty ratio shown in FIG. 18, and the amplitude is also the same as that shown in FIG. 18. When the drive chip obtains the first pulse signal in each pulse cycle, it controls the power supply terminal V2 to output the power source signal VLED, so that the positive electrode of the first row of light-emitting unit groups obtains the power source signal, and the drive chip then outputs a drive signal from the drive terminal based on the pulse signal, so that the light-emitting unit group in the first row emits light. When the drive chip obtains the second pulse signal in each pulse cycle, it controls the power supply terminal V2 to stop providing the power source signal, controls the power supply terminal V1 to provide the power source signal, and then outputs the drive signal based on the drive data, so that the first row of light-emitting unit groups does not emit light, and the second row of light-emitting unit groups emit light. This cycle repeats until the light-emitting period ends.

Since the power supply source of the light-emitting unit group connected to the drive chip is provided by the drive chip itself, during the driving process of the drive chip, it is only necessary to calibrate the pulse sequence of the drive signals corresponding to the multiple light-emitting unit groups connected to the same one drive terminal within each frame display cycle. In the related art, PM driving uses a unified power supply method to provide power source signals for the left and right light-emitting unit groups in the backlight assembly, which has high requirements on the power supply accuracy of the power source signal and requires the pulse sequence of all drive chips in the drive circuit to be calibrated. Therefore, the control method of the present application simplifies the control difficulty.

In some embodiments, the power source switch in the drive chip is a controllable transistor, such as CMOS. Since the on and off process of the controllable transistor also generates a large power consumption, the power consumption used in the on process is relatively small, therefore, the power consumption of the drive chip can be reduced by reducing the quantity of times the controllable transistor is turned on and off.

It is set that within the display period of each frame, the power supply terminal that is powered last of any pulse cycle is the same as the power supply terminal that is powered first of the next pulse cycle, and the power supply terminal that is powered last of any pulse cycle remains powered until the second power supply terminal of the next pulse cycle is powered.

For the circuit shown in FIG. 11C, when the drive chip drives the light-emitting unit group to emit light during the light-emitting period, the two power supply terminals can be controlled to provide power source signals in the order of power supply terminal V2 and power supply terminal V1 sequentially within the first pulse cycle, and the drive signals can be provided in this order to sequentially drive the first row of light-emitting unit groups and the second row of light-emitting unit groups to emit light. Within the second pulse cycle, the power source switch corresponding to the power supply terminal V1 is controlled not to be turned off at the end of the first pulse cycle, and then within the second pulse cycle, the two power supply terminals are controlled to provide power source signals in the order of power supply terminal V1 and power supply terminal V2 sequentially, and the provision of the drive signals is adjusted in this order to sequentially drive the second row of light-emitting unit groups and the first row of light-emitting unit groups to emit light; and at the end of the second pulse cycle, the power source switch corresponding to the power supply terminal V2 is kept in the on state, so that within the third pulse cycle, the two power supply terminals are controlled to provide power source signals in the order of power supply terminal V2 and power supply terminal V1 sequentially to sequentially drive the first row of light-emitting unit groups and the second row of light-emitting unit groups to emit light, and so on until the end of the light-emitting period. The waveform generated by the processor 250 is shown in FIG. 20.

In some embodiments, considering the unstable state period of the liquid crystal molecule group at the start period of the display cycle, the display cycle is divided into a black insertion period and a light-emitting period. The black insertion period may include an unstable state period of the liquid crystal molecules.

Among them, the unstable period of the liquid crystal molecule group is during the angle adjustment process of the liquid crystal molecules from the deflection angle applied when displaying the image of previous frame to the deflection angle applied when displaying the image of current frame. When the rotation angle is greater than or equal to the product of the preset ratio and a deflection angle difference, the liquid crystal molecules are determined to be in a stable period. When the rotation angle is less than the product of the preset ratio and the deflection angle difference, the liquid crystal molecules are determined to be in an unstable period.

The processor controls the light-emitting unit group not to emit light during the unstable period of the liquid crystal molecule group to achieve a black insertion operation, thereby preventing the occurrence of a ghosting phenomenon between two images of adjacent frames.

In the related art, in order to improve the image smoothness and clarity of the display apparatus, some liquid crystal display apparatuses will use variable refresh rate (VRR) technology, that is, the display cycle of the display panel and backlight assembly in the display apparatus according to the current frame quantities effect is dynamically adjusted to adjust the refresh rate of the image display. The processor 250 controls the backlight assembly to perform black insertion operation only in the start period of a frame image display. Under different refresh rates, the black insertion time is the same, but the light-emitting time length is different, which will cause the image to flicker when the refresh rate changes.

To address the above problem, the processor 250 can also be configured to split the display cycle of the light-emitting unit group into a black insertion period and at most two light-emitting periods, not output drive data during the black insertion period, and output drive data during the light-emitting period, so that the backlight assembly maintains a consistent average brightness in each frame of the image display based on the control signal, thereby reducing the flickering phenomenon in the image display.

In some embodiments, when the refresh rate applied to the current frame image is equal to the maximum refresh rate of the display panel, the processor 250 maintains the original wave-generating state unchanged. Taking the waveform shown in FIG. 19 as an example, when the current refresh rate is the maximum refresh rate of the display panel, the waveform output by the processor 250 is still the waveform shown in FIG. 19.

In some embodiments, when the refresh rate applied to the current frame image is less than the maximum refresh rate of the display panel, the processor 250 splits the light-emitting period into a first light-emitting sub-period and a second light-emitting sub-period, where the first light-emitting sub-period is the same as the light-emitting period corresponding to the maximum refresh rate, and the amplitude in the second light-emitting sub-period is a product of a preset ratio and the amplitude in the first light-emitting sub-period.

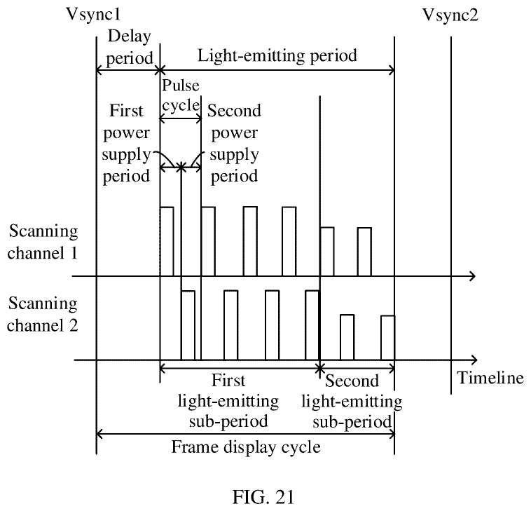

Taking the waveform shown in FIG. 19 as an example, when the refresh rate is less than the maximum refresh rate of the display panel, the waveform output by the processor 250 is shown in FIG. 21. The amplitude in the second light-emitting sub-period is the product of the amplitude of the first light-emitting sub-period and the black insertion ratio, where the black insertion ratio is the quotient of the black insertion time length divided by the sum of the black insertion time length and the first light-emitting sub-period in the display cycle.

In some other embodiments, the processor may also repeat the wave transmission according to the wave transmission situation corresponding to the maximum refresh rate. When the remaining time length after removing the time length of at least one light-emitting period corresponding to the maximum refresh rate is less than the time length of the light-emitting period corresponding to the maximum refresh rate, the duty ratio of the pulse wave in the remaining time length is adjusted to the black insertion ratio.

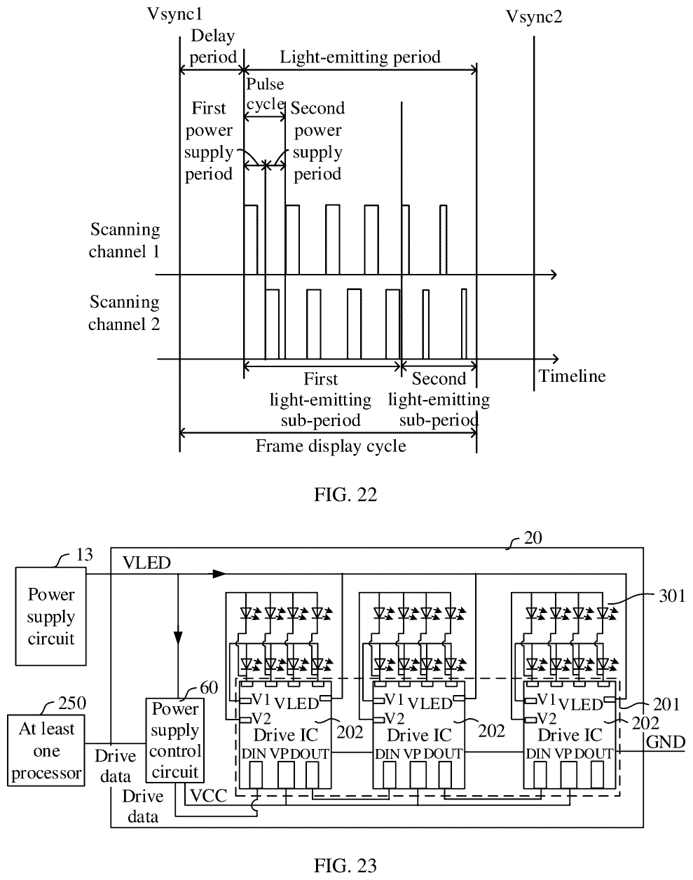

Taking the waveform shown in FIG. 19 as an example, when the refresh rate is less than the maximum refresh rate of the display panel, the waveform output by the processor 250 is shown in FIG. 22. The time length of each pulse in the second light-emitting sub-period is the product of the time length of the pulse in the first light-emitting sub-period and the black insertion ratio, where the black insertion ratio is the quotient of the black insertion time length divided by the sum of the black insertion time length and the first light-emitting sub-period in the display cycle.

In some embodiments, the processor 250 adopts joint dimming, that is, in the process of displaying a frame of image, in the drive data provided by the processor 250, the amplitudes of the currents are the same, and different duty ratios correspond to different light-emitting time lengths, thereby corresponding to different numerical values in the backlight data. Among them, the larger the numerical value in the backlight data, the brighter the brightness provided by the light-emitting unit group in the backlight assembly, and the larger the duty ratio in the drive data provided by the processor for the light-emitting unit group; the smaller the numerical value in the backlight data, the smaller the duty ratio in the drive data provided by the processor for the light-emitting unit group.

When the processor 250 uses joint dimming to display different frame images, the amplitudes in the drive data generated based on the backlight data are not completely the same. The application of joint dimming can make the backlight provided by the backlight assembly controlled by the control method provided in the present application more delicate, and the display apparatus using the backlight assembly has better display quality.

In some embodiments, the processor 250 obtains the power supply state of the light-emitting unit group through the drive circuit, and controls the power supply circuit to adjust the voltage value provided by it based on the power supply state. In order to simplify the circuit structure, the current-voltage relationship of the light-emitting unit group is stored in advance in the processor 250 or a memory accessible thereto. The image data may include backlight data, and the current-voltage relationship of the light-emitting unit group represents the value of the current flowing through the light-emitting sub-unit when different power supply voltage values are applied to the light-emitting sub-unit.

In some embodiments, based on the backlight data, drive data corresponding to each light-emitting sub-unit is generated; the drive data may include a current value and a duty ratio; and the current values corresponding to the light-emitting sub-units are the same.

In some embodiments, based on the current-voltage relationship, a power supply voltage value corresponding to the current value is determined, and a power supply voltage having a power supply voltage value corresponding to the target current value is output to the light-emitting unit group.

In some embodiments, when determining the current-voltage relationship of the light-emitting unit group, the processor determines the minimum power supply voltage that can be provided by the power supply circuit, and determines the current value at which each light-emitting unit group is in an overvoltage state based on the minimum power supply voltage as the first sampling point of the fitting relationship.

The processor controls the drive circuit to provide at least one preset current value, and adjusts the power supply voltage so that the voltage value is the minimum voltage value of the overvoltage of each light-emitting unit group.

Based on the above multiple current-voltage sampling points, the current-voltage relationship is fitted, so that the power supply circuit no longer needs to obtain the feedback signal related to the light-emitting unit group from the drive circuit when determining the power supply voltage, thereby no longer occupying the transmission path of the drive data or setting a separate data line, and ensuring the transmission rate of the drive data and the simplicity of the circuit structure. Moreover, since the current-voltage relationship of the light-emitting sub-unit is pre-fitted, the consistency of the backlight circuit based on the joint dimming ensures the accuracy of determining the power supply voltage, thereby ensuring the display accuracy.

In some embodiments, a power supply control chip 251 is further provided in the backlight assembly. The power supply control chip 251 is respectively connected to the power supply output terminal of the power supply circuit, the power supply terminal of the drive circuit, and the output terminal of the processor 250. The circuit connection relationship is shown in FIG. 23. The power supply control chip 251 can be configured to supply power to the corresponding drive chip and output the drive signal when receiving the drive signal, so that the drive chip drives the light string to emit light based on the drive signal.

The power supply control chip 251 can also be configured to stop supplying power and providing drive signals to the corresponding drive chip when no drive signal is received, so that the drive chip stops driving the light string to emit light, thereby reducing leakage current and reducing losses during the standby process of the display apparatus.

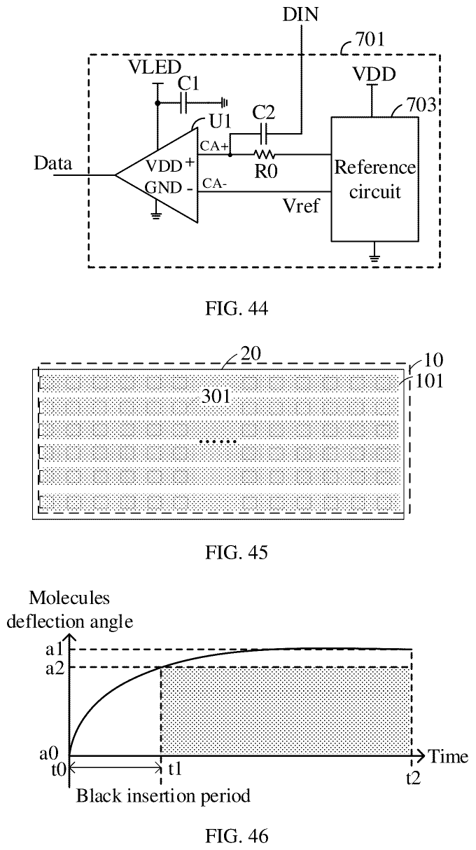

FIG. 44 is a schematic diagram of a circuit structure of a power supply source according to some embodiments.

In some embodiments, the power supply circuit 13 includes a filter and rectifier circuit 131, which is configured to obtain AC power, filter the AC power, perform voltage rectification, and output a DC signal.

In some embodiments, the power supply circuit 13 includes a power factor correction (PFC) circuit 132, which is configured to perform power factor compensation and correction on the DC signal based on the power generated by the current load to improve the utilization rate of electric energy. The output electric signal is a corrected electric signal.

In some embodiments, the power supply circuit 13 includes an LLC isolation voltage conversion circuit 133, which is configured to perform voltage conversion on the corrected electrical signal after power factor correction to output the voltage with a value required for the normal operation of the mainboard 80, the accompanying audio and backlight assembly.

In some embodiments, the mainboard 80 includes at least one of a tuner, a communicator, a detector, an external device interface, a processor, an audio output interface, a memory, or a user interface.

In some embodiments, the LLC isolation voltage conversion circuit 133 includes at least two LLC circuits.

Taking the LLC isolation voltage conversion circuit 133 including two LLC circuits as an example, its power supply process is explained.

The LLC isolation voltage conversion circuit 133 includes a first LLC circuit and a second LLC circuit. The first LLC circuit is a circuit for powering the mainboard 80 and the accompanying sound circuit, and the second LLC circuit is a circuit for powering the backlight assembly 20. The first LLC circuit generates an electrical signal such as 12V or 16V/24V, etc., based on the output electrical signal of the power factor correction circuit 132, and the second LLC circuit generates an electrical signal of 10V to 15V based on the output electrical signal of the power factor correction circuit 132.

The two LLC circuits perform dimming separately, and the second LLC circuit can be controlled not to provide an electrical signal when the display apparatus is in standby mode, so that the backlight assembly will not generate loss caused by leakage current during the standby process.

However, with the complexity of the local dimming function, in order to improve the response speed of the front-end power supply to the current and voltage of the backlight and reduce the power supply cost, in the related art, stepped power supply is applied, that is, the high-voltage side circuit of the LLC isolation voltage conversion circuit 133 corresponds to at least two low-voltage side circuits thereof. Through the transformer voltage conversion, the voltages obtained on the low-voltage side are different, and the output terminals provide electrical signals with different voltage values. The circuit structure is shown in the LLC isolation voltage conversion circuit 133 of FIG. 44.

In the circuit structure shown in FIG. 44, an LLC isolation voltage conversion circuit 133 is provided with a high-voltage side circuit and multiple low-voltage side circuits. The multiple low-voltage side circuits all obtain electrical energy from the high-voltage side circuit through a transformer. When a power supply signal is obtained at the input terminal of the high-voltage side circuit, corresponding voltages with values can be provided to the mainboard 80, the accompanying audio, and the backlight assembly 20 at the same time.

In some embodiments, the backlight assembly 20 includes a drive circuit and a light board, and the LLC isolation voltage conversion circuit 133 is configured to provide a power source signal VLED to the drive circuit and provide a power source signal VCC to the light board.

Since the components and circuit structures in the drive circuit and the light board are different, the voltage values of the power source signals used by the drive circuit and the light board are different. Generally, two low-voltage side circuits in the LLC isolation voltage conversion circuit 133 are required to provide power source signals.

In some embodiments, in order to simplify the circuit structure, a low-dropout regulator (LDO) may be added to the backlight assembly 20, and its circuit connection relationship in the backlight assembly 20 is shown in FIG. 25.

In the backlight assembly shown in FIG. 25, the input terminal of the low-dropout regulator 40 is electrically connected to the output terminal of the power supply circuit 13, and the output terminal thereof is electrically connected to the power source terminal of the drive chip 202 in the drive circuit. The low-dropout regulator 40 is configured to convert the power source signal VLED into the power source signal VCC. Therefore, only a low voltage side circuit that provides a power source signal for the backlight assembly needs to be set in the LLC isolation voltage conversion circuit.

When the display apparatus is in standby mode, since the mainboard requires a power source signal, but the drive chip in the backlight assembly does not require a power source signal, the LLC isolation voltage conversion circuit cannot be completely turned off, and the backlight assembly can still obtain a power source signal.

Since the low-dropout regulator 40 arranged before the power supply terminal of each drive chip can only perform voltage changes but cannot control the turned-on and turned-off of the electrical signal, even when the backlight assembly 20 stops emitting light, the drive chip 202 in the backlight assembly 20 still has leakage current. Even if the leakage current of each drive chip is small, the large quantity of drive chips 202 in the micro-LED backlight assembly 20 will still cause the backlight assembly 20 to generate a considerable leakage current when the display apparatus is in standby mode, thereby causing non-negligible power loss during the standby process.

To this end, the embodiments of the present application provide a power supply control circuit, a drive chip and a display apparatus. The power supply control circuit is set between the drive circuit and the processor of the display apparatus, so that when the drive circuit drives the light board to emit light, the power supply control circuit supplies power to the drive chip based on the drive data provided by the processor, and provides drive data so that the drive chip drives the light string in the backlight assembly to emit light. During the standby process of the display apparatus, when the power supply control circuit obtains a low power consumption command, it stops providing backlight to the drive chip, so that the drive chip can reduce leakage current and reduce losses during the standby process of the display apparatus.

The technical solution of the present application is described in detail below in conjunction with specific embodiments. The following specific embodiments can be combined with each other, and the same or similar concepts or processes may not be described in detail in some embodiments.

In some embodiments, the display apparatus 200 includes a backlight assembly 20, and the backlight assembly 20 includes at least one power supply control circuit 60. An input port of the power supply control circuit 60 is electrically connected to the processor 250, a first output terminal of the power supply control circuit 60 is electrically connected to a power supply terminal of a drive circuit, and a second output terminal of the power supply control circuit 60 is electrically connected to a data input terminal of the drive circuit.

In some embodiments, the power supply control circuit 60 is configured to supply power to the drive circuit and output the drive data when receiving the drive data provided by the processor 250 from the input interface, so that the drive circuit drives the light-emitting unit group to emit light based on the drive data.

The power supply control circuit 60 is configured to stop supplying power to the drive circuit and providing drive data when receiving a low power consumption command from the input interface, so that the drive circuit stops driving the light-emitting unit group to emit light. The low power consumption command can be an operation to stop sending data, or can be control data for controlling low power consumption.

In some embodiments, the drive circuit includes at least one drive chip 202, the power supply control circuit 60 corresponds to at least one drive chip 202, the first output terminal of the power supply control circuit 60 is electrically connected to the power source terminal VCC of each drive chip 202, and the second output terminal is electrically connected to the data input terminal Din of each drive chip 202.

In some embodiments, the power supply control circuit 60 is configured to supply power to the corresponding drive chip 202 and output the drive data when receiving the drive data provided by the processor 250, so that the drive chip 202 drives the light-emitting unit group to emit light based on the drive data.

The power supply control circuit 60 is also configured to stop supplying power and providing drive data to the corresponding drive chip 202 when the drive data provided by the processor 250 is not received, so that the drive chip 202 stops driving the light-emitting unit group to emit light.

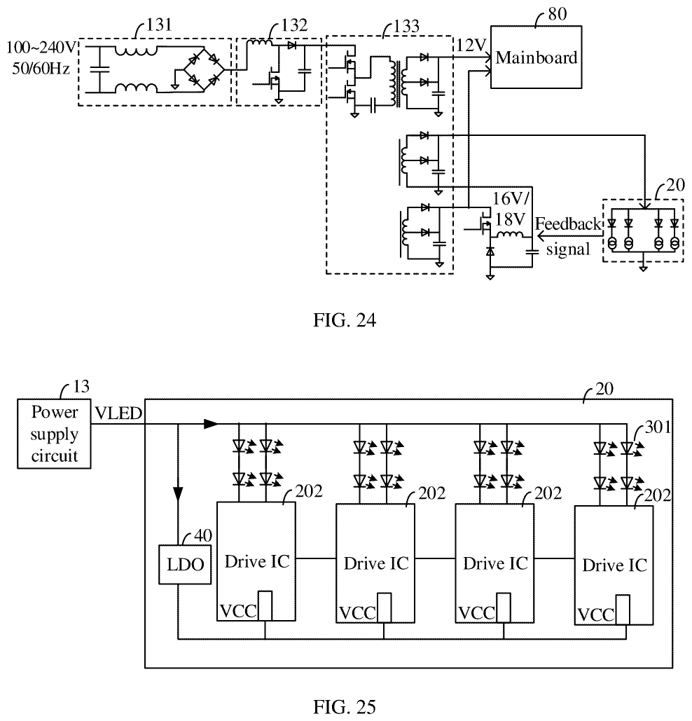

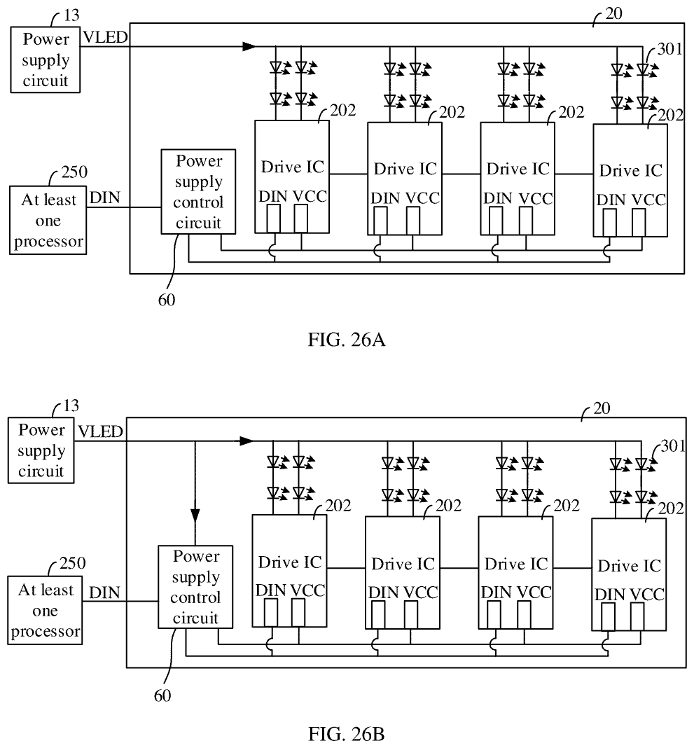

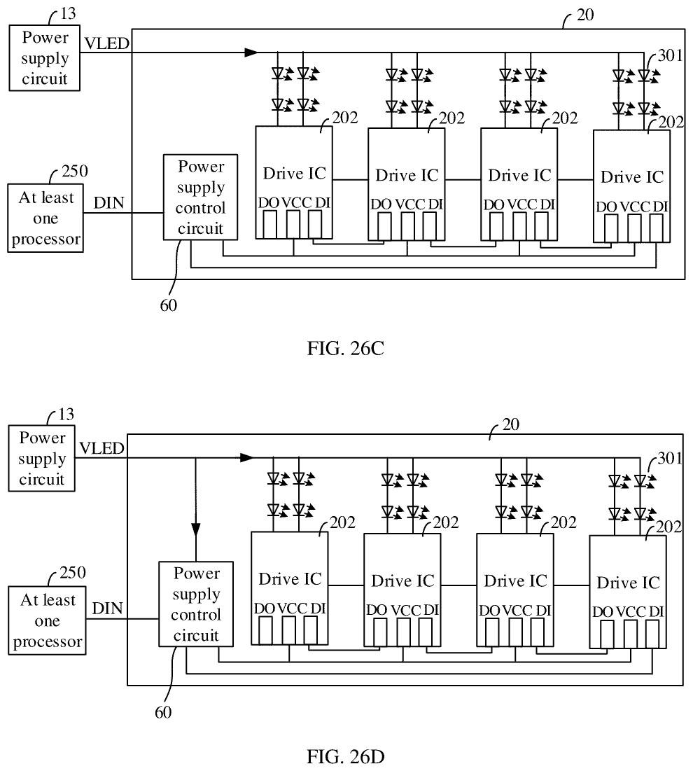

In some embodiments, at least one drive chip 202 corresponding to the power supply control circuit 60 is electrically connected in parallel. The schematic diagram of the electrical connection relationship is shown in FIGS. 26A and 26B. The second output terminal of the power supply control circuit 60 is electrically connected to the data input terminal Din of each drive chip 202.

Each drive chip 202 is provided with address information, and the power supply control circuit 60 is configured to broadcast data including the address information to the data line. The drive chip 202 corresponding to the address information obtains drive data from the data line to drive its corresponding light-emitting unit group to emit light.

In some other embodiments, at least one drive chip 202 corresponding to the power supply control circuit 60 is electrically connected in series. The connection relationship diagram is shown in FIGS. 26C and 26D. The drive chip 202 is provided with an input terminal D1 and an output terminal DO. The data input terminal D1 of the drive chip 202 located in the first position is electrically connected to the output terminal of the processor 250, and the data input terminal D1 of other drive chips 202 is electrically connected to the data output terminal DO of the previous drive chip 202. Each drive chip 202 is configured to obtain drive data from its input terminal D1, and after obtaining its corresponding drive data segment therefrom, output the drive data from its output terminal DO.

In some embodiments, the power supply control circuit 60 is configured to supply power to a corresponding drive chip based on the drive data when receiving the drive data, and output the drive data after a preset time length.

In some embodiments, the power supply control circuit 60 is further configured to obtain a power source signal, and when the voltage values of the power source signal and the power supply signal of the drive chip 202 are inconsistent, convert the voltage value of the power source signal into the voltage value of the power supply signal.

That is to say, when the control signal is obtained, the power supply control circuit 60 determines whether it needs to supply power to the drive chip and transmit data based on the control signal. When it is determined that power needs to be supplied to the drive chip, if necessary, corresponding voltage conversion is required to enable it to output the working voltage required by the drive chip. After obtaining the power supply signal, the drive chip can perform power-on initialization and other operations. The time length of the above operation is less than the preset time length to ensure that the drive chip is stably powered on before obtaining the drive data transmitted by the processor, so as to prevent the drive chip from obtaining incomplete drive data due to power supply delays and other situations, affecting the backlight brightness, thereby affecting the display effect of the display apparatus.

In some embodiments, the power supply control circuit 60 may be integrated into a power supply control chip or may be a discrete circuit, which is not specifically limited here.

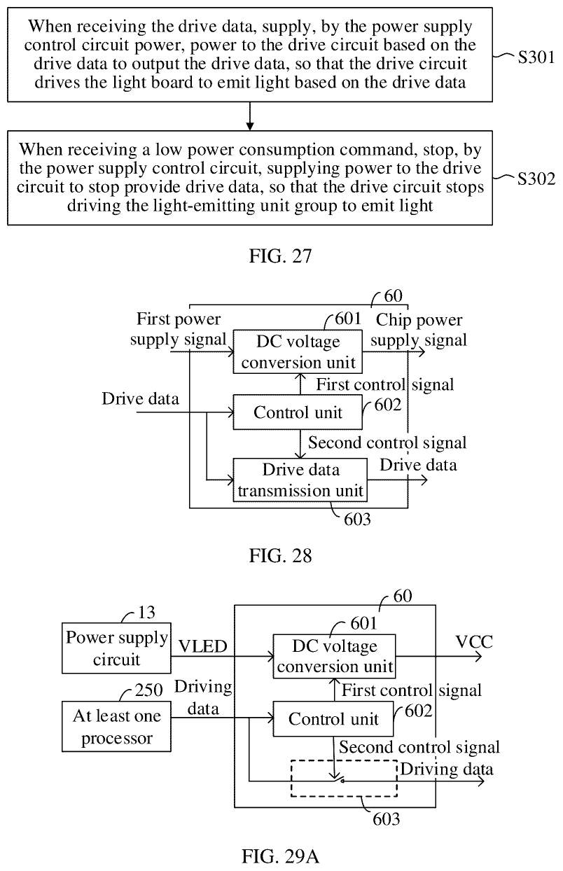

FIG. 27 is a display control method according to some embodiments, as shown in FIG. 7, including the following steps.

S301, when the power supply control circuit receives drive data, it supplies power to the drive circuit based on the drive data and outputs the drive data, so that the drive circuit drives the light board to emit light based on the drive data.

S302, when the power supply control circuit obtains a low power consumption command, it stops supplying power to the drive circuit and stops providing drive data, so that the drive circuit stops driving the light-emitting unit group to emit light.

The schematic structural diagram of the power supply control circuit 60 is shown in FIG. 28, and the ways in which the power source signal is obtained include but are not limited to: a power source signal obtained from the power supply circuit, and a power source signal obtained from the drive data transmitted by the processor. The two situations are explained below.

In some embodiments, when the power source signal obtained by the power control circuit 60 is a power source signal obtained from the power supply circuit 13, the input port of the power control circuit 60 is electrically connected to the power supply circuit 13.

More specifically, the input port of the power supply control circuit 60 includes an input terminal and a power source terminal. The input terminal of the power supply control circuit 60 is electrically connected to the processor 250, and the power source terminal of the power supply control circuit 60 is electrically connected to the power supply circuit 13 and the power supply terminal of the light board. The connection relationship of the power supply control circuit 60 in the backlight assembly is shown in FIGS. 26B and 26D.

The power supply control circuit 60 is configured to obtain a first power source signal from the power supply circuit 13, and when obtaining the corresponding drive data, output the first power source signal based on the drive data as a chip power supply signal.

In some embodiments, the power supply control circuit 60 is configured to convert the first power source signal into a chip power supply signal based on the drive data to supply power to the drive chip 202.

In some embodiments, the power supply control circuit 60 includes a control unit 602, and an input terminal of the control unit 602 is coupled to an input terminal of the power supply control circuit 60. The control unit is configured to receive drive data during a non-standby period of the display apparatus, and generate a first control signal and a second control signal based on the drive data, where the start moment of the first control signal is earlier than the start moment of the second control signal by a preset time length.

In some embodiments, the control unit 602 is further configured to not receive drive data and not generate the first control signal and the second control signal during a standby period of the display apparatus.

In some embodiments, a delay circuit (e.g., RC circuit) is provided in the control unit 602, and the delay circuit is configured to obtain a first control signal, and output a second control signal after a preset time length, and the delay time length is determined based on the delay characteristic parameters of the devices in the delay circuit. For example, in an RC circuit, it is determined based on the resistance value of the resistor and the capacitance of the capacitor.

In some embodiments, the power supply control circuit 60 includes a DC voltage conversion unit 601, whose input terminal is coupled to the power source terminal of the power supply control circuit 60, whose output terminal is electrically connected to the first output terminal of the power supply control circuit 60, and whose control terminal is electrically connected to the first output terminal of the control unit 602.

The DC voltage conversion unit 601 is configured to obtain a first control signal from the control unit 602, obtain a first power supply signal from its input terminal, and output the first power supply signal as a chip power supply signal based on the first control signal.

In some embodiments, the DC voltage conversion unit 601 is configured to convert the first power supply signal into a chip power supply signal based on the first control signal, and output the chip power supply signal, as shown in FIG. 28.

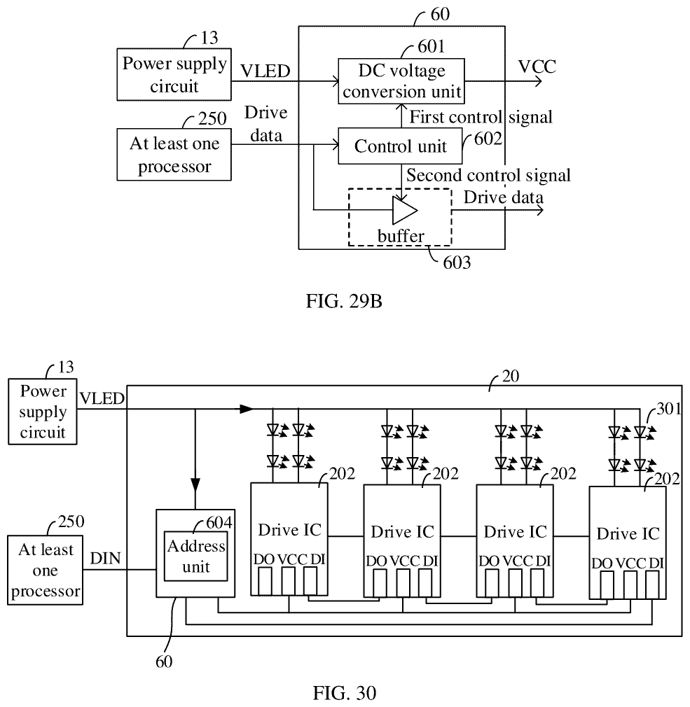

When the first power supply signal is a power supply signal of the light-emitting unit group, the first power supply signal is a power source signal VLED, and the chip power supply signal is a power source signal VCC, as shown in FIG. 29A and FIG. 29B.

In some embodiments, the DC voltage conversion unit 601 includes a low-dropout regulator LDO and a controllable switching device. The controllable switching device is connected in series between the input terminal of the DC voltage conversion unit 601 and the input terminal of the low-dropout regulator LDO. The DC voltage conversion unit 601 is configured to control the conduction state of the controllable switching device based on a first control signal. When the switching device is turned on, the power source signal VLED obtained at the input terminal of the LDO is converted into a chip power supply signal.

In some embodiments, the DC voltage conversion unit 601 includes a DC-DC conversion circuit (e.g., a Buck circuit), and the first control signal is configured to control the conduction of a switching device in the DCDC conversion circuit to perform voltage conversion.

In some embodiments, the power supply control circuit 60 also includes a drive data transmission unit 603, whose input terminal is coupled to the input terminal of the power supply control circuit 60, whose output terminal is electrically connected to the second output terminal of the power supply control circuit 60, and whose control terminal is electrically connected to the second output terminal of the control unit 602.

The drive data transmission unit 603 is configured to obtain the second control signal from the control unit 602 and the drive data from the processor 250, and its conduction state is controlled by the second control signal, and when it is turned on, it outputs the drive data.

In some embodiments, the drive data transmission unit 603 includes a controllable switching device or a buffer amplifier (Buffer). The controllable switching device includes but is not limited to a field effect transistor and a triode.

The controllable switching device and the buffer amplifier are configured to be turned on when receiving the second control signal, and output the drive data obtained at their input terminals.

Among them, when the drive data transmission unit includes a controllable switching device, the circuit structure of the power supply control circuit 60 is shown in FIG. 29A. When the drive data transmission unit includes a buffer amplifier (Buffer), the circuit structure of the power supply control circuit 60 is shown in FIG. 29B.

In some embodiments, address information is set in the power supply control circuit 60, and the processor 250 outputs drive data based on the address information.

In some embodiments, the power supply control circuit 60 includes an address unit 604, and a schematic structural diagram is shown in FIG. 30. The address unit 604 is configured to set an address of the power supply control circuit 60.

In some embodiments, the processor 250 is configured to send drive data to the power supply control circuit 60 based on the address of the power supply control circuit 60, where the drive data includes the address of the power supply control circuit.

The power supply control circuit 60 is configured to receive drive data, and based on the drive data, output a circuit power supply signal from its first output terminal, and output the drive data from its second output terminal, so that the backlight drive circuit electrically connected to the power supply control circuit 60 generates a drive signal based on the drive data to drive the corresponding light bead(s) 301 to emit light.

In some embodiments, the backlight drive circuit may be packaged as the drive chip 202, and the circuit power supply signal generated by the power supply control circuit 60 is a chip power supply signal.

In some embodiments, the power supply control circuit 60 is further configured to stop outputting the circuit power supply signal and drive data when receiving a low power consumption command.

In the above technical solution, the power supply control circuit arranged between the processor and the backlight drive circuit can supply power to the drive chip based on the drive data provided by the processor, and provide drive data so that the drive chip drives the light string in the backlight assembly to emit light. During the standby process of the display apparatus, when the power supply control circuit obtains the low power consumption command, it stops providing backlight to the drive chip, so that the drive chip reduces leakage current and reduces losses during the standby process of the display apparatus. In addition, the corresponding address is set in the power supply control circuit, so that when multiple power supply control circuits are connected to the same output terminal of the processor, the corresponding drive data can be distinguished based on their corresponding addresses, thereby reducing the use of data lines in the backlight assembly, simplifying the circuit structure, and improving the control ability of the processor.

In some embodiments, the address unit 604 includes an address configuration circuit 6041, an input terminal of the address configuration circuit 6041 is used as the input terminal of the power supply control circuit 60, and is electrically connected to the processor 250. The address configuration circuit 6041 is set with its corresponding physical address inside, and is configured to obtain the drive data sent by the processor 250.

When the address information of the power supply control circuit 60 in the drive data is the same as the physical address, a conduction control signal is generated.

When the address information of the power supply control circuit 60 in the drive data is different from the physical address, no conduction control signal is generated.

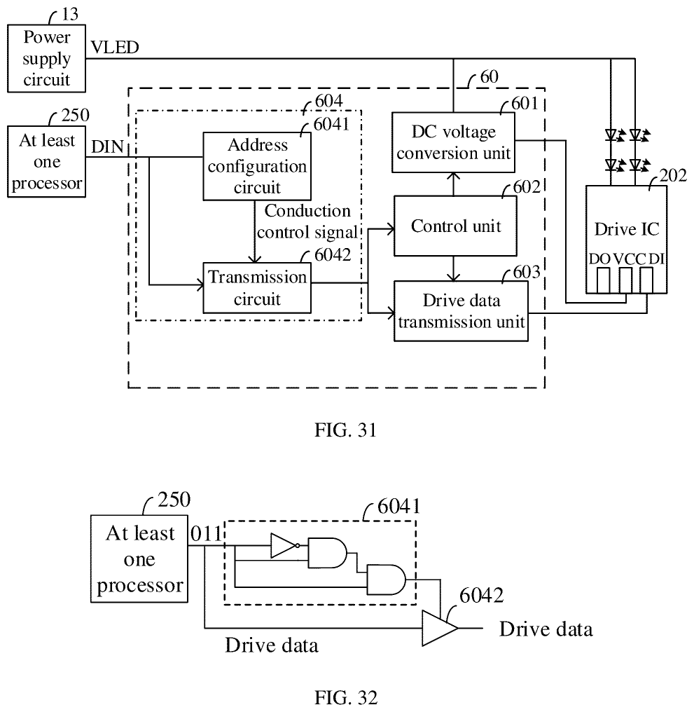

In some embodiments, the address unit 604 further includes a transmission circuit 6042, whose input terminal is electrically connected to the processor 250 through the input terminal of the power supply control circuit 60, and whose control terminal is electrically connected to the output terminal of the address configuration circuit 6041. An exemplary circuit connection relationship between the transmission circuit 6042 and the address configuration circuit 6041 is shown in FIG. 31.

The transmission circuit 6042 is configured to obtain drive data from its input terminal, and output the drive data when the control terminal obtains a conduction control signal; and stop outputting the drive data when the control terminal does not obtain the conduction control signal.

In some embodiments, the address configuration circuit 6041 includes a multi-input AND gate circuit. The multi-input AND gate circuit is configured to output a first level as a conduction control signal when obtaining an address corresponding to the physical address set by the address unit 604 from its input terminal; and output a second level when obtaining other addresses from its input terminal.

The address is an address composed of at least one digital electrical signal, and the digital electrical signal includes a high-level electrical signal or a low-level electrical signal.

The multi-input AND gate circuit performs a logic operation on at least one digital electrical signal corresponding to the address, and determines the electrical signal with an output target level as a conduction control signal.

In some embodiments, the address set by the address unit 604 is an address composed of three-bit digital electrical signal, for example: 011, then the circuit structure example diagram of the multi-input AND gate circuit corresponding to the physical address is set as shown in FIG. 32, including two AND gates and one NOT gate, where the NOT gate inverts the electrical signal obtained from the first input terminal of the first AND gate, the output terminal of the first AND gate is electrically connected to the first input terminal of the second AND gate, and the output terminal of the second AND gate is configured to output the conduction control signal.

The circuit structure shown in FIG. 32 includes three input terminals, which are coupled to the processor 250, corresponding to obtaining three-bit address information of the address unit 604.

In some embodiments, the three input terminals of the multi-input AND gate circuit determine their corresponding physical addresses according to a preset order, and the processor 250 is configured to output the level corresponding to the physical address based on the preset order so that the multi-input AND gate circuit outputs a high-level electrical signal.

The high-level electrical signal is the conduction control signal output by the multi-input AND gate circuit, and the low-level electrical signal is other electrical signals output when the multi-input AND gate circuit does not output the conduction control signal.

For example, the three input terminals of the multi-input AND gate circuit determine their corresponding physical addresses in order from top to bottom. When the processor 250 outputs low-level, high-level, and high-level electrical signals based on the physical addresses, the multi-input AND gate circuit outputs a high-level electrical signal as a conduction control signal. When the level of any bit of the physical address output by the processor 250 is inconsistent with the above level, the multi-input AND gate circuit outputs a low-level electrical signal as the case when the address configuration circuit 6041 does not output a conduction control signal.

In some embodiments, the digital signal transmitted by the processor 250 includes 0 and 1, 0 corresponds to a low-level electrical signal, and 1 corresponds to a high-level electrical signal. For the circuit structure shown in FIG. 32, the digital signal corresponding to the physical address set by the address configuration circuit 6041 is 011.

In some embodiments, the input terminals of the multi-input AND gate circuit obtain not only the address but also other control signals, and the conduction control signal output by the multi-input AND gate circuit is a signal generated by the multi-input AND gate circuit based on the address and other control signals.

In some embodiments, a serial-to-parallel circuit is electrically connected in series between the processor 250 and the address configuration circuit 6041, and the serial-to-parallel circuit is configured to transmit the serially transmitted digital signal in parallel to the input terminal of the address configuration circuit 6041, so that the address configuration circuit 6041 processes multiple digital electrical signals transmitted by the processor 250.

In some other embodiments, the address configuration circuit 6041 may further include a reference circuit for generating a preset voltage value and a voltage comparator. The output terminal of the reference circuit is electrically connected to the first input terminal of the voltage comparator, and the output terminal of the processor 250 is electrically connected to the second input terminal of the voltage comparator.

The processor 250 is configured to output a first voltage signal as an address corresponding to a target drive chip.

The address configuration circuit 6041 is configured to obtain a first voltage signal and a preset voltage value. When the output voltage value is less than the preset voltage threshold, it indicates that the address output by the processor 250 is an address matching the address set by the address configuration circuit 6041, and the output voltage value is determined as the conduction control signal.

When the output voltage value is greater than the preset voltage threshold, it indicates that the address output by the processor 250 is an address that does not match the address set by the address configuration circuit 6041, and the output voltage value is determined as other signals output by the address configuration circuit 6041.

In some embodiments, the transmission circuit 6042 includes a controllable transmission circuit, such as the transmission gate shown in FIG. 32.

In some embodiments, the enable terminal of the transmission gate serves as the control terminal of the transmission circuit 6042 and is electrically connected to the output terminal of the address configuration circuit 6041. The input terminal of the transmission gate is electrically connected to the output terminal of the processor 250 and is configured to be turned on based on the conduction control signal output by the address configuration circuit 6041, and output the drive data obtained at its input terminal.

In some embodiments, in the power supply control circuit 60, the input terminal of the control unit 602 is electrically connected to the output terminal of the transmission unit 6042, and the control unit 602 is configured to obtain drive data from the transmission unit 6042, and generate a first control signal based on the drive data to control the drive data transmission unit 603 to be turned on.

The control unit 602 is further configured to generate a second control signal based on the drive data to control the DC voltage conversion unit 601 to perform level conversion and output a circuit power supply signal of the backlight drive circuit.

The drive data transmission unit 603 is electrically connected to the output terminal of the transmission circuit 6042, and is configured to obtain drive data from the transmission circuit 6042, and output the drive data when it is turned on.

In some embodiments, when the power supply control circuit 60 shown in FIG. 31 is used to construct the backlight assembly of the display apparatus, the backlight assembly includes a plurality of drive units and a plurality of data lines, and each drive unit is connected to the processor 250 through a corresponding data line. Each drive unit includes a plurality of drive groups, and each drive group includes the power supply control circuit as shown in FIG. 31 and at least one drive chip. The address of the power supply control circuit is the address of the drive group, and the addresses of different drive groups in the same drive unit are different.

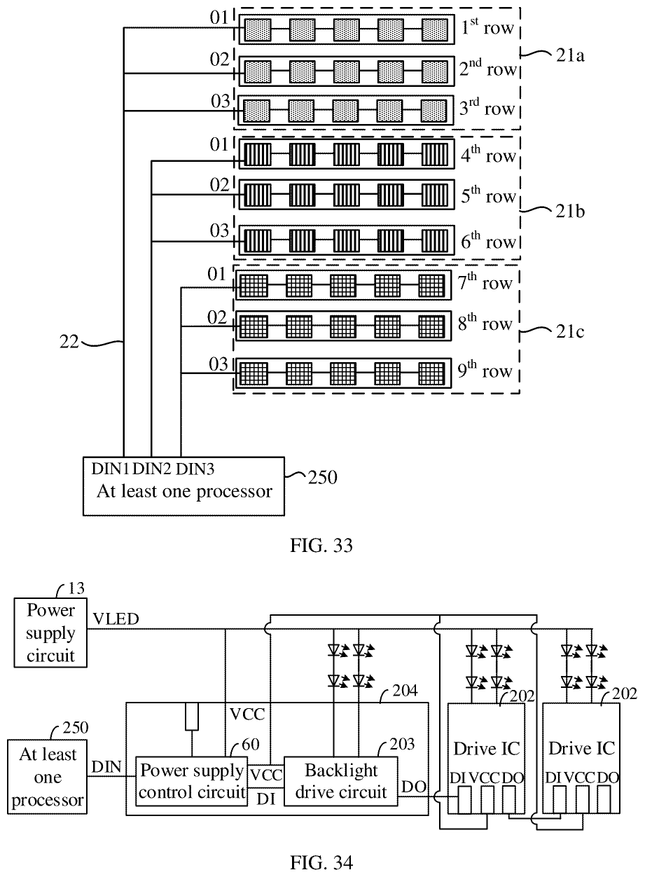

The structure of the backlight assembly provided by the present application is explained with the structure shown in FIG. 33. The processor 250 is provided with three output terminals Din1, Din2, and Din3, the output terminal Din1 is connected to the corresponding first drive unit 21a through a data line 22, the output terminal Din2 is connected to the corresponding second drive unit 21b through a data line 22, and the output terminal Din3 is connected to the corresponding third drive unit 21c through a data line 22.

The internal structure and connection relationship of the drive unit are explained below by taking the first drive unit 21a as an example.

The first drive unit 21a includes three drive groups corresponding to three groups of liquid crystals for displaying on the display panel 10.

In the structure shown in FIG. 33, taking the first row drive group as an example, each drive group includes a power supply control circuit 60 and a plurality of drive chips 202, and the input terminal of the power supply control circuit 60 and the output terminal of the processor 250 are electrically connected, as shown in the first schematic structure in the order from left to right in FIG. 33.

The power source terminal VCC of each drive chip 202 is electrically connected to the output terminal of the DC voltage conversion unit 601 in the power supply control circuit 60. The data input terminal D1 of each drive chip 202 is coupled to the output terminal of the drive data transmission unit 603 in the power supply control circuit 60.

In some embodiments, in the drive group, the data input terminal D1 of each drive chip 202 is connected to the output terminal of the drive data transmission unit 603 in the power supply control circuit 60, as shown in FIG. 26B.

In some embodiments, in the drive group, the data input terminal D1 of the drive chip 202 located first among the drive chips 202 is connected to the output terminal of the drive data transmission unit 603 in the power supply control circuit 60, and the data output terminal DO thereof is connected to the data input terminal of the next drive chip 202, as shown in FIG. 26D.

In some embodiments, in each drive unit, the addresses of the drive groups are different, so that the processor 250 transmits corresponding drive data based on the address of each drive group.

In some embodiments, in each drive group, the address of the power supply control circuit 60 is used as the address of the drive group to which the power supply control circuit belongs.

In some embodiments, each drive chip 202 is configured to obtain each corresponding data segment based on its corresponding internal address to generate a drive signal to drive the corresponding light bead 301 to emit light. The circuit structure of the power supply control circuit 60 is shown in FIG. 31.

In some embodiments, when the processor 250 transmits drive data to the target drive chip, the processor 250 is configured to send the drive data to the target power supply control circuit in the drive group based on an address of the drive group where the target drive chip is located; and the address includes an address of the power supply control circuit.

The target power supply control circuit is configured to output a circuit power supply signal and drive data based on the address, so that the target drive chip drives the corresponding light bead to emit light based on the drive data.

In some embodiments, the power supply control circuit 60 can be integrated with the backlight drive circuit in the drive chip 202 in the controllable drive chip 204, that is, the controllable drive chip 204 includes the power supply control circuit 60 and the backlight drive circuit 203. The circuit structure of the controllable drive chip 204 is explained below using FIG. 34 as an example.

In some embodiments, the controllable drive chip 204 includes a power supply control circuit 60, and a first output terminal of the power supply control circuit 60 serves as a power supply terminal of the power supply control circuit 60, and is electrically connected to a power source terminal VCC of at least one drive chip 202 corresponding thereto, and is also electrically connected to a power source terminal VCC of a backlight drive circuit 203 in the controllable drive chip 204, and the first output terminal is configured to output a circuit power supply signal of the backlight drive circuit, and output a chip power supply signal of the drive chip 202, where the circuit power supply signal and the chip power supply signal are the same.

In some embodiments, the second output terminal of the power supply control circuit 60 is connected to the input terminal D1 of the backlight drive circuit 203 of the controllable drive chip 204, and is configured to output drive data from its second output terminal after outputting the circuit power supply signal at its first output terminal.

In some embodiments, the circuit structure of the power supply control circuit 60 is as shown in FIG. 29A or FIG. 29B.

In some embodiments, the address of the power supply control circuit 60 is an address burned into the control unit 602.

In some other embodiments, the address of the power supply control circuit 60 is set by a pin address. The control unit 602 in the power supply control circuit 60 is connected to the address pin of the controllable drive chip 204, and the address pin is configured to set the physical address of the controllable drive chip 204, which is also the physical address of the power supply control circuit 60.

The control unit 602 is configured to, after obtaining the drive data, determine whether the address of the control unit 602 and the address in the drive data are the same based on the physical address set by the address pin, and if they are the same, generate the first control signal and the second control signal in sequence based on the drive data to control the DC voltage conversion unit 601 to output the circuit power supply signal and the chip power supply signal, and control the drive data transmission unit 603 to output the drive data.

In some embodiments, the address pin of the controllable drive chip 204 can be connected to other functional pins of the chip, and the other functional pins correspond to their own physical addresses. Different functional pins correspond to different physical addresses. When the address pin is connected to the functional pin, the address of the address pin is the address of the functional pin. The functional pins include: power supply pins, data input pins, data output pins, and power source pins.

In some embodiments, a level generating circuit may be provided in the controllable drive chip 204, and the address pin of the controllable drive chip 204 is electrically connected to the output terminal of the level generating circuit, and the voltage value or level state generated by the level generating circuit is set as the address of the controllable drive chip 204, where the level state includes a low level state or a high level state.

In some other embodiments, the circuit structure of the power supply control circuit 60 is shown in FIG. 31, and includes an address unit 604, and a corresponding address can be set based on the address unit 604.

In the above technical solution, after receiving the drive data, the drive chip of the power supply control circuit can adjust the power supply process of the current drive chip based on the drive data, so that the drive chip is powered on only when it receives its corresponding drive data, thereby reducing the leakage current generated by the drive chip during the standby process of the display apparatus.

In some embodiments, the present application provides a drive group, which includes a controllable drive chip 204 and multiple drive chips 202. The address of the controllable drive chip 204 is used as the address of the drive group. The power source terminal of the controllable drive chip 204 is electrically connected to the power supply circuit 13, the data input terminal is connected to the processor 250, the power source terminal is electrically connected to the power source terminal of the multiple drive chips 202, and the drive terminal is electrically connected to the corresponding light bead(s).

In some embodiments, the data output terminal of the controllable drive chip 204 is electrically connected to the data input terminals of the plurality of drive chips 202.

In some other embodiments, the data output terminal of the controllable drive chip 204 is electrically connected to the data input terminal of the drive chip 202 located first among the multiple drive chips 202, and the data input terminal of other drive chip 202 is electrically connected to the data output terminal of the previous drive chip 202. The circuit structure is shown in FIG. 34.

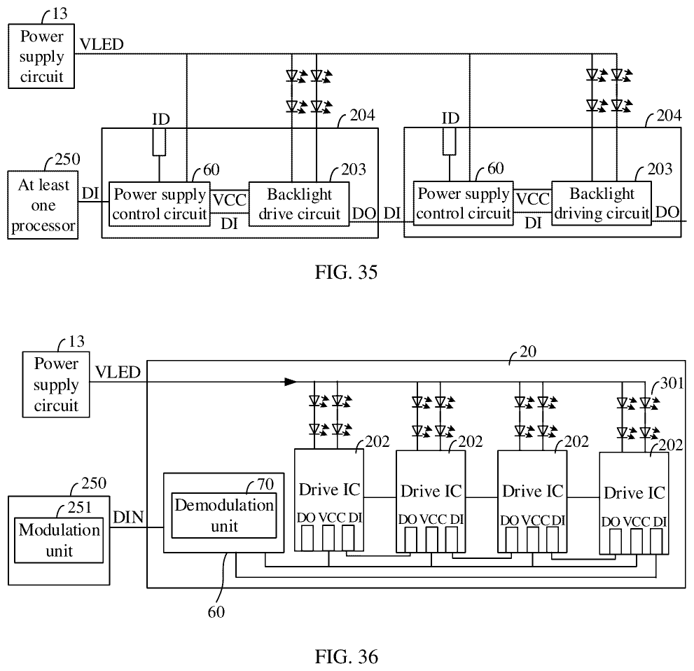

In some embodiments, the present application provides a drive group, which includes multiple controllable drive chips 204. As shown in FIG. 35, the power source terminal of each controllable drive chip 204 is electrically connected to the power supply circuit 13, and the drive terminal is electrically connected to the corresponding light bead.

In some embodiments, the data input terminal of the controllable drive chip 204 located at the first position is electrically connected to the processor 250, and the data input terminal of other controllable drive chip 204 is electrically connected to the data output terminal of the previous controllable drive chip 204.

In some other embodiments, the data input terminal of each controllable drive chip 204 is electrically connected to the processor 250.

In some embodiments, at least one drive chip 202 can be electrically connected between two controllable drive chips 204 that are adjacent to each other, and the power source terminal of at least one drive chip 202 is electrically connected to the power supply terminal of the previous controllable drive chip 204, so as to divide the partitions located in a row into multiple groups of partitions according to the quantity of controllable drive chips 204, and the multiple groups of partitions can be controlled separately in a targeted manner, thereby improving the precision of the control of the processor 204 over the partitions without increasing the quantity of data line wiring in the backlight assembly.

In the above technical solution, each drive unit in the backlight assembly includes multiple drive groups, and each drive group includes at least one drive chip including the power supply control circuit to manage the power consumption process of the drive chip and related devices. When it obtains the low power consumption command, the power supply circuit can be turned off in time to reduce the generation of leakage current. The power supply control circuit is integrated in the drive chip, and the quantity of chips used in the backlight assembly is not increased, thereby reducing production costs. In addition, multiple drive groups in the drive unit are distinguished in address based on the physical addresses of the drive chips, which improves the driving capability of the processor, reduces the use of data lines in the backlight assembly, and simplifies the circuit structure.

In some embodiments, the present application provides a processor 250, as shown in FIG. 36, the processor 250 includes a modulation unit 251, and an output terminal of the modulation unit 251 is coupled to an output terminal of the processor 250.

In some embodiments, the processor 250 is configured to obtain a frame of image data, acquire backlight data from the frame of image data, and generate drive data based on the backlight data.

In some embodiments, the processor 250 is configured to obtain a second power source signal.

In some embodiments, the modulation unit 251 is configured to obtain the second power source signal and drive data, and output modulated drive data, where the modulated drive data includes the drive data loaded on the second power source signal.

In some embodiments, the waveform output by the modulation unit 251 is shown in FIG. 38, where the second power source signal is a high level signal, and the drive data is a signal having a frequency higher than that of the second power source signal. The level state corresponding to the drive data includes a high level state or a low level state.

The potential value of the second power source signal loaded with the drive data in the high level state remains unchanged, and the potential value of the second power source signal loaded with the drive data in the low level state decreases, but the level state of the second power source signal is not changed, that is, it still at a high level after the low level signal is loaded with the high level signal in the second power source signal. In the waveform diagram shown in FIG. 38, the period t1 is a period of the second power source signal for loading the drive data, and the period t2 represents a low level period for not outputting the drive data and the second power source signal.

This loading method has little effect on the change of the power source signal and can simplify the modulation process of the modulation unit.

In some other embodiments, the waveform diagram output by the modulation unit 251 is as shown in FIG. 39, and the second power source signal loaded with drive data fluctuates up and down according to the second power source signal. During the period t1, the second power source signal that is not loaded with drive data is at the third level, as shown in the period D2; the second power source signal loaded with high-level drive data is at the first level, such as a level higher than the third level during the period D1 and the period D2, and the second power source signal loaded with low-level drive data is at the second level, such as a level lower than the third level during the period D1 and the period D2.

The waveform shown in FIG. 39 can transmit multi-terminal drive data and is helpful to distinguish drive data from power supply signals.

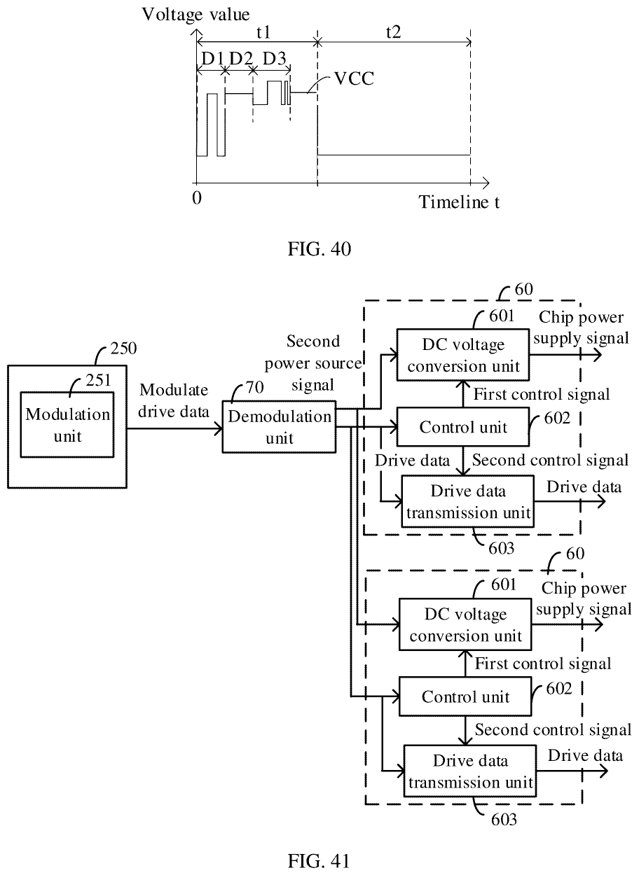

In some other embodiments, the waveform diagram output by the modulation unit 251 is as shown in FIG. 40. The address data is in the period D1, and the waveform of the second power source signal can be modulated as the address. The period D2 is an invalid period, and the signal in this period is a signal at the third level and without loading drive data. It can pre-charge for the subsequent power supply process in this period to stabilize the high level of the second power source signal, and this period can also provide processing time for the circuit structure that receives the address in the period D1 to process the address.

The power supply control circuit 60 is configured to separate the second power source signal and the drive data in the drive data after obtaining the above drive data, and to power the drive chip after performing voltage conversion on the separated second power source signal, and to transmit the separated original drive data to the drive chip to drive the light string to emit light.

In some embodiments, the backlight assembly 20 includes a demodulation unit 70, an input terminal of the demodulation unit 70 is coupled to the processor 250, a first output terminal thereof is connected to the input terminal of the DC voltage conversion unit 601, and a second output terminal thereof is connected to the input terminals of the control unit 602 and the drive data transmission unit 603. The demodulation unit 70 is configured to obtain a second power source signal loaded with drive data from the processor 250, output the second power source signal from the first output terminal as the first power supply signal after signal decoupling, and output the drive data from the second output terminal.

In some embodiments, the starting band of the original drive data includes address information, and the control unit 602 determines whether to output the first control signal based on the address information.

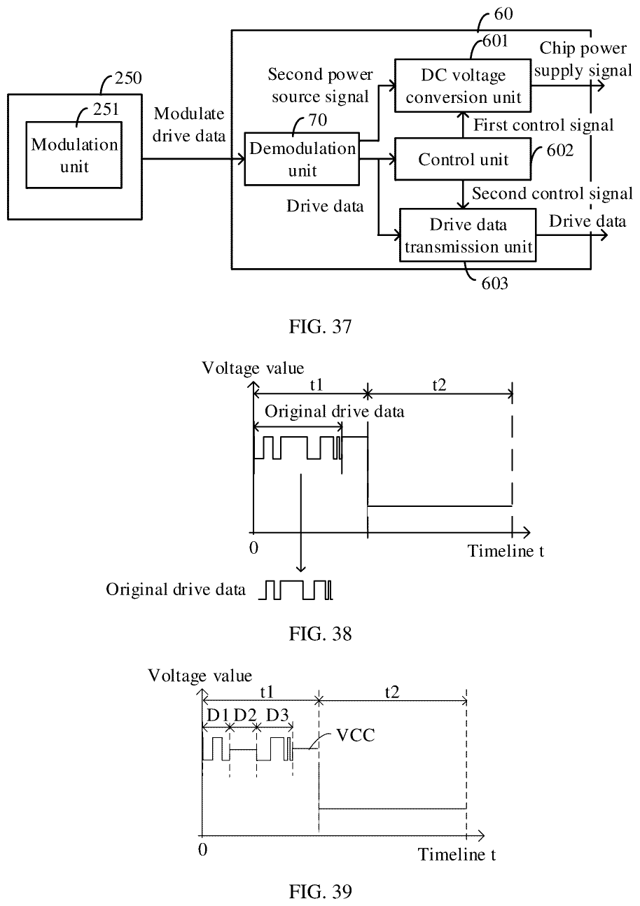

In some embodiments, the power supply control circuit 60 includes a demodulation unit 70, and an input terminal of the demodulation unit 70 is electrically connected to an input terminal of the power supply control circuit 60. A schematic diagram of the circuit structure of the power supply control circuit 60 is shown in FIG. 37.

In some other embodiments, the demodulation unit 70 is located outside the drive chip 202, and the demodulation unit 70 is electrically connected to at least one power supply control circuit 60.

Taking the demodulation unit 70 electrically connected to two power supply control circuits 60 as an example, the circuit connection relationship and control method of the demodulation unit 70 and the power supply control circuits 60 are explained. Among them, the circuit connection relationship of the demodulation unit 70 electrically connected to the two power supply control circuits 60 is shown in FIG. 41.

In some embodiments, after the demodulation unit 70 decouples the second power source signal loaded with drive data, the second power source signal is transmitted to the DC voltage conversion unit 601 in each corresponding power supply control circuit 60, and the drive data is transmitted to the control unit 602 and the drive data transmission unit 603 in each corresponding power supply control circuit 60.

The control unit 602 in each power supply control circuit 60 is configured to obtain address information from the drive data, and when the address information corresponds to its address information, control the corresponding DC voltage conversion unit 601 to supply power, and control the corresponding drive data transmission unit 603 to output drive data.

In some embodiments, a gain amplifier is provided at the input terminal of the demodulation unit 70, and is configured to perform gain amplification on the drive data to prevent the signal obtained by decoupling from attenuating, thereby ensuring the driving accuracy of the power supply control circuit 60.

In the above technical solution, the modulation unit is set in the processor, and a corresponding demodulation unit is set in the backlight assembly, so that after the processor loads the drive data on the second power source signal and outputs the modulated drive data, the modulated drive data is parsed to obtain the second power source signal and the drive data, so that the processor provides backlight for the drive chip in the backlight assembly, which simplifies the structure of the circuit in the backlight assembly. The power supply control circuit in the drive chip is set so that after the drive chip obtains the drive data, the power supply control circuit therein supplies power to the backlight drive circuit based on the drive data, and provides the drive data only after power-on, so that the backlight drive data generates the drive signal based on the drive data to drive the corresponding light beads to emit light, which avoiding the generation of leakage current when the drive chip obtains the low power consumption command, and reducing losses.

In some other embodiments, the demodulation unit 70 is provided with address information, which is address information of the drive group corresponding to all the power supply control circuits 60 electrically connected thereto. The demodulation unit 70 is configured to demodulate the signal in the start period after obtaining the second power source signal loaded with drive data from the processor 250. The time length of the start period is a preset time length. The signal at the start period is the second power source signal loaded with address information. When the address information is the same as its address information, the demodulation continues, otherwise, the demodulation stops. This circuit simplifies the operation loss of the demodulation unit.

In some embodiments, the demodulation unit 70 includes a demodulation circuit 701, the input terminal of the demodulation circuit 701 is electrically connected to the output terminal of the processor 250, and is configured to parse the modulated drive data to output a second power source signal, drive data and a target address.

In some embodiments, the demodulation unit 70 includes an address circuit 702, an input terminal of the address circuit 702 and an output terminal of the demodulation circuit 701 are electrically connected, and the address circuit 702 is provided with a corresponding physical address inside, and is configured to control the demodulation circuit 701 to output the second power source signal and drive data when the target address is the physical address corresponding to the address circuit.

The address circuit 702 is further configured to control the demodulation circuit 701 not to output the second power source signal and the drive data when the target address is not the physical address corresponding to the address circuit.

In some embodiments, the modulated drive data output by the processor 250 includes first modulated sub-data, and the first modulated sub-data includes a target address loaded on the second power source signal.

In some embodiments, the demodulation circuit 701 is configured to parse the first modulated sub-data to obtain a target address.

In some embodiments, the address circuit 702 includes an address configuration circuit. The address configuration circuit is electrically connected to a demodulation circuit, and is configured to obtain a target address, output a parsing control signal when the target address and the physical address corresponding to the address configuration circuit are the same, and do not output a parsing control signal when the target address and the physical address corresponding to the address configuration circuit are different.

In some embodiments, the address configuration circuit in the address circuit 702 has the same structure as the address configuration circuit 6041 shown in FIG. 31.

In some embodiments, a serial-to-parallel circuit is further provided between the demodulation circuit 701 and the address circuit 702, and is configured to convert the address obtained by bit-by-bit parsing of the demodulation circuit 701 into an address for parallel transmission.

In some embodiments, the demodulation circuit 701 includes a reference circuit 703, which is configured to output a reference electrical signal, where a voltage value of the reference electrical signal is the same as a voltage value of the second power source signal.

In some embodiments, the reference circuit 703 may be a voltage divider circuit based on a resistor and a fixed voltage value, or may generate a stable voltage value for a DA converter.

In some embodiments, the demodulation circuit 701 further includes a comparison circuit, where a first input terminal Din of the comparison circuit is electrically connected to an output terminal of the processor 250, and a second input terminal thereof is electrically connected to an output terminal of the reference circuit 70. The comparison circuit is configured to output a first level as first data in the drive data when a voltage corresponding to the data input at the first terminal thereof is greater than a voltage of a reference electrical signal obtained at the second terminal thereof, output the second level as second data in the drive data when the voltage corresponding to the data input at the first terminal is less than the voltage of the reference electrical signal obtained at the second terminal, and output the third level as invalid data in the drive data when the voltage corresponding to the data input at the first terminal is equal to the voltage of the reference electrical signal obtained at the second terminal.

In some embodiments, the circuit structure of the comparison circuit including a comparator U1 may be as shown in the example of FIG. 44. The first input terminal CA+ of the comparator U1 is electrically connected to the output terminal of the processor 250, the second input terminal CA-thereof is electrically connected to the output terminal of the reference circuit 703, and the power source terminal of the comparator U1 is electrically connected to the power source VLED. The comparator U1 is configured to obtain the modulated drive data from its first input terminal, obtain the reference electrical signal Vref from its second input terminal, compare the voltage value corresponding to the modulated drive data with the voltage value of the reference electrical signal Vref, and output a high level signal when the voltage value corresponding to the modulated drive data is greater than the voltage value of the reference electrical signal Vref, and output a low level signal when the voltage value corresponding to the modulated drive data is smaller than the voltage value of the reference electrical signal Vref.

In some embodiments, the comparison circuit also includes a second capacitor C2, the first input terminal CA+ of the comparator U1 is electrically connected to the first terminal of the second capacitor C2, the second terminal of the second capacitor C2 is electrically connected to the output terminal of the processor 250, and the second capacitor C2 is configured to adjust the voltage value of its first terminal based on its coupling effect and the change of the voltage value of its second terminal.

In some embodiments, the comparison circuit further includes a first capacitor C1, a first terminal of which is electrically connected to the power source terminal of the comparator U1, a second terminal thereof is grounded, and the first capacitor is configured to filter the power source signal obtained by the comparator U1.

In some embodiments, a controllable switch circuit is electrically connected in series between the first input terminal of the comparison circuit and the processor 250, and the control terminal of the controllable switch circuit is electrically connected to the output terminal of the address circuit 702. The controllable switch circuit is a normally closed switch circuit.

The controllable switch circuit is configured to remain in a closed state when the address circuit 702 outputs a parsing control signal, so as to continue receiving and parsing the drive data. The parsing control signal is consistent with the level state of the default signal received by the controllable switch circuit.

In some embodiments, the modulated drive data output by the processor 250 also includes invalid data, which is located after the first modulated sub-data. The data transmission time length of the invalid data is greater than the operating time length of the address circuit, so that the demodulation circuit 701 determines whether to parse the subsequently obtained data after the address circuit 702 completes the address analysis, thereby avoiding energy consumption caused by invalid analysis.

In some embodiments, the modulated drive data output by the processor 250 further includes second modulated sub-data, and the second modulated sub-data is located after the invalid data.

In the waveform diagram shown in FIG. 39, the waveform in the period D1 is the waveform corresponding to the first modulated sub-data, the waveform in the period D2 is the waveform corresponding to the invalid data, and the waveform in the D3 period is the waveform corresponding to the second modulated sub-data.

The second modulated sub-data includes drive data loaded on the second power source signal.

The demodulation circuit 701 is further configured to parse the second modulated sub-data after obtaining the parsing control signal, and output a second power source signal and drive data.

In some embodiments, the controllable switch circuit is further configured to be turned off when the address circuit 702 outputs a parsing control signal at the second level, stop receiving the drive data, and do not parse the drive data to reduce energy consumption generated by data parsing.

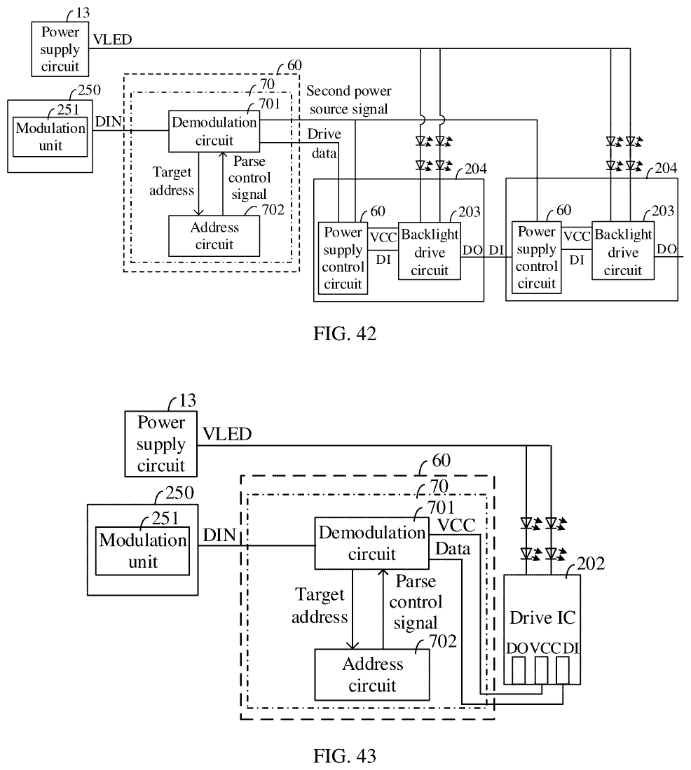

In some embodiments, the present application provides a backlight assembly, the circuit structure of which can be explained based on the structure illustrated in FIG. 42.

The backlight assembly 20 includes at least one demodulation unit 701, a plurality of drive chips and a light board, and the light board includes light beads 301 distributed in an array.

One demodulation unit 701 and a plurality of drive chips form a drive group, and the address set in the demodulation unit 701 is the address of the drive group.

In some embodiments, the drive chip in the drive group is a controllable drive chip 204 including a backlight drive circuit 203 and a power supply control circuit 60.

The input terminal of the demodulation unit 701 is electrically connected to the processor 250, and the output terminal thereof is electrically connected to the input terminal of the corresponding at least one drive chip, and is configured to parse the modulated drive data to obtain the second power source signal and drive data.

The controllable drive chip 204 is configured to control the power supply control circuit 60 to supply power to the backlight drive circuit 203 based on the drive data, so that after the backlight drive circuit 203 is powered on, a drive signal is generated based on the drive data provided by the power supply control circuit 60 to drive the corresponding light beads to emit light.

In some embodiments, the above drive group also includes at least one drive chip 202, the power supply terminal of at least one drive chip 202 is electrically connected to the power supply terminal of the corresponding controllable drive chip 204, the data input terminal of the drive chip 202 and the data output terminal of the controllable drive chip 204 can be electrically connected, and can also be electrically connected to the data output terminal of the previous drive chip 202.

In some embodiments, each drive group in the backlight assembly may include a power supply control circuit 60 and a plurality of drive chips 202.

The structure of the above drive group is explained below using the circuit structure shown in FIG. 43.

The processor 250 includes a modulation unit 251, and the processor 250 is configured to obtain the second power source signal and the drive data, and output the modulated drive data through the modulation unit, where the modulated drive data includes the drive data loaded on the second power source signal.

The input terminal of the power supply control circuit 60 is electrically connected to the processor 250, the first output terminal thereof is electrically connected to the power source terminal of the corresponding drive chip 202, and the second output terminal thereof is connected to the data input terminal of the corresponding drive chip 202. The power supply control circuit includes a demodulation unit 70. The power supply control circuit 60 is configured to demodulate the modulated drive data through the demodulation unit 60, and output the circuit power supply signal and drive data so that after the target drive chip is powered on, the corresponding light bead is driven to emit light based on the drive data.

In some embodiments, when the power supply control circuit 60 only includes the demodulation unit 70, the voltage value of the second power source signal is the same as the voltage value of the circuit power supply signal.

The processor 250 is further configured to send modulated drive data to the power supply control circuit of the drive group it belongs based on the address of the target drive chip; and the drive data sequentially includes the target address and the drive data loaded on the second power source signal.

The demodulation unit 70 is electrically connected to the processor 250. The demodulation unit 70 is provided with the address of the power supply control circuit 60 inside and is configured to parse the modulated drive data and output the second power source signal and the drive data when the target address is consistent with the address of the power supply control circuit 60, and not parse the drive data loaded on the second power source signal and not output the second power source signal and the drive data when the target address is inconsistent with the address of the power supply control circuit.

The output moment of the drive data is later than the output moment of the second power source signal.

FIG. 45 is a schematic diagram of the positional relationship between light beads and corresponding liquid crystal molecules according to some embodiments.

In some embodiments, the display panel 10 may include liquid crystal molecules distributed in an array.

In some embodiments, the liquid crystal molecules of the display panel 10 are scanned row by row, and one row of light beads 301 corresponds to one row of liquid crystal molecules 101, and the light beads 301 are located below the liquid crystal molecules 101, as shown in FIG. 45.

In some embodiments, the liquid crystal molecules of the display panel 10 are scanned column by column, and one column of light beads 301 corresponds to one column of liquid crystal molecules 101.

When the liquid crystal molecules are scanned row by row, the drive circuit in the backlight assembly drives the light beads in each row to emit light based on the drive data, and the processor controls the liquid crystal molecules in the corresponding row to deflect for displaying.

In some embodiments, when the display apparatus continuously displays multiple frames of images, the liquid crystal molecules maintain the deflection angle at the first deflection angle after the display panel is powered on or the display of the previous frame of image data is completed. After obtaining the display trigger signal of the current frame of image data, the processor controls to adjust the deflection angle of the liquid crystal molecule based on the display data corresponding to the pixel point where the liquid crystal molecule is located in the current frame, and also controls the light beads corresponding to the liquid crystal molecules to adjust the light brightness.

Since the response speed of liquid crystal molecules is lower than that of mini-LED or micro-LED, there is a delay between the time point when the deflection angle of the liquid crystal molecules is adjusted to within the preset angle range and the time point when the luminous brightness of the light beads is adjusted. The schematic diagram of the delay characteristic waveform is shown in FIG. 46.

In FIG. 46, a0 is a first deflection angle, a1 is a second deflection angle corresponding to the current frame display data, a2 is a deflection angle when the current frame display data can be normally displayed, a2 to a3 is the above preset angle range, and a2 is determined based on a preset ratio and an angle difference between the first deflection angle a0 and the second deflection angle a1. In some embodiments, the preset ratio is one-half.

Continuing to refer to FIG. 46, when the deflection angle of the liquid crystal molecules is at a0 to a2 (i.e., within t0 to t1 of each frame display period) and the light beads provide backlight, the display apparatus displays the transition screen from the previous frame to the current frame. When the deflection angle of the liquid crystal molecules is at a2 to a1 (i.e., within t1 to t2 of each frame display period) and the light beads provide backlight, the display apparatus can correctly display the image data of the current frame. When multiple frames of images are played continuously, the human eye can observe the ghosting phenomenon within t0 to t1 of each frame, affecting the user's viewing experience.

In some embodiments, the period t0 to t1 of each frame is determined as an unstable period of the liquid crystal molecules, and the period t1 to t2 of each frame is determined as a stable period of the liquid crystal molecules.

In the related art, in order to solve the ghosting phenomenon caused by the slow response of liquid crystal molecules in the above display panel, a black frame insertion (BFI) technology is used to avoid the display during the unstable period of the liquid crystal molecules, that is, during the unstable period of the liquid crystal molecules in the display period of each frame image, the backlight is turned off so that the user cannot observe the ghosting phenomenon caused by the deflection process of the liquid crystal molecules.

As shown in FIG. 46, the angle range a0 to a2 is the unstable angle range of the liquid crystal molecules. When the angle of the liquid crystal molecules is within a0 to a2 corresponding to the period t0 to t1, the light beads corresponding to the liquid crystal molecules are controlled not to emit light, and the user cannot observe the image displayed in t0 to t1. The above operation is called black insertion operation, and the period t0 to t1 when no image is displayed is called black insertion period. The length of the black insertion period is determined based on the response characteristics of the liquid crystal molecules. Generally, the same liquid crystal molecule has the same length of black insertion period applied in the display process of different frames.

In some embodiments, in order to improve the image smoothness and clarity of the display apparatus, some liquid crystal display apparatuses will use variable refresh rate (VRR) technology, that is, the display cycle of the display panel and backlight assembly in the display apparatus according to the current frame quantities effect is dynamically adjusted to adjust the refresh rate of the image display.

Taking the display apparatus continuously displaying three frames of images as an example, the BFI technology applied to VRR technology is explained.

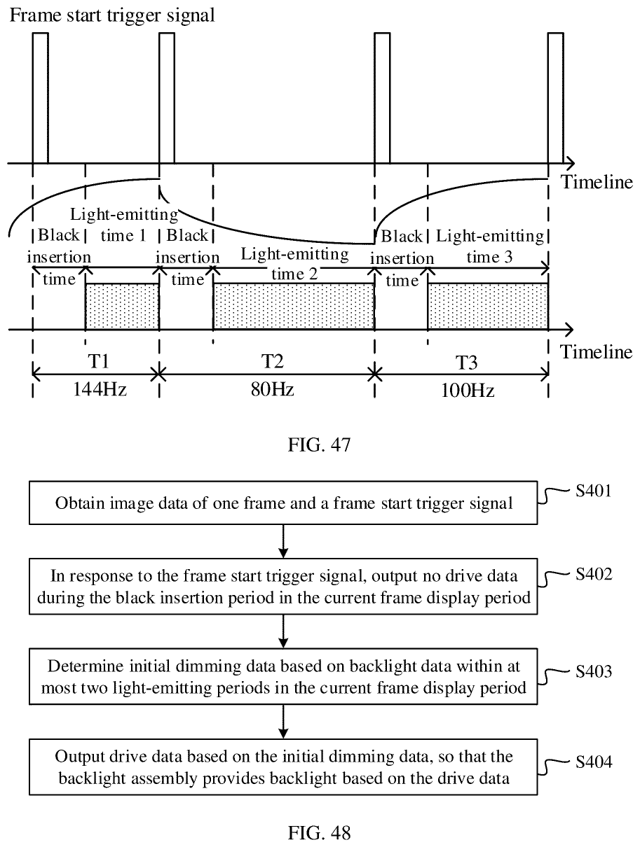

FIG. 47 is a waveform diagram of the BFI technology for VRR technology. As shown in FIG. 47, in response to three frame start trigger signals, the display apparatus displays three consecutive frames of images, where the refresh rates, i.e., 144 Hz, 80 Hz, and 100 Hz, applied to the three adjacent frames of images are different. The larger the refresh rate, the shorter the corresponding frame display time, that is, T1<T3<T2.

In the frame display periods, since the black insertion times are the same, the light-emitting time lengths are different and the black insertion ratios are different. When the drive data generated corresponding to three consecutive frames of image data is the same, the lower the refresh rate, the brighter the backlight brightness provided by the light beads.

When displaying the same image, the display apparatus generally keeps the backlight brightness unchanged.

When the same image is displayed based on the above three different refresh rates, the display apparatus generates the same drive data based on the same image. Due to different black insertion ratios, the backlight brightnesses of the three frames displayed by the display apparatus are different, resulting in flickering in the display apparatus.

To this end, an embodiment of the present application provides a display apparatus and a backlight control method thereof. After the processor in the display apparatus completes the black insertion operation, it continues to provide drive data based on the backlight data. The backlight assembly can continue to provide backlight and adjust the average brightnesses of the frames of the image display based on the backlight to keep them consistent, thereby reducing the flickering phenomenon in the image display.

The following specific embodiments are used to describe the implementation of the present application in detail. The following specific embodiments can be combined with each other, and the same or similar concepts or processes may not be described in detail in some embodiments.

In some embodiments, the processor may be configured to obtain image data of a frame and a frame start trigger signal.

In some embodiments, the processor acquires image data of the current frame based on the received video signal.

The image data may include display data and backlight data.

In some embodiments, the processor can be configured to obtain a frame start trigger signal and a row synchronization signal at the start moment of each frame, calculate the display time length of the current frame based on the row synchronization signal, and determine the display period of the current frame based on the frame start trigger signal and the display time length of the current frame.

In some embodiments, the frame start trigger signal may be a Vsync signal, or a time point represented by other forms, such as a command on software, etc., which is not specifically limited here.

In some embodiments, the row synchronization signal is an Hsync signal.

In some embodiments, the processor may be configured to calculate a refresh rate of the current frame based on the row synchronization signal, and determine a display time length of the current frame based on the refresh rate of the current frame.

Calculating the refresh rate of the current frame based on the row synchronization signal may include: after obtaining the frame start trigger signal, determining to enter a new frame display, and in the process of refreshing row by row, each time an Hsync signal is obtained, starting the image display of a scanned row (or scanned column): adjusting the flip state of the liquid crystal molecules in this row and adjusting the luminous state of the light beads corresponding to the liquid crystal molecules in this row.

Since the quantity of rows of liquid crystal molecules in the display panel is fixed, after obtaining two Hsync signals during the display period of the current frame, the frequency of the row synchronization signal in the current frame is determined based on the above two Hsync signals, and the refresh rate of the current frame is determined by dividing the frequency of the row synchronization signal by the quantity of rows.

In some embodiments, when calculating the display time length of a frame based on the refresh rate obtained by the above calculation, the quotient of 1 divided by the refresh rate is used as the display time length of the frame corresponding to the refresh rate. For example, the length of the display period corresponding to 144 Hz is 1/144s, and the length of the display period corresponding to 80 Hz is 1/80s.

In some embodiments, the processor obtains a frame start trigger signal at the start moment of each frame to determine the start moment of the display period, and calculates the end moment of the current frame based on the start moment and the display time length of the current frame to determine the display period of the current frame.

In some embodiments, in the display panel, multiple liquid crystals simultaneously for displaying are grouped into liquid crystal molecule groups based on a scanning method, and the division method of the light-emitting unit groups in the backlight assembly is determined according to the division method of the liquid crystal molecule groups.

In some examples, in a display apparatus based on row scanning display, the liquid crystal molecule groups and the light-emitting unit groups are divided by rows; and in a display apparatus based on column scanning, the liquid crystal molecule groups and the light-emitting unit groups are divided by columns.

In application, the quantities of rows or columns of light beads in the light-emitting unit groups can be the same, so that the corresponding quantity of rows and columns in each backlight data segment are the same. When the processor processes the data, it is not necessary to distinguish the backlight data segments, thereby reducing the processing burden of the processor and improving the processing efficiency of the processor. Of course, the quantities of rows or columns of light beads in the light-emitting unit groups can also be different. In contrast, there is no limitation in this example.

Taking the row-by-row scanning of liquid crystal molecule groups as an example, the liquid crystal molecule groups in rows are flipped row by row according to a preset scanning order, and the moment when the liquid crystal molecules in each row start to be flipped is the start moment of the display period of the corresponding light-emitting display group in the current frame. When the display apparatus displays a frame of image, according to the preset scanning order, the delay time of the start moment of the display period of each row of the light-emitting display group relative to the moment when the processor obtains the frame start trigger signal gradually increases.

In some embodiments, the processor may be configured to, in response to a frame start trigger signal, not output drive data during a black insertion period in a current frame display period.

The black insertion period may include an unstable period of liquid crystal molecules in the current frame.

In some embodiments, the backlight assembly 20 may be configured not to provide backlight and the display apparatus not to display an image when no drive data is obtained.

In some embodiments, the processor may be configured to determine initial dimming data based on the backlight data within at most two light-emitting periods in the current frame display period.

At most two light-emitting periods are located within the stable period of the liquid crystal molecules in the display panel.

In each frame display period, the non-black insertion period is the total light-emitting period.

The time length of each frame display period is determined based on the refresh rate of the current frame, and the refresh rate of the current frame is less than or equal to the maximum refresh rate of the display panel.

In some embodiments, the maximum refresh rate of the display panel is generally 144 Hz.

In some embodiments, the initial dimming data is dimming data determined by the processor based on the backlight data after taking backlight black insertion into account when the refresh rate of the current frame display period is the maximum refresh rate of the display apparatus.

In some embodiments, the processor may be configured to output drive data based on the initial dimming data, and the drive data may include a current value corresponding to each light-emitting period.

The average current value of the current values corresponding to at most two light-emitting periods in the current frame display period is the product of the initial dimming data and the light-emitting ratio.

In some embodiments, the sum of the light-emitting ratio and the black insertion ratio is 1. The black insertion ratio is the ratio of the black insertion time length determined for the maximum refresh rate of the display panel to the total display period. The black insertion time length is determined based on the deflection characteristics of the liquid crystal molecules on the display panel.

In some embodiments, the backlight assembly 20 may be configured to provide backlight based on the drive data, and the greater the average current value, the brighter the backlight generated by the backlight assembly 20.

In the process of the display apparatus displaying multiple frames of images continuously, when the refresh rates are different and the displayed images are the same, since the average current value obtained by the backlight assembly 20 is the same, the average brightness of the backlight provided by the backlight assembly 20 during each frame display period remains consistent, thereby reducing the flickering phenomenon of the display screen.

FIG. 48 is a flow chart of a backlight control method for a display apparatus according to some embodiments, where in this embodiment, a processor executes the backlight control method provided in this embodiment. As shown in FIG. 48, the backlight control method may include the following steps.

S401, the processor obtains image data of one frame and a frame start trigger signal; and the image data may include backlight data.

S402, the processor, in response to the frame start trigger signal, outputs no drive data during the black insertion period in the current frame display period.

S403, the processor determines initial dimming data based on backlight data within at most two light-emitting periods in the current frame display period.

S404, the drive data is output based on the initial dimming data, so that the backlight assembly provides backlight based on the drive data; and the drive data may include a current value corresponding to each light-emitting period.

The average current value of the current values corresponding to at most two light-emitting periods in the current frame display period is the product of the initial dimming data and the light-emitting ratio.

In the above embodiment, after obtaining the image data of a frame and the frame start trigger signal, the processor in the display apparatus responds to the frame start trigger signal to control the backlight assembly to complete the black insertion operation, and then determines the initial dimming data based on the backlight data. Based on the initial dimming data, the drive data is output so that the average current value obtained by the backlight assembly in each frame of the image display is the same, and the corresponding average brightness of the backlight provided is consistent, thereby reducing the flickering phenomenon in the image display.

In some embodiments, when the processor generates drive data to regulate the light emission of the backlight assembly 20, the luminous brightness of at most two light-emitting periods may be uniformly regulated.

That is, the processor determines the initial dimming data based on the backlight data, determines the stable current value based on the total light-emitting time length and the black insertion time length of at most two light-emitting periods, and continuously outputs the drive data of the stable current value within at most two light-emitting periods, so that the average brightness generated by the backlight assembly 20 within a frame display period based on the stable current value is the same.

The following is an exemplary introduction to a scheme in which the controller adjusts the power supply voltage output by the power supply circuit based on the levels of each input terminal of the drive circuit.

In some embodiments, for each frame, the controller is configured to enter a detection stage when it detects that drive data has been sent to each input terminal of the drive circuit; and the controller is configured to increase the power supply voltage output by the power supply circuit when at least one of the input terminals is at the first level.

In some other embodiments, the controller is configured to increase the power supply voltage of the power supply circuit according to a first preset step length if at least one of the input terminals of the drive circuit is at the first level; if the increased voltage makes all the input terminals of the drive circuit at the second level, the predetermined voltage under the preset current is determined based on the increased voltage.

The preset current is only a preset initial current, and the specific size is not specifically limited.

For example, if the current level is the first level, the power supply voltage U=U1, and the first preset step length is ΔU1, then U=U1+ΔU1 is adjusted up: if there is still an input terminal at the first level, U=U1+2ΔU1 is adjusted up again; and if all input terminals are currently at the second level, the predetermined voltage under the preset current is determined based on U=U1+2ΔU1.

In some examples, the voltage at the second level at each input terminal of the drive circuit can be adjusted to be the predetermined voltage under the preset current. It can be understood that the voltage, such as U=U1+2ΔU1 in the above example, changes the light-emitting unit from an undervoltage state to an overvoltage state.

In some examples, the controller is further configured to decrease the power supply voltage of the power supply circuit according to a second preset step length if all input terminals of the drive circuit are at the second level, and if the decreased voltage causes at least one input terminal of the drive circuit to become the first level, determine the predetermined voltage under the preset current based on the voltage that caused all input terminals of the drive circuit to be at the second level last time.

For example, if the current level is the second level, the power supply voltage U=U1, and the second preset step length is ΔU2, then U=U1−ΔU2 is lowered: if the current input terminals are all at the second level, U=U1−2ΔU2 is lowered again: if there is still an input terminal at the first level, the predetermined voltage under the preset current is determined based on U=U1−ΔU2.

In some examples, the voltage that causes each input terminal of the drive circuit to be at the second level last time is used as the predetermined voltage under the preset current, that is, U=U1−ΔU2 can be used as the predetermined voltage under the preset current.

In other examples, a voltage between the current lowered voltage and the voltage that caused all input terminals of the drive circuit to be at the second level last time can be estimated as the predetermined voltage under the preset current, for example, a value is selected between U=U1−ΔU2 and U=U1−2ΔU2.

In some embodiments, the controller is further configured to fit the current-voltage relationship of the light-emitting unit group based on the predetermined current and the preset voltage.

he current-voltage relationship of the light-emitting unit group represents the mapping relationship between the value of current flowing through the light-emitting unit group and the corresponding power supply voltage value when different power supply voltage values are applied to the light-emitting unit group. The current-voltage relationship is, when controlling the drive chip adjusts the current value of the light-emitting unit group to the preset current value during the test of the backlight assembly, the mapping relationship between the minimum power supply voltage value provided by the power supply circuit and the preset current value, while ensuring that each light-emitting unit group is not under-voltaged.

In some embodiments, the controller is further configured to obtain a frame of image data, and based on the image data and the current-voltage relationship, determine the target current and the target power supply voltage corresponding to the target current, and output the target power supply voltage to the light-emitting unit group. The image data includes backlight data and display data, where the backlight data is data for driving the backlight assembly to emit light, and the display data is data for driving the liquid crystal display panel to display.

In some embodiments, the current-voltage relationship is determined by fitting during the power-on initialization process of the display apparatus. That is, during the power-on initialization process, the display apparatus enters the detection stage. After the initialization is completed, it enters the data transmission stage.

In one embodiment, the controller is further configured to generate drive data corresponding to each light-emitting unit group based on the backlight data.

In some embodiments, the drive data includes a target current, which is data for adjusting the luminous brightness of the light-emitting unit group per unit time. During the process of displaying each frame of an image by the display apparatus, the backlight assembly provides backlight for the same time length in each frame of an image, and the drive chip is configured to drive the light-emitting unit group to generate backlights of different brightnesses based on the target current.

In some embodiments, the drive data includes a duty ratio, which is data for adjusting the time length of light emission of the light-emitting unit group in each frame display cycle. During the process of displaying each frame of an image by the display apparatus, the backlight assembly provides the same target current for backlight in each frame of an image, and the drive chip is configured to drive the light-emitting unit group to generate backlights of different brightnesses based on the duty ratio.

In some embodiments, the drive data includes a target current and a duty ratio, and the drive chip is configured to jointly control the brightness of the light-emitting unit group based on the target current and the duty ratio.

In some embodiments, the display apparatus uses hybrid dimming to adjust the backlight brightness of the backlight assembly in each frame.

When the display apparatus displays a frame of image, the controller adjusts the current values obtained by the light-emitting unit groups to be the same, but with different duty ratios. When displaying brightnesses of different values, the brightnesses are differentiated by adjusting the size of the duty ratio.

When the display apparatus displays different frame images, the current values obtained by the controller adjusting the light-emitting unit groups are not completely the same.

FIG. 7 is a hybrid dimming schematic diagram provided by the present application, including drive data corresponding to the four-row and five-column light-emitting unit groups. The current value of each backlight sub-unit is the same, which is 70 mA, and the duty ratios of the backlight sub-units are different. The brighter the brightness, the greater the duty ratio, and the darker the brightness, the smaller the duty ratio.

In some embodiments, the controller is configured to determine a target voltage at a target current based on a current-voltage relationship and a current value.

In some embodiments, the controller is configured to control the power supply circuit to output a target voltage to the light-emitting unit group.

Since the target currents of the backlight sub-units are the same during the display of one frame of image, ideally, the target voltages corresponding to the backlight sub-units are also the same. Therefore, when determining the power supply voltage of each backlight sub-unit, the target current is determined based on the backlight data generated by the component, and then based on the target current and the pre-fitted current-voltage relationship, the target voltage that the power supply circuit needs to provide to the backlight sub-unit when the backlight sub-unit displays the image of the current frame is determined.

In the above embodiment, when the display apparatus adjusts the power supply voltage of multiple light-emitting unit groups in the backlight assembly, the current-voltage relationship of the light-emitting unit group is obtained. When the display apparatus obtains a frame of image data, the drive data of each light-emitting unit group is determined based on the backlight data in the image data. Since the display apparatus adopts hybrid dimming, during the display of one frame of the image, the current value provided by the light-emitting unit groups in the backlight assembly are always the same. Therefore, the power supply voltage can be determined based on the mapping relationship between the power supply voltage and the current value determined in advance in the current value and the current-voltage relationship of the light-emitting unit group. It is no longer necessary to obtain the feedback signals related to the light-emitting unit group from the drive chip, so the transmission path of the drive data is no longer occupied, thereby ensuring the transmission rate of the drive data. Moreover, since the current-voltage relationship of the light-emitting unit group is pre-fitted, the consistency of the backlight circuit based on hybrid dimming ensures the accuracy of determining the power supply voltage, thereby ensuring the display accuracy.

The fitting of the current-voltage relationship involved in the above embodiment is explained below.

In one embodiment, the controller obtains the power supply voltage of the light-emitting unit group at a predetermined current and/or the current of the light-emitting unit group at a predetermined supply voltage.

In the process of sampling the voltage-current data group, since the power supply voltage values provided by the power supply circuit have a minimum value, when the current value of the light-emitting unit group is too small, the power supply voltage value required during the light-emitting process is also small. At this time, the minimum power supply voltage value provided by the power supply circuit is significantly larger than the power supply voltage required by the light-emitting unit group. When sampling the operating state of the light-emitting unit group, the power supply voltage values obtained when a small current flows through it are all the minimum power supply voltage, and the sampling data may be inaccurate. Therefore, it is necessary to sample the minimum point (data corresponding to the minimum current and the minimum power supply voltage) within the effective light-emitting range of the light-emitting unit group.

In one embodiment, the current-voltage relationship of the light-emitting unit group is fitted based on the predetermined current and the power supply voltage of the light-emitting unit group at the predetermined current, and/or the predetermined supply voltage and the current of the light-emitting unit group at the predetermined supply voltage obtained above.

When fitting the current-voltage relationship based on at least two sets of current-voltage data, multiple sets of data may be linearly fitted, or fitted based on other fitting methods, such as least squares fitting, polynomial fitting, or non-parametric fitting.

After at least two sets of voltage-current data are determined to fit the voltage-current relationship based on the above embodiment, the fitting accuracy of the current-voltage relationship is tested before application: at least one test current is determined within the current range in the current-voltage relationship, and the power supply voltage value corresponding to each test current is determined based on the current-voltage relationship.

The controller controls the power supply circuit to provide the above power supply voltage value to each light-emitting unit group, and controls the drive chip to provide the corresponding test current, and then the drive chip samples the state of each light-emitting unit group.

In some embodiments, when the display tests the fitted current-voltage relationship, when it is determined that at least one light-emitting unit group is in an undervoltage state, the power supply voltage corresponding to each current in the current-voltage relationship is compensated by a preset compensation voltage.

For example, after the current-voltage relationship is fitted, the controller determines that the current value in the drive data is 2A based on the backlight data, and determines that the corresponding supply voltage is 5V in the current-voltage relationship. The controller controls the power supply circuit to output a power supply voltage of 5V. When it is determined that at least one light-emitting unit group is in an under-voltage state based on the sampled state feedback from the drive chip, the controller controls the power supply voltage output by the power supply circuit to increase the preset compensation voltage.

In one embodiment, the preset compensation voltage is 0.2V.

In some other embodiments, the controller fits the current-voltage relationship at a preset temperature, and during the use of the current-voltage relationship, measures the temperature of the display apparatus. When it is determined that the temperature has been adjusted, a voltage adjustment coefficient is determined based on the present temperature and the preset temperature. When the power supply voltage is determined at the present temperature, the power supply voltage corresponding to the current at the preset temperature is determined based on the current value and the current-voltage relationship, and the product of the power supply voltage and the voltage adjustment coefficient is determined as the power supply voltage at the present temperature.

In some embodiments, as the temperature of the display apparatus decreases, the power supply voltage value corresponding to the same current increases.

In some embodiments, the temperature measurement of the display apparatus may be the temperature measurement of the light board, the temperature measurement of the drive chip, the temperature measurement of the controller, or the temperature measurement of the surrounding environment of the display apparatus. When determining the temperature, it may be any of the above temperatures, or it may be a calculated value of at least two temperatures, for example, a weighted calculation.

In some embodiments, the present application also provides a drive circuit as described in any of the above embodiments.

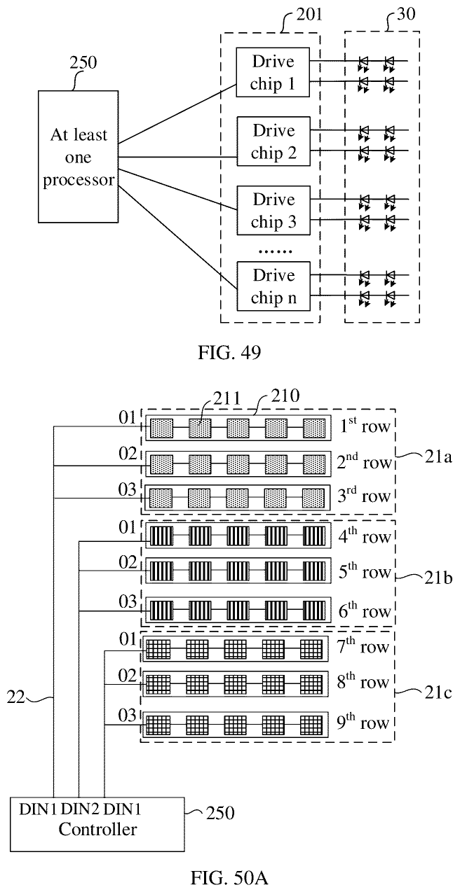

FIG. 49 is a schematic diagram of coupling an example of multiple drive chips and at least one controller. As shown in FIG. 49, each drive chip 20 needs to receive drive data sent by at least one controller 250, and each drive chip 211 is connected to at least one light bead 301. The drive chip 211 drives the corresponding light beads 301 according to the received data. For example, in a Mini-LED or Micro-LED display apparatus, the quantity of drive chips in the drive circuit is very large, so a large quantity of flexible flat cables (FFC) are required. The size and cost of FFC are relatively high, and the current display apparatus has the requirement of being thin and light, which greatly increases the manufacturing difficulty and manufacturing cost of the display apparatus.

Therefore, it is important to reduce the quantity of data lines connected between at least one controller and the drive circuit in a display apparatus.

To this end, the embodiments of the present application provide a drive circuit, a controller, and a display apparatus. In the drive circuit, multiple drive chips are divided into a drive group in units of corresponding rows or columns, and multiple drive groups are divided into a drive unit. Each drive group is provided with preset calibration information. The controller can send drive data to the corresponding drive group based on different preset calibration information. In this way, the controller can communicate with multiple drive groups with preset calibration information through one data line, without having to communicate with the drive groups separately through multiple data lines. Therefore, this solution can reduce the quantity of data lines connected between the controller and the drive circuit, thereby reducing the manufacturing difficulty and manufacturing cost of the display apparatus.

The present application is described in detail with specific embodiments below. The following specific embodiments can be combined with each other, and the same or similar concepts or processes may not be repeated in some embodiments. In the description of the present application, unless otherwise clearly specified and limited, each term should be understood in a broad sense in the art. The embodiments of the present application will be described below in conjunction with the accompanying drawings.

FIG. 50A is a structural schematic diagram 1 of the drive circuit provided in an embodiment of the present application, as shown in FIG. 50A.

In some embodiments, the drive circuit 202 includes at least one drive unit 21 and at least one data line 22, where the drive unit 21 corresponds to the data line 22.

In some embodiments, the drive unit 21 includes at least one drive group 210, where the drive group 210 includes at least one drive chip 211.

In some embodiments, the drive chips 211 in the same drive group 210 may be connected in series.

In some embodiments, the drive chips 211 in the same drive group 210 may be connected in parallel.

In some embodiments, the drive group 210 is configured with preset calibration information, where the preset calibration information of different drive groups 210 in the same drive unit 21 is different.

In some embodiments, the drive unit 21 is connected to at least one controller 250 via the corresponding data line 22.

In some embodiments, at least one controller 250 is configured to send drive data to the target drive group 210 based on preset calibration information of the target drive group 210, so that each drive chip 211 under the target drive group 210 obtains corresponding drive data.

In some embodiments, the drive chip 211 is connected to at least one light bead 301 in the light board 30, and the drive chip 211 is configured to drive at least one light bead 301 according to drive data; where the light board 30 includes a plurality of light beads 301 arranged in an array.

Combined with an example: as shown in FIG. 50A, the drive circuit includes a first drive unit 21a, a second drive unit 21b and a third drive unit 21c. The first drive unit 21a includes drive groups from the 1^{st} row to the 3^{rd} row, and the preset calibration information of each drive group is 01, 02, and 03 in sequence; the second drive unit 21b includes drive groups from the 4^{th} row to the 6^{th} row, and the preset calibration information is 01, 02, and 03 in sequence; and the third drive unit 21c includes drive groups from the 7^{th} row to the 9^{th} row, and the preset calibration information is 01, 02, and 03 in sequence. It can be seen that the preset calibration information of different drive groups in each drive unit is different; the three drive units are connected to the control module 10 through the data line DIN1, the data line DIN2, and the data line DIN3 respectively, and each drive chip 211 under the drive unit obtains the corresponding drive data.

FIG. 50B is a schematic structural diagram of the drive circuit in the related art. As shown in FIG. 50B, the drive circuit includes 9 drive groups 210. These drive groups 210 are not set with preset calibration information. The control module 10 cannot identify each drive group 210, so it is necessary to send drive data to the corresponding drive group separately through 9 data lines. In this way, the control module needs to communicate with the 9 drive groups through 9 data lines. However, the control module in the solution of FIG. 50A only needs 3 data lines to communicate with the 9 drive groups.

From the above, it can be seen that compared with the related art of FIG. 50B, the example of FIG. 50A can reduce the quantity of data lines between the control module and each drive group, thereby reducing the quantity of data lines in the drive circuit.

There are many ways for the drive group 210 to set the preset calibration information, which will be described exemplarily below.

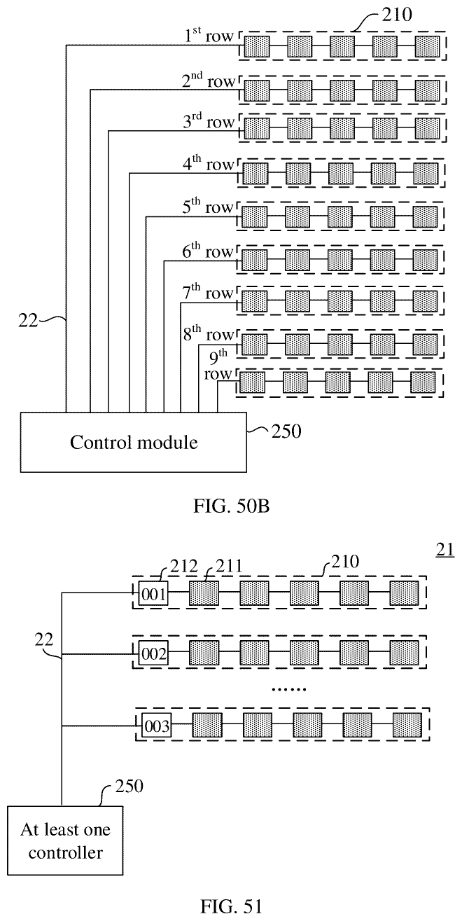

As an example, FIG. 51 is a second structural schematic diagram of the drive circuit provided in an embodiment of the present application. As shown in FIG. 51, the drive group 210 also includes an address chip 212, and the address chip 212 is set with an address. The preset calibration information of the drive group 210 includes the address of the address chip 212 under the drive group 210.

As another example, at least one drive chip 211 in the drive group 210 is provided with a physical address, the drive chips 211 in the same drive group 210 have the same physical addresses, and the preset calibration information of the drive group 210 includes the physical addresses of the drive chips 211 thereunder.

The following will provide examples for both methods.

For example, the drive group 210 includes the address chip 212, as shown in FIG. 51, each drive group 210 includes an address chip 212. For example, the first drive group 210 includes the first address chip 212, and the second drive group 210 includes the second address chip 212. The address of the first address chip 212 is 001, and the corresponding preset calibration information of the first drive group 210 is 001, the address of the second address chip 212 is 002, and the corresponding preset calibration information of the second drive group 210 is 002, and so on.

In this embodiment, the preset calibration information of the drive group is set by additionally setting the address chip, which will not affect the drive chip, thereby improving the versatility of the drive chip.

In some embodiments, the address chip 212 may be disposed before the drive chip 211 located first of the drive group 210 to which it belongs.

In some embodiments, the address chip 212 may be disposed after the drive chip 211 located last of the drive group 210 to which it belongs.

In some embodiments, the address of the address chip 212 may be a burning address.

In some embodiments, the address chip 212 is connected to at least one controller and at least one drive chip 211.

In some embodiments, the address chip 212 is connected to the controller via a data line corresponding to the drive unit.

In some embodiments, the address chip 212 may be configured to receive drive data of the drive group 210 sent by the controller through the data line 22.

In some embodiments, the address chip 212 may be configured to divide the drive data of the drive group 210 into at least one drive data segment in sequence, and at least one data segment corresponds to at least one drive chip 211.

The lengths of the drive data segments may be the same or different, and may be determined according to the quantity of channels of the drive chip 211.

In some embodiments, the address chip 212 may also be configured to send a drive data segment to a corresponding drive chip 211.

In the above embodiment, the address chip 212 receives the drive data of the drive group 210, divides the drive data into multiple data segments, and sends the drive data segments. In this way, the controller does not need to divide the drive data, so the processing burden of the controller can be reduced, thereby improving the efficiency of the drive chip 211 in receiving the drive data segments.

The embodiment of the present application does not limit the manner in which the address chip 212 sends the drive data segment to the corresponding drive chip 211.

As an implementation method, the drive chip 211 is provided with an internal address, and different drive chips 211 under the same drive group 210 have different internal addresses. After the drive data of the drive group 210 is divided into at least one drive data segment in sequence, the address chip 212 is further configured to, for the drive data segment, add the internal address of the corresponding drive chip 211 to the drive data segment.

Based on the internal address in the drive data segment, the drive data segment is sent to the corresponding drive chip 211.

In this implementation, the drive chip 211 is provided with an internal address, where in the example where the drive chips 211 under the same drive group 210 are serial, the internal address can be a serial address or a burning address. The address chip 212 can add the internal address of the drive chip 211 to the identification bit of the drive data segment, and when sending, the data segment can be sent to the corresponding drive chip 211 based on the internal address of the identification bit. Since each drive data segment includes a corresponding internal address, the address chip 212 can send each drive data segment out of sequence, thereby improving the flexibility of data transmission.

As another implementation method, the order of the drive data segments is consistent with the order of the corresponding drive chips 211; and when sending the drive data segments to the corresponding drive chips 211, the address chip 212 is specifically configured to: send the drive data segments to the drive chips 211 in the drive group 210 in sequence.

In this embodiment, each drive data segment is not provided with an address, and the order of the drive data segments corresponds to the order of the drive chips 211, that is, the position of the drive data segment in the drive data is consistent with the position of the drive chip 211 in the drive group 210. Directly in the order from left to right or from right to left, each drive data segment is sent to the corresponding drive chip 211 in sequence. In this implementation, the sending can only be done sequentially, but since there is no need to add addresses to the drive data segments, the processing tasks of the address chip 212 are reduced, thereby improving the efficiency of data transmission.

In some embodiments, the address chip 212 is configured to receive drive data of the drive group 210 and store it in the first memory; where the drive data of the drive group 210 includes at least one drive data segment, and the at least one data segment corresponds to the at least one drive chip 211.

In this embodiment, the controller divides the drive data, and the address chip 212 receives the divided drive data. The address chip 212 stores the received drive data including each drive data segment into the first memory.

In some embodiments, during storage, for each frame of data, the drive data stored in the current frame may overwrite the drive data stored in the previous frame.

In some embodiments, the drive chip 211 is configured to read the corresponding drive data segment from the first memory.

In this embodiment, the drive chip 211 can actively read the drive data segments in the first memory, so that the drive chip 211 can read synchronously without waiting for sequential transmission, thereby improving the efficiency of the drive chip 211 in acquiring the drive data segments.

In some embodiments, the first memory includes at least one storage unit, and the at least one storage unit corresponds to at least one drive chip 211.

In some embodiments, the address chip 212 is specifically configured to store the drive data segment into a corresponding storage unit.

In some embodiments, the drive chip 211 is specifically configured to read the drive data segment from the corresponding storage unit.

In this embodiment, the storage units in the first memory correspond to the drive chips 211 one by one, and each storage unit only stores the drive data segment corresponding to the drive chip 211. The drive chip 211 can obtain the drive data segment by reading the corresponding storage unit. For example, the drive group 210 includes 5 drive chips 211, and the first memory includes 5 storage units, where the drive chips 211 No. 001 to No. 005 correspond to the storage units No. 101 to No. 105, respectively, and the drive chip 211 No. 001 reads the data in the storage unit No. 101. Similarly, the drive chip 211 No. 002 reads the data in the storage unit No. 102.

In some other embodiments, the drive chip 211 is provided with an internal address, and different drive chips 211 in the same drive group 210 have different internal addresses; where the drive data segment includes the internal address of the corresponding drive chip 211.

In this embodiment, the controller has configured an internal address for each drive data segment, and the address chip 212 can store the drive data segment in a corresponding storage unit in sequence, or can store the drive data segment randomly in the storage unit.

In some other embodiments, the drive chip 211 is specifically configured to read the corresponding drive data segment from the first memory based on the internal address of the drive chip 211.

In this embodiment, the drive chip can read the drive data segment including its internal address from the first storage unit, so as to improve the flexibility of the address chip in storing data.

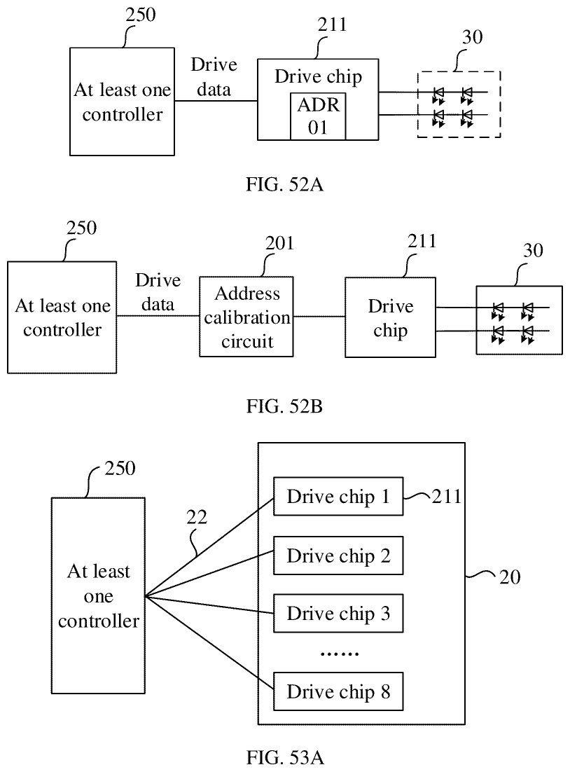

For example, the drive group includes at least one drive chip set with a physical address, and FIG. 52A is a structural schematic diagram of the drive chip provided in an embodiment of the present application. As shown in FIG. 52A, the drive chip 211 is provided with an address pin ADR, and the address pin ADR is configured to be provided with the physical address of the drive chip 211.

At least one controller 250 is connected to the drive chip 211. The at least one controller 250 is configured to send drive data to the drive chip 211 based on the address of the drive chip 211. The address of the drive chip 211 includes the physical address of this chip.

The drive chip 211 is connected to at least one light bead 301, and the drive chip 211 is configured to drive at least one light bead 301 according to the drive data. In another case, another structural schematic diagram of the drive chip 211 is shown in FIG. 52B.

A corresponding address calibration circuit 201 is disposed in front of the drive chip 211. The control terminal and the first terminal of the address calibration circuit 201 are connected to at least one controller 250. The output terminal of the address calibration circuit 201 is connected to the input terminal of the corresponding drive chip 211.

The address calibration circuit 201 is configured to obtain address data output by at least one controller 250 from its control terminal, and when the address data includes the address of the drive chip 211 electrically connected to it, send the drive data obtained by its first terminal to the corresponding drive chip 211. Different address calibration circuits 201 correspond to different address data.

The drive chip 211 is connected to at least one light bead, and the drive chip 211 is configured to drive at least one light bead according to drive data.

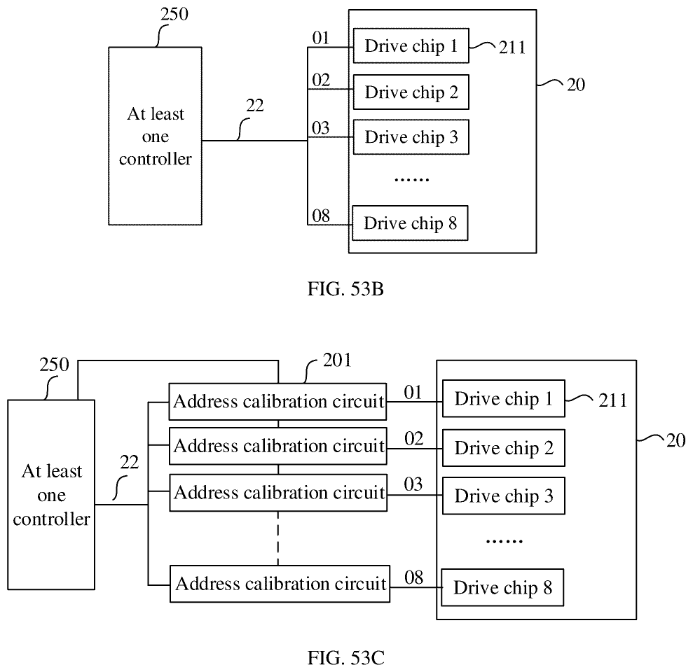

The following is an exemplary description in combination with actual scenarios. FIG. 53A is a structural schematic diagram three showing the drive circuit of some embodiments of the present disclosure. As shown in FIG. 53A, the drive circuit 20 includes 8 ordinary drive chips 212 without physical addresses. Since the 8 ordinary drive chips 212 are identical and cannot be identified, at least one controller 250 can only be connected to the four ordinary drive chips 211 through 8 data lines respectively, and send drive data to the corresponding ordinary drive chips 211 through the 8 data lines.

FIG. 53B is a fourth structural schematic diagram of a drive circuit provided in an embodiment of the present application. As shown in FIG. 53B, the drive circuit 20 includes 8 drive chips 211 with physical addresses. The physical addresses of the 8 drive chips 211 are different, i.e., 01, 02, 03, . . . 08. At least one controller 250 is connected to the substrate where the 8 drive chips 211 are located through a data line, and drive data is sent through the data line. The drive data can carry the physical address of the drive chip 211, so that based on the physical address, the drive data can be sent to the corresponding drive chip 211. As can be seen from the above, the drive circuit in FIG. 53B can reduce 7 data lines relative to the drive circuit in FIG. 53A.

In this embodiment, the drive chip is set with a physical address based on the address pin, and at least one controller can send drive data to multiple drive chips with different physical addresses through a data line without connecting at least one controller to the drive chip respectively. This can reduce the quantity of data lines connected between at least one controller and the drive chip, thereby reducing the quantity of FFCs connected between at least one controller and the drive circuit in the display apparatus.

FIG. 53C is a structural schematic diagram 5 of the drive circuit provided in the embodiment of the present application. As shown in FIG. 53C, the drive circuit 20 includes 8 drive chips 211 and 8 address calibration circuits. The address data of the 8 address calibration circuits are different, and the address data are 000, 001, 010 . . . , 111 respectively. At least one controller 250 is electrically connected to the substrate where the 8 address calibration circuits are located through 4 data lines, where 3 data lines are configured to transmit address data, and 1 data line is configured to transmit drive data. In this way, the corresponding address calibration circuit is controlled to be turned on based on the address information transmitted by the 3 data lines, and the drive data obtained at its input terminal is transmitted to the corresponding drive chip 211. As can be seen from the above, the drive circuit in FIG. 53C can reduce 4 data lines relative to the drive circuit in FIG. 53A.

The following is an exemplary introduction to the setting of the physical address of the drive chip.

In some embodiments, the drive chip 211 may further include: a plurality of functional pins, each functional pin corresponds to a physical address, and different functional pins correspond to different physical addresses.

In some embodiments, the address pin is connected to a functional pin; the physical address of the drive chip 211 is the physical address corresponding to the functional pin connected to the address pin.

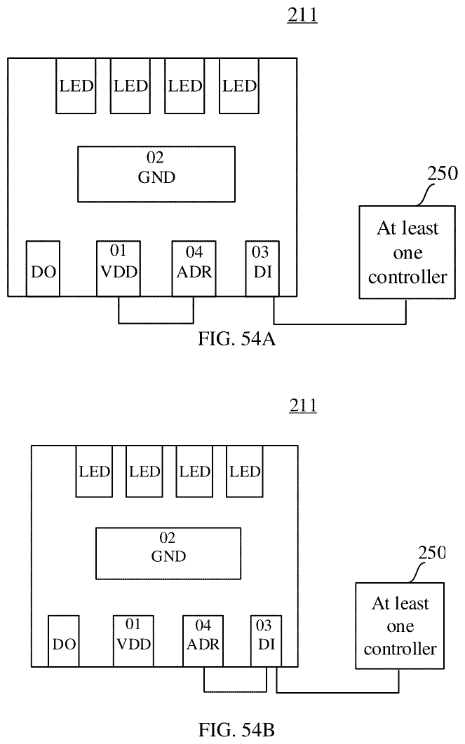

Taking an example in combination with an actual scenario, FIG. 54A is a schematic structural diagram of a drive chip with a physical address in one example, and FIG. 54B is a schematic structural diagram of a drive chip with a physical address in another example. As shown in FIG. 54A and FIG. 54B, the functional pins include a power supply pin VDD, a data input pin D1, and a ground pin GND, and the corresponding physical addresses are 01, 02, and 03, respectively. The address pin ADR is connected to any functional pin, and the physical address of the address pin is the same as the physical address of the functional pin. Referring to FIG. 54A, the address pin ADR is connected to the power supply pin VDD. Since the physical address of the power supply pin VDD is 01, the physical address of the drive chip 211 is 01. As shown in FIG. 54B, the address pin ADR is connected to the data input pin D1. Since the physical address of the data input pin D1 is 03, the address pin ADR of the drive chip 211 is 03. In practical applications, in order to increase the quantity of physical addresses of the drive chips 211, the physical address of the address pin ADR may be preset to 04, that is, when the address pin ADR is in a vacant state, the physical address of the drive chip 211 is 04.

The following is an introduction to the principle of the drive chip sensing the physical address. Continuing to refer to 9A and 9B, the drive chip 211 can obtain the corresponding physical address by detecting the level of the address pin ADR. Combined with the above FIGS. 54A and 81B, the functional pins include the power supply pin VDD, the data input pin D1, the ground pin GND and the vacant (the address pin ADR itself), and different functional pins correspond to different levels.

When the address pin ADR is connected to the power supply pin VDD, since the power supply pin VDD is at a high level, the address pin ADR is at a high level; when the address pin ADR is connected to the ground pin GND, since the ground pin GND is at a low level, the address pin ADR is at a low level; when the address pin ADR is connected to the data input pin D1, since the level of the data input pin D1 is the same as the level of the input data, and the level of the input data is changing, the address pin ADR is at a changing level; when the address pin ADR is vacant, the address pin ADR has no level. Therefore, the drive chip 211 can sense the physical address of the drive chip 211 based on the level of the address pin ADR.

In this embodiment, based on the connection between the address pin and the functional pin, the physical address of the functional pin is determined as the physical address of the drive chip. The above scheme only adds connections between the existing functional pins and no additional components are set to obtain the physical address. In this way, the physical address of the drive chip can be obtained based on a simple structure.

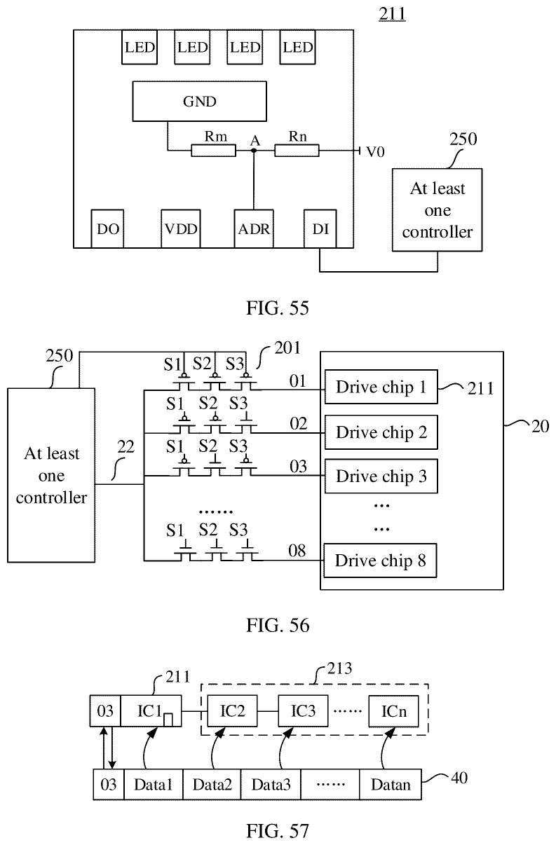

Since the quantity of functional pins of the drive chip is limited, in order to obtain more physical addresses, in some other embodiments, FIG. 55 is a schematic structural diagram of a drive chip in another example. As shown in FIG. 55, the drive chip 211 further includes: a sampling resistor Rm, where one terminal of the sampling resistor Rm receives a fixed voltage V0, another terminal of the sampling resistor Rm is connected to the address pin ADR, and different resistance values of the sampling resistor Rm correspond to different physical addresses; and a fixed resistor Rn, one terminal of the fixed resistor Rn is connected to another terminal of the sampling resistor Rm, and another terminal of the fixed resistor Rn is grounded.

In this example, as shown in FIG. 55, the sampling resistor Rm and the fixed resistor Rn are voltage-dividing resistors, and the resistance value of the fixed resistor Rn remains unchanged, so the resistance value of the sampling resistor Rm affects the voltage at point A, thereby affecting the voltage at the address pin ADR. For example, the larger the resistance value of the sampling resistor Rm, the larger the voltage at point A, and the larger the voltage at the address pin ADR. A corresponding relationship is set between the physical address and the voltage, so the physical address of the drive chip 211 at the current voltage can be obtained by detecting the voltage of the address pin ADR and based on the corresponding relationship between the physical address and the voltage. In this way, the quantity of physical addresses of the drive chips 211 can be free from the quantity of functional pins of the drive chip 211, so this example can obtain more drive chips with different physical addresses.

FIG. 56 is a structural schematic diagram of a drive chip provided with an address calibration circuit in an example. As shown in FIG. 56, each address calibration circuit is provided with three switching transistors, and the conduction mode of each switching transistor includes low-level conduction or high-level conduction. In order from left to right, the types of the three switching transistors correspond to their corresponding address data. For example, when the address data corresponding to the three switching transistors is 010, and the types of the switching transistors are PMOS, NMOS, and PMOS, they are turned on when corresponding to low level, high level, and low level. Each level corresponds to an address bit. According to the arrangement order of the three switching transistors, the address data containing the address bits corresponding to the low level, high level, and low level are represented by digital signals as 010, the address calibration circuit is turned on, and the drive chip electrically connected thereto obtains the drive data.

In this embodiment, address gating can be achieved by arranging a small quantity of controllable switching transistors upstream of the drive chip, thereby simplifying the circuit structure and reducing the difficulty of manufacturing the display apparatus.

In some embodiments, FIG. 57 is a structural schematic diagram of the drive group of some embodiments of the present disclosure. As shown in FIG. 57, each drive group includes a first drive chip 211 and multiple second drive chips 213 connected in series (the second drive chip 213 is a common drive chip), and the first drive chip 211 is located before the multiple second drive chips 213. The first drive chip 211 is a drive chip with a physical address set in any of the above embodiments, and the physical address of the first drive chip 211 is the preset calibration information of the drive group to which it belongs.

In this example, the drive group includes only one first drive chip 211 with a physical address, and the preset calibration information of the drive group is the physical address of the first drive chip 211. The others are second drive chips 212 without physical addresses, and the first drive chip 211 is connected in series with the second drive chip 212, that is, the first drive chip 211 is sequentially connected with the plurality of second drive chips 212. The drive data sent by at least one controller 250 includes the drive data of all the drive chips in the drive group. After the first drive chip 211 obtains the corresponding drive data, the other second drive chips 212 can obtain the corresponding drive data in sequence.

In the drive group in this example, only the drive chip located first is set as the first drive chip with a physical address, and the other second drive chips connected in series are all drive chips without physical addresses. The second drive chip is more versatile than the first drive chip, so the manufacturing difficulty and cost of the drive group in this example are relatively low.

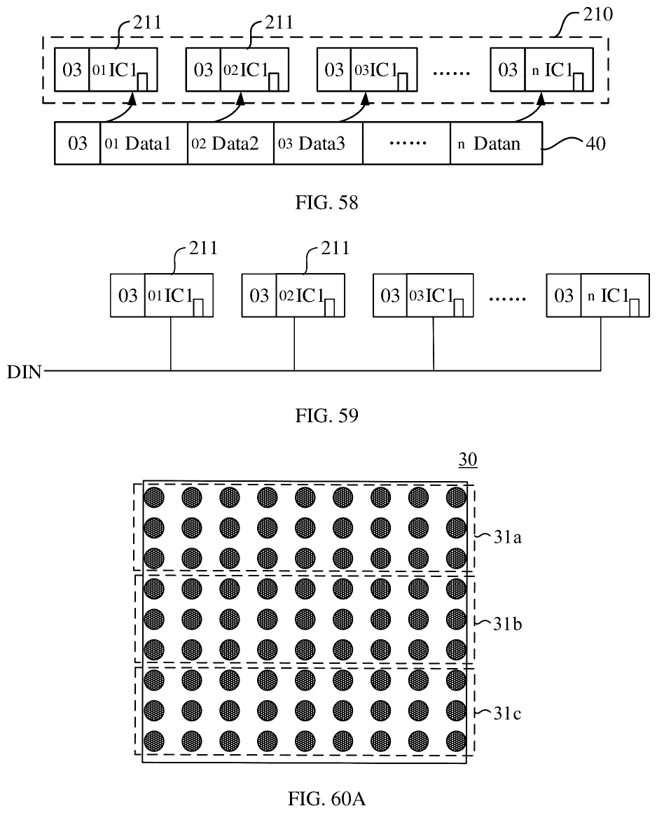

In another example, FIG. 58 is a schematic diagram showing the structure of a drive group of some embodiments of the present disclosure. As shown in FIG. 58, the drive group includes a plurality of drive chips 211 with physical addresses set in the above examples, and the physical addresses of the plurality of drive chips 211 in the same drive group are the same.

In some embodiments, each drive chip 211 in the drive group is set with an internal address, where different drive chips 211 in the same drive group have different internal addresses.

In some embodiments, at least one controller 250 is configured to send drive data to the target drive chip 211 according to the physical address of the drive group where the target drive chip 211 is located and the internal address of the drive chip 211.

The following will provide an exemplary description of the process in which the drive chip in this example obtains the corresponding drive data in combination with actual scenarios. As shown in FIG. 58, the drive group includes multiple first drive chips 211; the physical address of the first drive chip 211 is 03, and the physical address of the drive group is also 03. Each drive group corresponds to an internal address, such as 01, 02, 03 . . . n in FIG. 51. At least one controller sends the drive data of the drive group, where the drive data of the drive group includes the physical address 03 of the drive group and the internal address 01, 02, 03 . . . n of the drive chip 211. Each first drive chip 211 obtains data whose physical address and serial address are the same as its own physical address and serial address as the drive data of the drive chip.

In this example, since each drive chip in the drive unit is unique based on the physical address and the internal address, the drive data can be sent directly to the corresponding drive chip based on the physical address and the internal address, instead of sending the drive data of the entire drive group as in the above example. Therefore, this example is relatively more flexible in sending data.

As an implementation manner, the plurality of drive chips in the same drive group are connected in series, and the internal address of the drive chip is the serial address of the drive chip.

As another implementation, the plurality of drive chips in the same drive group are connected in burning address of the drive chip.

FIG. 59 is a structural schematic diagram of a drive group of some embodiments of the present disclosure. As shown in FIG. 59, the drive group includes n first drive chips 211, and the first drive chips 211 are connected in parallel. Each first drive chip 211 is burned with a corresponding burning address, and the first drive chip 211 obtains corresponding drive data based on the burning address.

In this embodiment, the internal address of the drive chip is burned, so the drive chips in this embodiment can be connected in parallel, that is, multiple drive chips are connected in parallel through one data line, thereby further improving the efficiency of data transmission.

The arrangement of the drive chips in each drive group may include various forms.

In some embodiments, each drive group corresponds to a row of light beads in the light panel, and different drive groups correspond to different rows.

Each drive chip in each drive group is connected to at least one light bead in a row corresponding to the drive group.

It can be understood that in this example, the drive group is connected to a row of light beads, and this row of light beads includes multiple partitions (light strings), and each partition includes at least one light bead. To facilitate the connection between the drive chip and the light beads, the drive chip and the corresponding light beads can be installed on a substrate nearby as a backlight bar, so the arrangement of each drive chip in the drive group is the same as the corresponding light beads. When the drive group corresponds to a row of light beads, the drive chips in the drive group are also arranged in rows. In other words, the backlight bar is a horizontal strip.

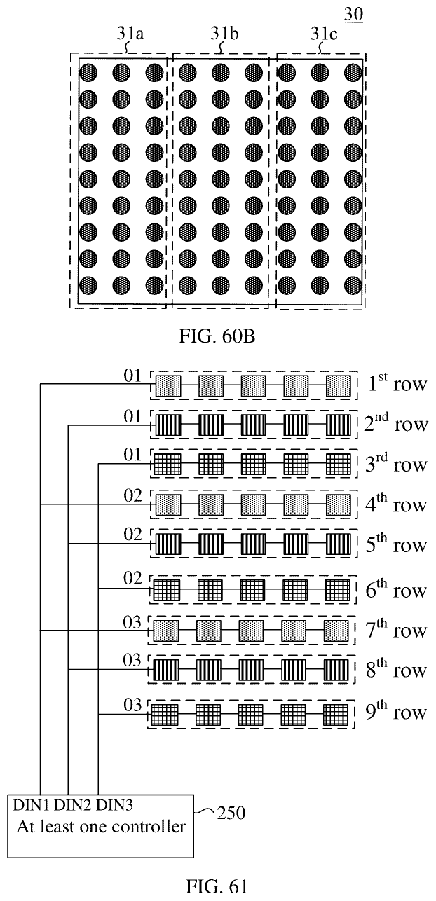

As an example, FIG. 60A is a schematic diagram showing the structure of a light board of some embodiments of the present disclosure. As shown in FIG. 60A, the light beads of the light board are divided into multiple display groups with the same quantity of rows from top to bottom, and the drive groups corresponding to each row in the same display group are divided into the same drive unit. For example, the 1^{st} row drive group, the 2^{nd} row drive group and the 3^{rd} row drive group corresponding to the 1^{st} row, the 2^{nd} row and the 3^{rd} row in the display group 31a are divided into one drive unit, which is the example in FIG. 60A.

As another example, the light beads of the light board are divided into multiple display groups with the same quantity of rows from top to bottom, and the drive groups corresponding to the rows with corresponding positions in the display groups are divided into the same drive unit. As shown in FIG. 60A, the 1^{st} row is the 1^{st} row of the first display group 31a, the 4^{th} row is the 1^{st} row of the second display group 31b, and the 7^{th} row is the 1^{st} row of the third display group 31c, where the 1^{st} row, the 4^{th} row and the 7^{th} row are rows with corresponding positions, and similarly the 2^{nd} row, the 5^{th} row and the 8^{th} row are rows with corresponding positions. FIG. 61 is a schematic structural diagram of the drive circuit of some embodiments of the present disclosure, in which the drive group of the 1^{st} row corresponding to the 1^{st} row (light beads), the 4^{th} row drive group corresponding to the 4^{th} row, and the 7^{th} row drive group corresponding to the 7^{th} row are divided into one drive unit, and similarly the 2^{nd} row drive group, the 5^{th} row drive group and the 8^{th} row drive group are divided into one drive unit.

In another example, each drive group corresponds to a column of light beads in the light board, and different drive groups correspond to different columns; each drive chip in each drive group is connected to at least one light bead in the column corresponding to the drive group. That is to say, the backlight bar in this example is a longitudinal strip.

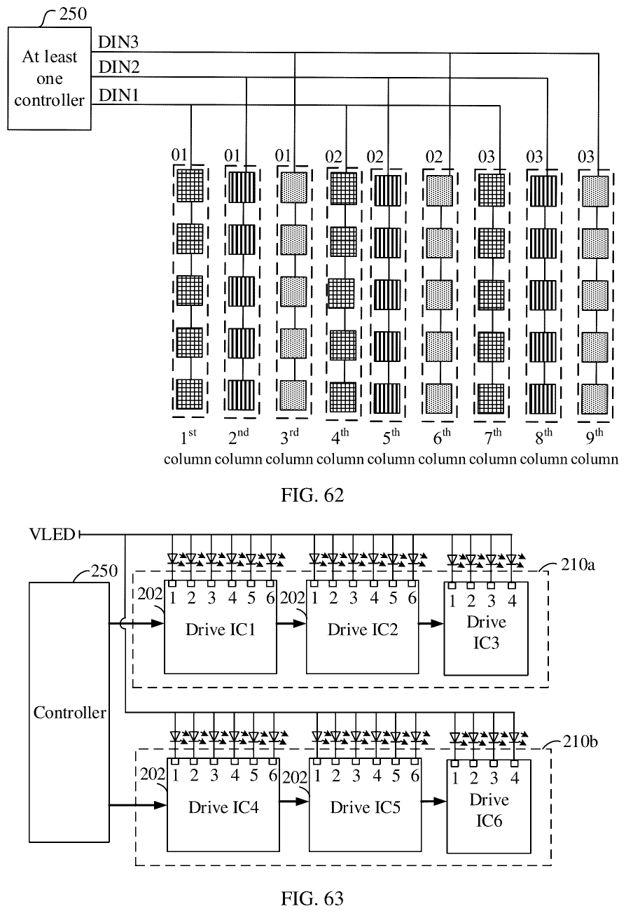

Similarly, there is no restriction on the position of the columns corresponding to each drive group in the same drive unit in the light board. As an example, the light beads of the light board are divided into multiple display groups with the same quantity of columns from left to right, and the drive groups corresponding to the columns with corresponding positions in the display groups are divided into the same drive unit. FIG. 60B is a structural schematic diagram of the light board of some embodiments of the present disclosure. As shown in FIG. 60B, starting from the first column, every three consecutive columns are divided into a display group. Taking the second display group 212b as an example, the first column, the fourth column, and the seventh column are columns with corresponding positions, and the second column, the fifth column, and the eighth column are columns with corresponding positions. FIG. 62 is a structural schematic diagram of the drive circuit of some embodiments of the present disclosure. As shown in FIG. 62, the first column drive group, the fourth column drive group, and the seventh column drive group are divided into one drive group, and the third column drive group, the sixth column drive group, and the ninth column drive group are divided into one drive group.

As another example, the light beads of the light board are divided into a plurality of display groups with the same quantity of columns from left to right, and the drive groups corresponding to the columns in the same display group are divided into the same drive unit.

In some embodiments, the quantity of drive groups in each drive unit may be the same, and the preset calibration information of the drive groups corresponding to different drive units may be the same, so that at least one controller can generate drive data for each drive group.

The drive circuit provided in this embodiment includes multiple drive units, and the preset calibration information of the multiple drive groups in each drive unit is different. In this way, the multiple drive groups can obtain corresponding drive data based on the corresponding physical through the data lines corresponding to the drive units to which they belong, instead of requiring each drive group to obtain the preset calibration information through a separate data line. Therefore, this solution can reduce the quantity of data lines used between at least one controller and the drive group, thereby reducing the manufacturing difficulty and manufacturing cost of the display apparatus.

The present application also provides a controller.

In some embodiments, the controller is configured to obtain a drive data group of the drive unit, where the drive data group includes at least one piece of drive data, the drive data in the drive data group corresponds to a drive group under the drive unit, and the drive data includes preset calibration information of the corresponding drive group.

In some embodiments, the controller is configured to send the drive data segment to the corresponding drive group through the data line corresponding to the drive unit based on the preset calibration information of the drive data, so that the drive chip under the drive group receives the corresponding drive data.

The present application also provides a display apparatus.

In some embodiments, a display apparatus includes the drive circuit in any of the above embodiments.

In some embodiments, a display apparatus includes at least the controller in any one of the above embodiments.

In the related art, the drive chip includes a uniform quantity of channels, one light string corresponds to one channel, and the controller sends a uniform quantity of drive data to each drive chip so that each channel obtains the corresponding drive data. However, in some cases, the quantity of light strings in each row of light beads does not exactly match the quantity of channels in the drive chip, which results in vacant channels in the drive chip. For example, each row of light beads has 14 partitions, and a 6-channel drive chip is used. If 2 drive chips are used, it is insufficient, so only 3 drive chips can be used, which will leave 4 channels, which makes the utilization rate of the drive chip low.

The drive group uses drive chips with consistent specifications. For example, if they all use 6 channels or 4 channels, the above channel surplus problem will easily occur. If the drive chips with different quantities of channels are mixed, the above problem can be avoided. For example, in the above scenario where each row of light beads includes 14 partitions, 24-channel drive chips and 16-channel drive chip can be mixed and connected, which just matches the quantity of partitions in each row. Therefore, the mixed connection of drive chips with different quantities of channels can avoid the channel surplus of the drive chip, thereby improving the utilization rate of the drive chip. However, the difficulty in realizing the mixed connection method is that after the mixed connection, the quantity of channels of each drive chip is not fixed, and the communication between the controller and each drive chip will be chaotic, so that the drive chip cannot obtain the corresponding drive data, which in turn causes the drive chip to fail to work normally.

The technical content provided by the present application is intended to solve the above technical problems of related technologies. The solution of the present application can ensure that drive chips with different quantities of channels obtain corresponding drive data in an orderly manner, and then can realize mixed connection of drive chips with different quantities of channels, thereby improving the utilization rate of the drive chips and reducing the cost and occupied area of the drive circuit.

The technical solution of the present application is described in detail below in conjunction with specific embodiments. The following specific embodiments can be combined with each other, and the same or similar concepts or processes may not be described in detail in some embodiments. In the description of the present application, unless otherwise clearly specified and limited, each term should be understood in a broad sense in the art. The embodiments of the present application will be described below in conjunction with the accompanying drawings.

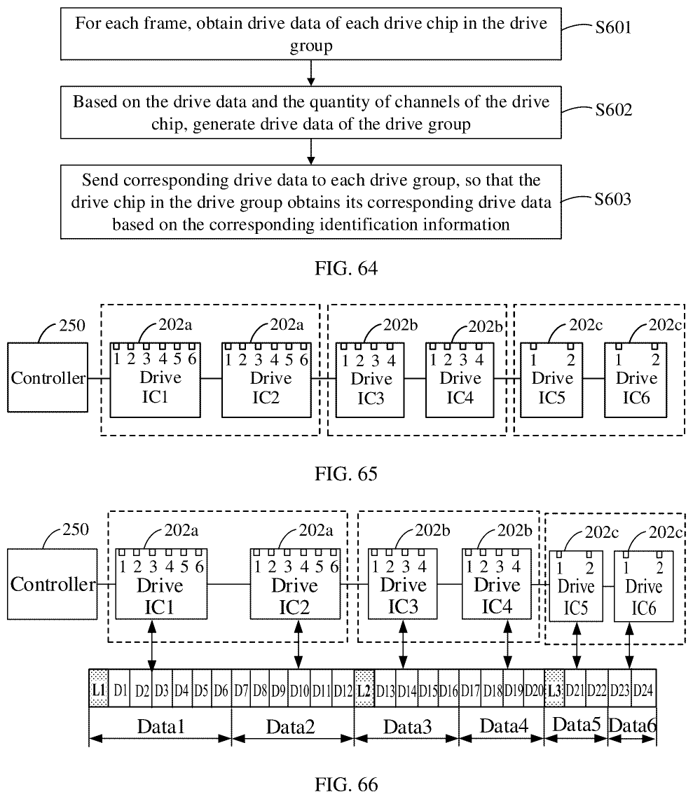

In some embodiments, FIG. 64 is a schematic structural diagram of a display apparatus provided in an embodiment of the present application. As shown in FIG. 64, the drive circuit of the display apparatus includes at least one drive group 210, where each drive group 210 includes multiple drive chips 202.

In some embodiments, the plurality of drive chips 202 in the same drive group 210 correspond to at least one row or at least one column of light beads. The plurality of drive chips 202 drive the corresponding row or column of light beads to emit light based on the drive data.

In some embodiments, as shown in FIG. 64, multiple drive chips 202 in the same drive group 210 are connected in series.

In some other embodiments, multiple drive chips 202 in the same drive group 210 are connected in parallel.

In some embodiments, with continued reference to FIG. 64, the drive chip 202 under the same drive group 210 is connected to the controller 250 via a connecting line.

In some embodiments, multiple drive groups 210 are connected to the controller 250 via a data line, where each drive group 210 is provided with an address, different drive groups 210 correspond to different addresses, and the controller 250 sends each group of drive data to the corresponding drive group 210 via the address.

In some embodiments, at least one of the plurality of drive chips 202 has a different quantity of channels than the other drive chips 202. One channel can correspond to one light resource, and one light resource can comprises one or more light beads. One light-emitting unit group comprising a plurality of light sources can be a light strip, or one light resource can be a light strip, which is not limited herein.

The plurality of drive chips 202 may include drive chips 202 with at least two channel quantities. As shown in FIG. 64, the quantity of channels of drive chip IC1 and drive chip IC2 is 6, and the quantity of channels of drive chip IC3 is 4.

There is no limit on the specific quantity of channels, which can be an odd quantity or an even quantity, and can be set according to the quantity of light beads or light strings.

In some embodiments, the controller 250 is configured to obtain drive data of each drive chip 202 in the drive group 210 for each frame.

When acquiring the drive data of each drive chip 202, in some embodiments, the controller 250 is configured to acquire a frame of image data, where the image data includes backlight data and display data. The controller 250 is configured to send the display data to the display panel, and the display panel displays based on the display data and the backlight provided by the backlight assembly. The controller 250 is also configured to process the backlight data to obtain the drive data of the drive chip 202. It should be noted that the data length of each drive chip 202 is positively correlated with the quantity of channels.

In some embodiments, the controller 250 is configured to generate drive data of the drive group 210 based on the drive data and the quantity of channels of the drive chip 202.

In some embodiments, the drive data of the drive group 210 includes multiple data segments, and the multiple data segments correspond one-to-one to multiple drive chips 202. The drive data of the drive group 210 includes at least one piece of identification information, and the drive chip 202 corresponds to one piece of identification information. The identification information corresponding to the drive chips 202 with different channel quantities is different.

The identification information corresponding to the drive chips 202 with different quantities of channels is different. That is, if the drive group 210 includes drive chips 202 with three quantities of channels, the drive data of the drive group 210 includes three types of identification information.

Multiple drive chips may correspond to one piece of identification information and multiple drive chips 202 may correspond one-to-one to multiple pieces of identification information. For example, in FIG. 64, two 6-channel drive chips 202 may correspond to the same identification information, or may correspond to different identification information.

In some embodiments, the identification information corresponding to the drive chips 202 in different drive groups 210 is the same.

For example, the drive data of the first drive group 210a includes identification 1 and identification 2, the drive chip IC1 and the drive chip IC2 correspond to identification 1, and the drive chip IC3 corresponds to identification 2; the drive data of the second drive group 210b also includes identification 1 and identification 2, the drive chip IC4 and the drive chip IC5 correspond to identification 1, and the drive chip IC6 corresponds to identification 2.

In some embodiments, the identification information corresponding to the drive chips 202 in different drive groups 210 may be different.

For example, the drive data of the first drive group 210a includes identification 1 and identification 2, the drive chip IC1 and the drive chip IC2 correspond to identification 1, and the drive chip IC3 corresponds to identification 2; the drive data of the second drive group 210b also includes identification 3 and identification 4, the drive chip IC4 and the drive chip IC5 correspond to identification 3, and the drive chip IC6 corresponds to identification 4.

In some embodiments, the information identifier is identifiable data, and the specific form is not limited.

In some embodiments, the controller 250 is configured to send corresponding drive data to each drive group 210.

In some embodiments, each drive chip 202 in the drive group 210 obtains its corresponding drive data based on the corresponding identification information, so as to drive the corresponding light-emitting unit group to emit light based on the drive data.

In some embodiments, FIG. 65 is a flow chart of a data communication method provided by the present application. As shown in FIG. 65, the method performed by a controller of a display apparatus includes the following steps.

S601, for each frame, drive data of each drive chip in the drive group is obtained.

S602, based on the drive data and the quantity of channels of the drive chip, the drive data of the drive group is generated; where the drive data of the drive group includes a plurality of data segments, the plurality of data segments correspond one-to-one to the plurality of drive chips, the drive data of the drive group includes at least one piece of identification information the drive chip corresponds to one piece of identification information, and the identification information corresponding to drive chips with different quantities of channels is different.

S603: corresponding drive data is sent to each drive group, so that the drive chip in the drive group obtains its corresponding drive data based on the corresponding identification information.

In the above embodiment, at least one drive chip in the drive group has a different quantity of channels from other drive chips, and the drive data of the drive group includes identification information associated with the quantity of channels of the drive chip. When the drive chip obtains the drive data of the drive group, it can obtain the drive data corresponding to each channel from the drive data based on the identification information. In this way, the problem of data reading confusion caused by the different quantity of channels of each drive chip will not occur. Therefore, based on the solution in the present application, drive chips with different quantities of channels can obtain corresponding drive data in an orderly manner, and then mixed connection of drive chips with different quantities of channels can be realized, thereby improving the utilization rate of the drive chip and reducing the cost and occupied area of the drive circuit.

The following is an exemplary introduction to the method for generating the drive data of the drive group.

In some embodiments, the drive chips 202 in the same drive group 210 are connected in series, and the drive chips 202 with the same quantity of channels are adjacent to each other. In other words, the drive chips 202 with the same quantity of channels are arranged continuously.

For example, FIG. 66 is a schematic structural diagram of a drive circuit in an embodiment, as shown in FIG. 66, two drive chips with 6 channels are adjacent, two drive chips with 4 channels are adjacent, and two drive chips with 2 channels are adjacent. However, a drive chip with other channels cannot be arranged between the 4-channel drive chip IC3 and drive chip IC4.

In the above embodiment, the drive chips 202 with the same quantity of channels are adjacent, so that the drive chips with the same quantity of channels can correspond to the same identification information, thereby reducing the amount of identification information, increasing the occupancy rate of valid data in the drive data of the drive group, and thus improving data transmission efficiency.

In some embodiments, the controller 250 is configured to add identification information before the drive data corresponding to the drive chip 202 located first among the drive chips 202 with the same quantity of channels.

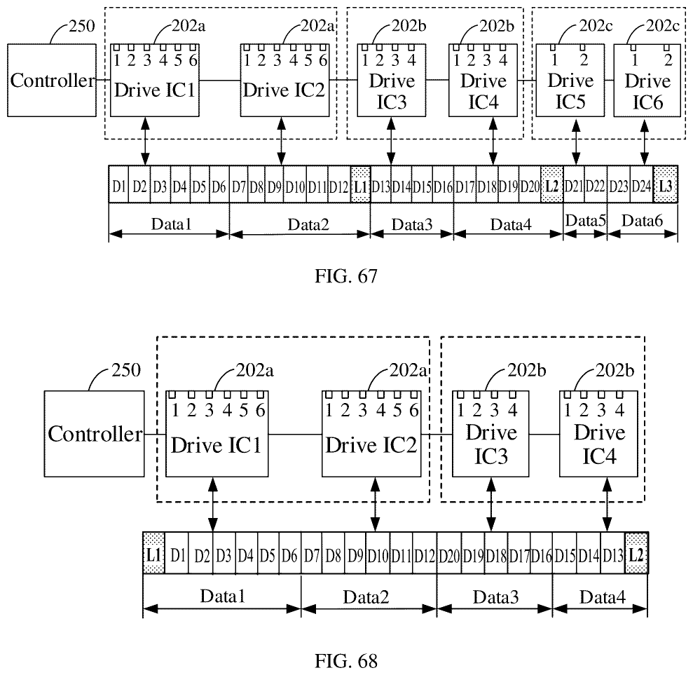

As an example, FIG. 67 is a structural schematic diagram of the drive data of the drive group. As shown in FIG. 67, D1-D6 are the drive data corresponding to the drive chip with 6 channels at the first position, and the first identification information L1 is added to the previous position of D1 to generate the data segment data1 corresponding to the drive chip. D13-D16 are the drive data corresponding to the drive chip with 4 channels at the first position, and the second identification information L2 is added to the previous position of D3 to generate the corresponding data segment data2. Similarly, the third identification information L3 is added to the previous position of D21, and the data segments are combined to generate the drive data of the drive group 210.

In some embodiments, the controller 250 is configured to add identification information after the drive data corresponding to the drive chip 202 located last among the drive chips 202 with the same quantity of channels to generate the drive data of the drive group 210.

As an example, FIG. 68 is a second structural diagram of the drive data of the drive group. As shown in FIG. 68, D7-D12 are the drive data corresponding to the drive chip with the last 6 channels, and the first identification information L1 is added to the last bit of D12. D13-D20 is the drive data corresponding to the drive chip with the last 4 channels, and the second identification information L2 is added to the last bit of D20. The third identification information L3 is added to the last bit of D24.

In the above embodiment where the identification information is located before the drive data corresponding to the first drive chip, the order of the data segments in the drive data of the drive group 210 is consistent with the order of the corresponding drive chips in the drive group 210.

Among them, “consistent order” can be understood as the position of the drive chip in the drive chips with the same quantity of channels and the position of the corresponding data segment in the drive data of the drive group are the same. For example, as shown in FIG. 67, the drive chip IC2 is located at the second position in the drive chips 202, where the corresponding data segment Data2 is the second segment in the drive data of the drive group 210, and the drive chip IC4 is located at the fourth position in the drive chips 202, where the corresponding data segment Data4 is the fourth segment in the drive data of the drive group 210.

The drive chip 202 is configured to read data of the quantity of channels in the order of the corresponding identification information in each drive chip 202 with the same quantity of channels as the drive data of the drive chip 202.

Taking FIG. 67 as an example, the drive chip IC2 is located second among the drive chips 202 with 6 channels, so the drive chip IC2 reads the first 6 bits of data starting from the first identification information L1, namely D1-D6; the drive chip IC4 is located second among the drive chips 202 with 4 channels, so the drive chip IC2 reads the second 4 bits of data starting from the second identification information L2, namely D17-D20.

In the above example, the order of data segments in the drive data of the drive group 210 is set to be consistent with the order of the corresponding drive chips 202 in the drive group 210, so that a higher effective data rate can be ensured while increasing the quantity of channels.

In some embodiments, the drive chip 202 includes at least one first drive chip and at least one second drive chip, and the first drive chip and the second drive chip have different quantities of channels. That is, the drive group 210 includes drive chips 202 with two quantities of channels.

The first drive chip is located before the second drive chip, where “before” can be understood as, if the drive chips 202 are arranged from left to right, the first drive chip is on the left side of the second drive chip, otherwise, the first drive chip is on the right side of the second drive chip. If the drive chips 202 are arranged from top to bottom, the first drive chip is on the upper side of the second drive chip, otherwise, the first drive chip is on the lower side of the second drive chip.

In some embodiments, the order of data segments corresponding to the first drive chip in the drive data of the drive group 210 is consistent with the order of the first drive chip in at least one first drive chip; and the order of data segments corresponding to the second drive chip in the drive data of the drive group 210 is the reverse order of the second drive chip in at least one second drive chip.

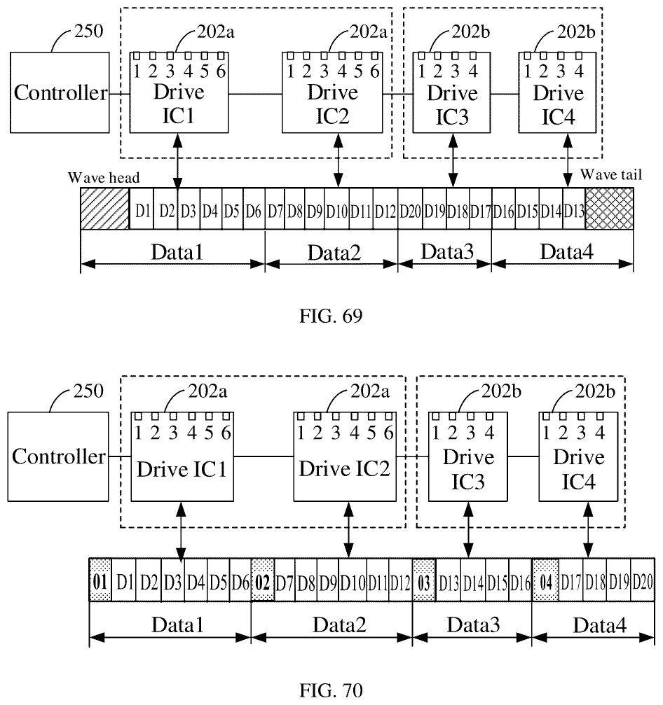

For example, FIG. 69 is a structural schematic diagram 3 of the drive data of the drive group. As shown in FIG. 69, the quantity of channels of the first drive chip is 6, and the order of the first drive chip IC1 to the first drive chip IC2 is from left to right, and the drive data corresponding to the first drive chip is also from left to right. The quantity of channels of the second drive chip is 4, and the order of the second drive chip IC3 to the second drive chip IC4 is from left to right, and the drive data corresponding to the second drive chip is also from right to left.

In some embodiments, the controller 250 is configured to add the first identification information before the drive data corresponding to the first drive chip at the first position, and add the second identification information after the drive data corresponding to the second drive chip at the last position, to generate the drive data of the drive group 210.

Taking FIG. 69 as an example, the first drive chip IC1 is the first drive chip at the first position, and the first identification information L1 is added before D1. The second drive chip IC3 is the second drive chip at the last position, and the second identification information L2 is added after D13.

During communication, the drive data of the drive group 210 includes a wave head and a wave tail for identification by the communicating party. In some embodiments, as shown in FIG. 70, the wave head and the wave tail are used as the first identification information and the second identification information, respectively, so that there is no need to set identification information separately, thereby further reducing invalid data in the drive data of the drive group.

For example, the wave head is used as the first identification information corresponding to the first drive chip, and the wave tail is used as the second identification information corresponding to the second drive chip. From the wave head, in order from left to right, each first drive chip extracts the corresponding drive data; and from the wave tail, in order from right to left, each second drive chip extracts the corresponding drive data.

In some embodiments, the first drive chip is configured to read the corresponding channel quantity of drive data from the drive data of the drive group 210, starting from the first identification information in the order of at least one first drive chip, as the drive data of the first drive chip.

The second drive chip is configured to read the corresponding channel quantity of drive data from the drive data of the drive group 210 in reverse order from the second identification information forward in at least one second drive chip as the drive data of the second drive chip.

For example, as shown in FIG. 70, the first drive chip IC1 reads D1-D6 from the first identification information, i.e., the wave head, and the first drive chip IC2 reads D7-D12; the second drive chip IC3 reads D13-D16 from the second identification information, i.e., the wave tail, and the second drive chip IC4 reads D17-D20.

In the above embodiment, the drive data corresponding to the first drive chip and the drive data corresponding to the second drive chip are arranged in reverse order, so that the first drive chip is read from left to right and the second drive chip is read from right to left. This can improve the reading efficiency of the drive chip. In addition, the wave head and wave tail can be used as corresponding identification information, thereby reducing the occupancy rate of invalid data in the drive data of the drive group, thereby improving the communication efficiency of the drive data.

Based on the above scheme that the drive chips 202 in the same drive group 210 are connected in series, the method for generating the drive data of the drive group 210 is introduced as an example. The following will introduce the method for generating the drive data of the drive group 210 as an example without limiting the connection mode of the drive chips 202 in the same drive group 210.

In some embodiments, in the same drive group 210, different drive chips 202 correspond to different identification information.

In some embodiments, the drive chip 202 is provided with an address, and the identification information includes the address.

The address can be a physical address set based on the physical structure, a burned-in address, or a serial address when connected in series.

In some embodiments, the controller 250 is configured to add corresponding identification information before the data segment corresponding to each drive chip 202 for each drive group 210 to generate drive data of the drive group 210.

For example, FIG. 98 is a structural diagram five of the drive data of the drive group. As shown in FIG. 98, a drive group 210 includes two 6-channel drive chips and two 4-channel drive chips, where the addresses of the 6-channel drive chips are 01 and 02 respectively; the addresses of the 2-channel drive chips are 03 and 04 respectively, and the corresponding addresses are added before the data segments corresponding to each drive chip, such as 02 is added before D7.

In some embodiments, the drive chip 202 is configured to obtain the channel quantity of data of the drive chip 202 after the corresponding identification information from the drive data of the drive group 210 as the drive data of the drive chip 202.

After receiving the drive data from the controller 250, the drive chip 202 locates the corresponding address from the drive data and reads the channel quantity of data after the address. In conjunction with FIG. 70, the drive chip IC3 locates to the address 03 and reads D13-D16 after 03 as the drive data of the drive chip IC3.

Based on the above embodiments, in some examples, the order of the drive chips 202 in the same drive group 210 is inconsistent with the order of the data segments corresponding to the drive chips 202 in the drive data.

Based on the above embodiments, in some examples, the order of the drive chips 202 in the same drive group 210 is consistent with the order of the data segments corresponding to the drive chips 202 in the drive data.

In some embodiments, the drive chips 202 in the same drive group 210 are connected in series.

In some embodiments, the drive chips 202 in the same drive group 210 are connected in parallel.

In the above embodiment, different drive chips correspond to different identification information. The drive chip reads the channel quantity of data after the corresponding identification information in the drive data of the drive group as its drive data. In this way, the drive chip is not restricted by the sequence and connection method.

The present application also provides a communication device, the communication device includes: an acquisition module 81, configured to acquire drive data of each drive chip in the drive group for each frame; a processing module 82, configured to generate the drive data of the drive group based on the drive data and the quantity of channels of the drive chip, where the drive data of the drive group includes a plurality of data segments, the plurality of data segments correspond one-to-one to the plurality of drive chips, the drive data of the drive group includes at least one piece of identification information the drive chip corresponds to one piece of identification information, and the identification information corresponding to the drive chips with different quantities of channels is different; and a sending module 83, configured to send the corresponding drive data to each drive group, so that the drive chip in the drive group obtains its corresponding drive data based on the corresponding identification information.

In some embodiments, multiple drive chips in the same drive group are connected in series, and drive chips with the same quantity of channels are adjacent to each other; the processing module 82 is specifically configured to, among the drive chips with the same quantity of channels, add identification information before the drive data corresponding to the first drive chip, or add the identification information after the drive data corresponding to the last drive chip, to generate the drive data of the drive group.

In some embodiments, the processing module 82 is specifically configured to: among the drive chips with the same quantity of channels, add identification information before the drive data corresponding to the first drive chip to generate the drive data of the drive group, so that the drive chip reads data of the quantity of channels in the order of the drive chips with the same quantity of channels starting from the corresponding identification information as the drive data of the drive chip.

In some embodiments, the drive chip includes at least one first drive chip and at least one second drive chip, the quantity of channels of the first drive chip and the quantity of channels of the second drive chip are different; the first drive chip is located before the second drive chip; the order of the data segment corresponding to the first drive chip in the drive data of the drive group is consistent with the order of the first drive chip in the at least one first drive chip; and the order of the data segment corresponding to the second drive chip in the drive data of the drive group is the reverse order of the second drive chip in the at least one second drive chip. The processing module 82 is configured to add the first identification information before the drive data corresponding to the first drive chip at the first position, and add the second identification information after the drive data corresponding to the second drive chip at the last position, to generate the drive data of the drive group.

As such, the first drive chip reads drive data of the corresponding quantity of channels from the drive data of the drive group in the order of the at least one first drive chip from the first identification information in the reverse order as the drive data of the first drive chip, and the second drive chip reads drive data of the corresponding quantity of channels from the drive data of the drive group in the reverse order of the at least one second drive chip from the second identification information in the reverse order as the drive data of the second drive chip.

In some embodiments, in the same drive group, different drive chips correspond to different identification information, and the processing module 82 is specifically configured to: for each drive group, add corresponding identification information before the data segment corresponding to each drive chip, and generate drive data of the drive group; so that the drive chip obtains the channel quantity of data of the drive chip after the corresponding identification information from the drive data of the drive group as the drive data of the drive chip.

In some embodiments, the present application further provides a drive circuit, which is applied to the display apparatus in any of the above embodiments.

In this embodiment, at least one drive chip in the drive group has a different quantity of channels from other drive chips, and the drive data of the drive group includes identification information associated with the quantity of channels of the drive chip. When the drive chip obtains the drive data of the drive group, it can obtain the drive data corresponding to each channel from the drive data based on the identification information. In this way, the problem of data reading confusion caused by the different quantity of channels of each drive chip will not occur. Therefore, based on the solution in the present application, drive chips with different quantities of channels can obtain corresponding drive data in an orderly manner, and then mixed connection of drive chips with different quantities of channels can be realized, thereby improving the utilization rate of the drive chip and reducing the cost and occupied area of the drive circuit.

What is claimed is:

1. A display apparatus, comprising:
a backlight assembly, comprising:
at least one drive group, wherein one drive group comprises at least one first drive chip and at least one second drive chip, a quantity of channels of a first drive chip differs from a quantity of channels of a second drive chip, and the at least one first drive chip and the at least one second drive chip are connected in series; and
at least one light-emitting unit group, wherein one light-emitting unit group comprises a plurality of light sources, each of the plurality of light sources is connected to the first drive chip or the second drive chip via a channel of the first drive chip or the second drive chip; and
a controller, connected to the at least one drive group and configured to:
control the at least one drive group to drive the at least one light-emitting unit group to emit light based on drive data and a quantity of channels of the at least one drive group.

2. The display apparatus according to claim 1, wherein a sum of a quantity of channels of the at least one first drive chip and a quantity of channels of the at least one second drive chip in the one drive group equals a quantity of the plurality of light sources in the one light-emitting unit group, and the at least one first drive chip and the at least one second drive chip are connected one-to-one with the plurality of light sources in the one light-emitting unit group through channels corresponding to the plurality of light sources.

3. The display apparatus according to claim 1, wherein the at least one first drive chip and the at least one second drive chip within the one drive group correspond to one light-emitting unit group, the one light-emitting unit group comprises at least one row or at least one column of light sources.

4. The display apparatus according to claim 1, wherein each drive group among the at least one drive group is assigned a physical address, and different drive groups correspond to different physical addresses.

5. The display apparatus according to claim 4, wherein a physical address of the first drive chip is the physical address of the drive group to which the first drive chip belongs.

6. The display apparatus according to claim 4, wherein the at least one first drive chip and the at least one second drive chip within the one drive group share the same physical address, and each of the at least one first drive chip and the at least one second drive chip within the one drive group is assigned an internal address, wherein different drive chips within the one drive group are provided with different internal addresses.

7. The display apparatus according to claim 6, wherein the controller is further configured to:
transmit the drive data to a target drive chip based on a physical address of the drive group to which the target drive chip belongs and an internal address of the target drive chip.

8. The display apparatus according to claim 6, wherein the internal address is a burned-in address or a serial address.

9. The display apparatus according to claim 1, wherein first drive chips or second drive chips with the same quantity of channels are connected in series and adjacent to each other.

10. The display apparatus according to claim 1, wherein the quantity of channels of the first drive chip is greater than the quantity of channels of the second drive chip.

11. The display apparatus according to claim 10, wherein the first drive chip is positioned before the second drive chip.

12. The display apparatus according to claim 1, wherein the controller is connected to a drive chip corresponding to a address calibration circuit within the drive group via the address calibration circuit.

13. The display apparatus according to claim 12, wherein a control terminal and a first terminal of the address calibration circuit are connected to the controller, and an output terminal of the address calibration circuit is connected to an input terminal of the drive chip corresponding to the address calibration circuit.

14. The display apparatus according to claim 13, wherein the address calibration circuit is configured to obtain address data output by the controller from the control terminal of the address calibration circuit, and when the address data comprises an address of the drive chip connected to the address calibration circuit, send the drive data obtained through the first terminal to the drive chip.

15. The display apparatus according to claim 14, wherein different address calibration circuits correspond to different address data.

16. The display apparatus according to claim 1, wherein quantities of first drive chips in different drive groups are the same, and quantities of second drive chips in different drive groups are the same.

17. The display apparatus according to claim 1, wherein quantities of first drive chips in different drive groups are different.

18. The display apparatus according to claim 1, wherein quantities of second drive chips in different drive groups are different.

19. The display apparatus according to claim 1, wherein a sequence of data segments in the drive data of the one drive group is consistent with a sequence of the at least one first drive chip and the at least one second drive chip within the drive group.

20. The display apparatus according to claim 1, wherein a sequence of a data segment corresponding to the first drive chip within the drive data of the drive group is consistent with a sequence of the first drive chip among the at least one first drive chip; and a sequence of a data segment corresponding to the second drive chip within the drive data of the drive group is reverse to a sequence of the second drive chip among the at least one second drive chip.
